(19) United States
(12) Patent Application Publication
(10) Pub. No.: US 2022/0244637 A1
(43) Pub. Date: Aug. 4, 2022

(54) COMPOSITION, FILM, CURED FILM AND METHOD FOR MANUFACTURING THE SAME, NEAR-INFRARED TRANSMITTING FILTER, SOLID-STATE IMAGING ELEMENT, AND INFRARED SENSOR

(71) Applicant: FUJIFILM Corporation, Tokyo (JP)

(72) Inventors: Takashi KAWASHIMA, Haibara-gun (JP); Masaomi MAKINO, Haibara-gun (JP)

(73) Assignee: FUJIFILM Corporation, Tokyo (JP)

(21) Appl. No.: 17/720,543

(22) Filed: Apr. 14, 2022

Related U.S. Application Data
(63) Continuation of application No. PCT/JP2020/038426, filed on Oct. 12, 2020.

(30) Foreign Application Priority Data
Oct. 17, 2019 (JP) 2019-189941

(51) Int. Cl. G03F 7/00; G03F 7/004; C08F 220/18; C08F 222/20; H01L 27/146

(52) U.S. Cl. CPC G03F 7/0007; G03F 7/0045; G02B 5/208; C08F 222/20; H01L 27/1462; C08F 220/1807

(57) ABSTRACT

Provided are a composition including a colorant, a resin, and a solvent, in which the resin includes 10 mol % or more of a specific repeating unit, a content of the colorant is 30 mass % or more with respect to a total solid content of the composition, and Amin/B, which is a ratio of a minimum value Amin of an absorbance of the composition in a wavelength range of 400 to 640 nm to an absorbance B of the composition at a wavelength of 1,500 nm, is 5 or more; a film obtained from the composition; a cured film obtained by curing the composition and a method for manufacturing the same; a near-infrared transmitting filter including the film or the cured film, a solid-state imaging element including the film or the cured film; and an infrared sensor including the film or the cured film.

### CROSS-REFERENCE TO RELATED APPLICATIONS

This application is a Continuation of PCT International Application No. PCT/JP2020/038426 filed on Oct. 12, 2020, which claims priority under 35 U.S.C § 119(a) to Japanese Patent Application No. 2019-189941 filed on Oct. 17, 2019. Each of the above application(s) is hereby expressly incorporated by reference, in its entirety, into the present application.

### BACKGROUND OF THE INVENTION

### 1. Field of the Invention

The present invention relates to a composition, a film, a cured film and a method for manufacturing the same, a near-infrared transmitting filter, a solid-state imaging element, and an infrared sensor.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A film including a pigment, such as a color filter, has been used for the solid-state imaging element. The film including a pigment, such as a color filter, is manufactured by using a composition and the like, which includes a colorant, a resin, and a solvent.

For example, JP2019-031627A discloses an alkali-soluble resin having a specific constitutional unit, which is characterized by including each constitutional unit in a specific content, a photosensitive resin composition for a color filter, which includes the resin, and the like.

JP1995-311461A (JP-H7-311461A) discloses a water-soluble coloring photosensitive resin composition which includes a water-soluble resin having a polymer formed of at least one monomer selected from a group of an acrylamide-based monomer consisting of α-substituted acrylamide, N-mono-substituted acrylamide, N,N-di-substituted acrylamide, and N-mono-substituted methacrylamide, a crosslinking agent having a water-soluble azide compound, and a colorant.

### SUMMARY OF THE INVENTION

In recent years, in the manufacturing process of a solid-state imaging element, it has been also studied to form a film such as a color filter using a composition including a colorant, a resin, and a solvent, and then subject the film to a step requiring a heating treatment at a high temperature (for example, 320° C. or higher). Therefore, it is desired to provide a composition having excellent heat resistance of the film to be obtained.

Accordingly, an object of the present invention is to provide a novel composition with which a film having excellent heat resistance is obtained, a film obtained from the composition, a cured film obtained by curing the composition and a method for manufacturing the same, a near-infrared transmitting filter including the film or the cured film, a solid-state imaging element including the film or the cured film, and an infrared sensor including the film or the cured film.

Examples of typical embodiments of the present invention are shown below.

<1>

A composition comprising:

a colorant;

a resin; and

a solvent,

in which the resin includes at least one repeating unit selected from the group consisting of repeating units each represented by any one of Formula (1-1), . . . , or Formula (1-5),

a proportion of a total amount of the repeating units each represented by any one of Formula (1-1), . . . , or Formula (1-5) is 10 mol % or more with respect to a total molar amount of all repeating units included in the resin,

a total content of the colorant and a near-infrared absorber is 30 mass % or more with respect to a total solid content of the composition, and

Amin/B, which is a ratio of a minimum value Amin of an absorbance of the composition in a wavelength range of 400 to 640 nm to an absorbance B of the composition at a wavelength of 1,500 nm, is 5 or more,

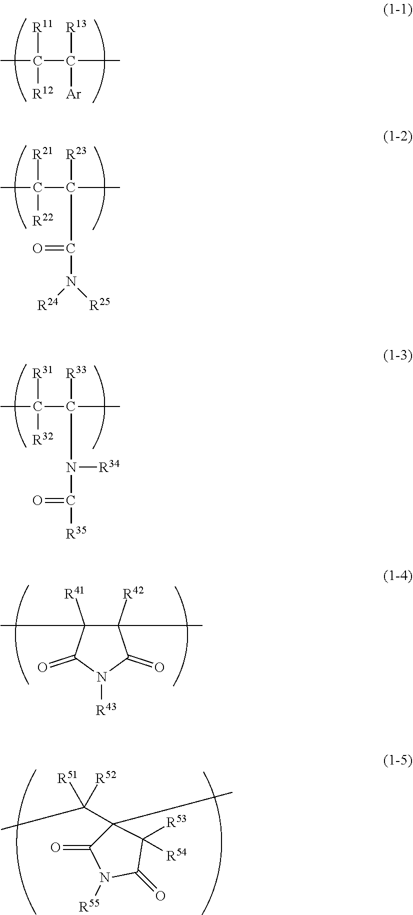

in Formula (1-1), R¹¹, R¹², and R¹³ each independently represent a hydrogen atom, a fluorine atom, an alkyl group which may be substituted with a fluorine atom, or an aromatic hydrocarbon group which may be substituted with a fluorine atom, and Ar represents an aromatic group having 5 to 30 ring members,

in Formula (1-2), R²¹, R²², and R²³ each independently represent a hydrogen atom, a fluorine atom, an alkyl group which may be substituted with a fluorine atom, or an aromatic hydrocarbon group which may be substituted with a fluorine atom, R²⁴ and R²⁵ each independently represent a hydrogen atom, an alkyl group having 1 to 30 carbon atoms, or an aromatic hydrocarbon group having 6 to 30 carbon atoms, and R²⁴ and R²¹ may be bonded to each other to form a ring structure,

in Formula (1-3), R³¹, R³², and R³³ each independently represent a hydrogen atom, a fluorine atom, an alkyl group which may be substituted with a fluorine atom, or an aromatic hydrocarbon group which may be substituted with a fluorine atom, R³⁴ and R³⁵ each independently represent a hydrogen atom, an alkyl group having 1 to 30 carbon atoms, or an aromatic hydrocarbon group having 6 to 30 carbon atoms, and R³⁴ and R³⁵ may be bonded to each other to form a ring structure,

in Formula (1-4), R⁴¹ and R⁴² each independently represent a hydrogen atom, a fluorine atom, an alkyl group which may be substituted with a fluorine atom, or an aromatic hydrocarbon group which may be substituted with a fluorine atom, and R⁴³ represents a hydrogen atom, an alkyl group having 1 to 30 carbon atoms, or an aromatic hydrocarbon group having 6 to 30 carbon atoms,

in Formula (1-5), R⁵¹ to R⁵⁴ each independently represent a hydrogen atom, a fluorine atom, an alkyl group which may be substituted with a fluorine atom, or an aromatic hydrocarbon group which may be substituted with a fluorine atom, and R⁵⁵ represents a hydrogen atom, an alkyl group having 1 to 30 carbon atoms, or an aromatic hydrocarbon group having 6 to 30 carbon atoms.

<2> The composition according to <1>,

in which a proportion of a total amount of the repeating unit represented by Formula (1-1) is 10 mol % or more with respect to the total molar amount of all repeating units included in the resin.

<3> The composition according to <1>,

in which the proportion of the total amount of the repeating units each represented by any one of Formula (1-1), . . . , or Formula (1-5) is more than 60 mol % with respect to the total molar amount of all repeating units included in the resin.

<4> The composition according to any one of <1> to <3>,

in which, in Formula (1-1), Ar has, as a substituent, a substituent including a heteroatom.

<5> The composition according to any one of <1> to <4>,

in which a wavelength of a film, which is formed from the composition and has a film thickness of 1 μm, indicating a light transmittance of 50% in a thickness direction of the film is 700 to 950 nm, and a minimum value of a light transmittance of the film in a wavelength range of 950 to 1,300 nm is 90% or more.

<6> The composition according to any one of <1> to <5>,

in which a wavelength of a film, which is formed from the composition and has a film thickness of 1 μm, indicating a light transmittance of 50% in a thickness direction of the film is 700 to 800 nm, and a minimum value of a light transmittance of the film in a wavelength range of 800 to 1,300 nm is 90% or more.

<7> The composition according to any one of <1> to <6>,

in which the colorant is an organic pigment.

<8> The composition according to any one of <1> to <7>, further comprising:

the near-infrared absorber.

<9> The composition according to any one of <1> to <8>,

in which the colorant includes a black coloring material.

<10> The composition according to any one of <1> to <9>,

in which the colorant includes at least one coloring material selected from the group consisting of a red coloring material, a green coloring material, a blue coloring material, a yellow coloring material, and a violet coloring material.

<11> The composition according to any one of <1> to <10>,

in which the resin has at least one group selected from the group consisting of a hydroxy group, a carboxy group, a sulfo group, a phosphoric acid group, and an amino group.

<12> The composition according to any one of <1> to <11>,

in which an acid value of the resin is 0 to 150 mgKOH/g.

<13> The composition according to any one of <1> to <12>,

in which the resin has an ethylenically unsaturated bond.

<14> The composition according to any one of <1> to <13>,

in which, as the resin, the following resin 1 and resin 2 are included,

resin 1: a resin which is the resin and includes a group having an acid group and an ethylenically unsaturated bond,

resin 2: a resin which is the resin, has at least one group selected from the group consisting of a hydroxy group, a carboxy group, a sulfo group, a phosphoric acid group, and an amino group, and has a molecular chain having a molecular weight of 500 to 10,000 and having no acid group and basic group.

<15> The composition according to any one of <1> to <14>, further comprising:

a polymerizable compound.

<16> The composition according to any one of <1> to <15>, further comprising:

a polymerization initiator.

<17> The composition according to <16>,

in which the polymerization initiator is a photopolymerization initiator.

<18> The composition according to any one of <1> to <17>,

in which the composition is used for forming a pattern in a photolithography method.

<19> The composition according to any one of <1> to <18>,

in which the composition is used for a solid-state imaging element.

<20> A film obtained from the composition according to any one of <1> to <19>.

<21> A cured film obtained by curing the composition according to any one of <1> to <19>.

<22> A near-infrared transmitting filter comprising:

the film according to <20>; or

the cured film according to <21>.

<23> A solid-state imaging element comprising:

the film according to <20>; or

the cured film according to <21>.

<24> An infrared sensor comprising:

the film according to <20>; or

the cured film according to <21>.

<25> A method for manufacturing a cured film, comprising:

a step of curing a film formed from the composition according to any one of <1> to <19> by at least one of exposure or heating.

<26> The method for manufacturing a cured film according to <25>, further comprising:

a step of curing a film formed from the composition according to any one of <1> to <19> by exposure.

<27> A method for manufacturing a cured film, comprising:

an exposing step of exposing a part of a film formed from the composition according to any one of <1> to <19>; and

a developing step of developing the film after exposure.

According to the present invention, a novel composition with which a film having excellent heat resistance is obtained, a film obtained from the composition, a cured film obtained by curing the composition and a method for manufacturing the same, a near-infrared transmitting filter including the film or the cured film, a solid-state imaging element including the film or the cured film, and an infrared sensor including the film or the cured film are provided.

### BRIEF DESCRIPTION OF THE DRAWINGS

FIG. 1 is a schematic diagram showing an embodiment of an infrared sensor.

### DESCRIPTION OF THE PREFERRED EMBODIMENTS

Hereinafter, main embodiments of the present invention will be described. However, the present invention is not limited to the specified embodiments.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, a (meth)allyl group represents either or both of allyl and methallyl, “(meth)acrylate” represents either or both of acrylate and methacrylate, “(meth)acryl” represents either or both of acryl and methacryl, and “(meth)acryloyl” represents either or both of acryloyl and methacryloyl.

In the present specification, a weight-average molecular weight and a number-average molecular weight are values in terms of polystyrene through measurement by a gel permeation chromatography (GPC) method.

In the present specification, near-infrared rays denote light having a wavelength in a range of 700 to 2,500 nm.

In the present specification, a total solid content denotes the total mass of all the components of the composition excluding a solvent.

In the present specification, the term “step” refers to not only an individual step but also a step which is not clearly distinguishable from another step as long as an effect expected from the step can be achieved.

In addition, in the present specification, a combination of preferred aspects is a more preferred aspect.

(Composition)

A composition according to an embodiment of the present invention includes a colorant, a resin, and a solvent, in which the resin includes at least one repeating unit selected from the group consisting of repeating units each represented by any one of Formula (1-1), . . . , or Formula (1-5), a proportion of a total amount of the repeating units each represented by any one of Formula (1-1), . . . , or Formula (1-5) is 10 mol % or more with respect to a total molar amount of all repeating units included in the resin, a total content of the colorant and a near-infrared absorber is 30 mass % or more with respect to a total solid content of the composition, and Amin/B, which is a ratio of a minimum value Amin of an absorbance of the composition in a wavelength range of 400 to 640 nm to an absorbance B of the composition at a wavelength of 1,500 nm, is 5 or more.

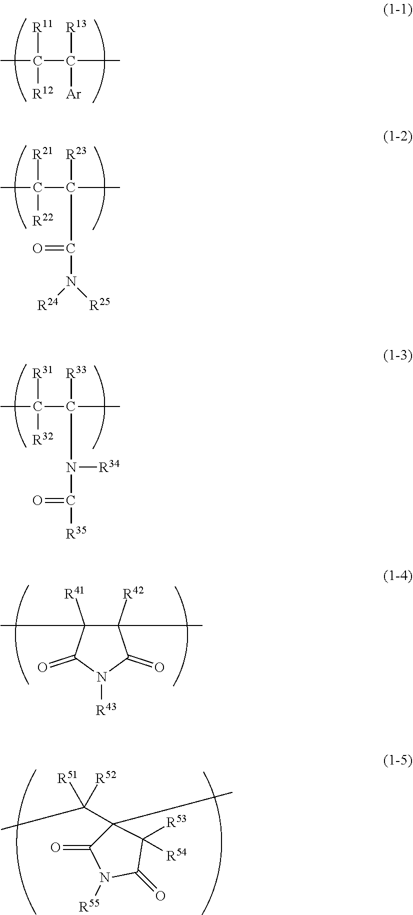

In Formula (1-1), R¹¹, R¹², and R¹³ each independently represent a hydrogen atom, a fluorine atom, an alkyl group which may be substituted with a fluorine atom, or an aromatic hydrocarbon group which may be substituted with a fluorine atom, and Ar represents an aromatic group having 5 to 30 ring members;

in Formula (1-2), R²¹, R²², and R²³ each independently represent a hydrogen atom, a fluorine atom, an alkyl group which may be substituted with a fluorine atom, or an aromatic hydrocarbon group which may be substituted with a fluorine atom. R²⁴ and R²⁵ each independently represent a hydrogen atom, an alkyl group having 1 to 30 carbon atoms, or an aromatic hydrocarbon group having 6 to 30 carbon atoms, and R²⁴ and R²⁵ may be bonded to each other to form a ring structure;

in Formula (1-3), R³¹, R³², and R³³ each independently represent a hydrogen atom, a fluorine atom, an alkyl group which may be substituted with a fluorine atom, or an aromatic hydrocarbon group which may be substituted with a fluorine atom. R³⁴ and R³⁵ each independently represent a hydrogen atom, an alkyl group having 1 to 30 carbon atoms, or an aromatic hydrocarbon group having 6 to 30 carbon atoms, and R³⁴ and R³⁵ may be bonded to each other to form a ring structure;

in Formula (14), R⁴¹ and R⁴² each independently represent a hydrogen atom, a fluorine atom, an alkyl group which may be substituted with a fluorine atom, or an aromatic hydrocarbon group which may be substituted with a fluorine atom, and R⁴³ represents a hydrogen atom, an alkyl group having 1 to 30 carbon atoms, or an aromatic hydrocarbon group having 6 to 30 carbon atoms;

in Formula (1-5), R⁵¹ to R⁵⁴ each independently represent a hydrogen atom, a fluorine atom, an alkyl group which may be substituted with a fluorine atom, or an aromatic hydrocarbon group which may be substituted with a fluorine atom, and R⁵⁵ represents a hydrogen atom, an alkyl group having 1 to 30 carbon atoms, or an aromatic hydrocarbon group having 6 to 30 carbon atoms.

The composition according to the embodiment of the present invention contains a colorant and, as necessary, a near-infrared absorber, and further contains a resin and an organic solvent. Specifically, a total content of the colorant contained in the composition and the near-infrared absorber which may be contained in the composition as necessary is 30 mass % or more with respect to a total solid content of the composition.

As a result of intensive studies, the present inventors have found that, in a composition including such a colorant, a resin, and a solvent, in which the content of the colorant and a near-infrared absorber which may be contained as necessary is 30 mass % or more with respect to the total solid content of the composition, in a case where an acrylic resin used in the related art is used as the resin, for example, there is room for further improvement in a heat resistance of a film which is obtained in a case of being subjected to a step requiring a heating treatment at a high temperature (for example, 320° C. or higher), such as an increase in film contraction ratio of the film.

The present inventors have presumed that the above-described film contraction is caused by a decomposition of the acrylic resin due to high temperature.

Therefore, as a result of intensive studies, the present inventors have found that, by using, as the resin, a resin (hereinafter, also referred to as a “specific resin”) in which a proportion of a total amount of repeating units each represented by any one of Formula (1-1), . . . , or Formula (1-5) is 10 mol % or more, a film having excellent heat resistance is obtained.

Although the mechanism by which the above-described effects are obtained is unclear, it is considered that, in the film obtained by the composition including the above-described specific resin, a decomposition of the above-described specific resin is suppressed even in the step of a heating treatment requiring the high temperature. Therefore, it is considered that the film formed of the composition according to the embodiment of the present invention is suppressed from contraction due to heating and has excellent heat resistance.

In addition, in the composition according to the embodiment of the present invention, Amin/B, which is a ratio of a minimum value Amin of an absorbance in a wavelength range of 400 to 640 nm to an absorbance B at a wavelength of 1,500 nm, is 5 or more. With such an aspect, it is possible to form a film which shields visible light and transmits infrared light.

Here, the present inventors have found that, in a case where the composition is designed to shield such visible light, a transmission of ultraviolet light during exposure of a pattern formation may be hindered, and there is room for further improvement in exposure sensitivity.

Therefore, as a result of intensive studies, the present inventors have found that, by using the specific resin having the repeating unit represented by any one of Formula (1-1), . . . , or Formula (1-5), which has a highly polar structure, compared to a structure included in the acrylic resin in the related art, the exposure sensitivity is also easily improved. It is presumed that this is because, for example, by using the above-described specific resin, there is a high possibility that polymerizable groups in the specific resin or polymerizable compound, which has a low polar structure, are close to each other in the composition, and crosslinking of the polymerizable groups during exposure is likely to proceed.

In any of JP2019-031627A or JP1995-311461A (JP-H7-311461A) described above, it has not been investigated to use the composition including the specific resin and having Amin/B of 5 or more described above.

Hereinafter, details of the composition according to the embodiment of the present invention will be described.

<Amin/B>

In the composition according to the embodiment of the present invention, Amin/B, which is a ratio of a minimum value Amin of an absorbance in a wavelength range of 400 to 640 nm to an absorbance B at a wavelength of 1,500 nm, is 5 or more.

The composition according to the embodiment of the present invention can also be referred to as a near-infrared transmitting composition because it allows transmission of near-infrared ray.

The value of Amin/B described above is preferably 10 or more, more preferably 15 or more, and still more preferably 30 or more.

In the composition according to the embodiment of the present invention, the value of Amin/B described above is designed, for example, by adjusting the type of the colorant and the content of the colorant.

In the present invention, an absorbance Aλ at a wavelength λ is defined by the following Expression (1).

Aλ=−log(Tλ/100) (1)

Aλ is an absorbance at the wavelength λ and Tλ is a transmittance (%) at the wavelength λ.

In the present invention, the value of the absorbance may be a value measured in the form of a composition or a value of a film which is formed using the composition. In a case where the absorbance is measured in a form of the film, it is preferable that the absorbance is measured using a film prepared by applying the composition to a glass substrate using a method such as spin coating such that a thickness of the film after drying is a predetermined value, and drying the applied composition using a hot plate at 100° C. for 120 seconds. The thickness of the film can be measured using a stylus type surface shape measuring device (DEKTAK 150, manufactured by ULVAC Inc.) on the substrate including the film.

In addition, the absorbance can be measured using a known spectrophotometer in the related art. A measurement condition for the absorbance is not particularly limited, but it is preferable to measure the absorbance B in a wavelength range of 1,500 nm under conditions which are adjusted such that the minimum value Amin of the absorbance in the wavelength range of 400 to 640 nm is 0.1 to 3.0. By measuring the absorbance under such conditions, a measurement error can be further reduced. A method of adjusting the minimum value Amin of the absorbance in the wavelength range of 400 to 640 nm to be 0.1 to 3.0 is not particularly limited. For example, in a case where the absorbance is measured in the form of the composition, a method of adjusting an optical path length of a sample cell may be mentioned. In addition, in a case where the absorbance is measured in the form of the film, a method of adjusting the film thickness may be mentioned.

Specific examples of a measuring method of spectral characteristics, film thickness, and the like of a film formed of the composition according to the embodiment of the present invention are shown below.

The composition according to the embodiment of the present invention is applied to a glass substrate using a method such as spin coating such that a thickness of the film after drying is a predetermined value, and the composition according to the embodiment of the present invention is dried using a hot plate at 100° C. for 120 seconds. The thickness of the film is measured by using a stylus type surface shape measuring device (DEKTAK150 manufactured by ULVAC, Inc.) on the dried substrate including the film. Using an ultraviolet-visible-near infrared spectrophotometer (U-4100 manufactured by Hitachi High-Tech Corporation), a transmittance of the dried substrate including the film is measured in a wavelength range of 300 to 1,500 nm.

It is more preferable that the composition according to the embodiment of the present invention satisfies any of the following spectral characteristics (1A) to (4A).

(1A): Amin1/Bmax1, which is a ratio of a minimum value Amin1 of an absorbance in a wavelength range of 400 to 640 nm to a maximum value Bmax1 of an absorbance in a wavelength range of 800 to 1,500 nm, is 5 or more, preferably 10 or more, more preferably 15 or more, and still more preferably 30 or more. According to this aspect, for example, it is possible to form a film capable of shielding light in the wavelength range of 400 to 640 nm and transmitting near-infrared ray at a wavelength of more than 670 nm.

(2A): Amin2/Bmax2, which is a ratio of a minimum value Amin2 of an absorbance in a wavelength range of 400 to 750 nm to a maximum value Bmax2 of an absorbance in a wavelength range of 900 to 1,500 nm, is 5 or more, preferably 10 or more, more preferably 15 or more, and still more preferably 30 or more. According to this aspect, for example, it is possible to form a film capable of shielding light in the wavelength range of 400 to 750 nm and transmitting near-infrared ray at a wavelength of more than 850 nm.

(3A): Amin3/Bmax3, which is a ratio of a minimum value Amin3 of an absorbance in a wavelength range of 400 to 830 nm to a maximum value Bmax3 of an absorbance in a wavelength range of 1,000 to 1,500 nm, is 5 or more, preferably 10 or more, more preferably 15 or more, and still more preferably 30 or more. According to this aspect, for example, it is possible to form a film capable of shielding light in the wavelength range of 400 to 830 nm and transmitting near-infrared ray at a wavelength of more than 940 nm.

(4A): Amin4/Bmax4, which is a ratio of a minimum value Amin4 of an absorbance in a wavelength range of 400 to 950 nm to a maximum value Bmax4 of an absorbance in a wavelength range of 1,100 to 1,500 nm, is 5 or more, preferably 10 or more, more preferably 15 or more, and still more preferably 30 or more. According to this aspect, for example, it is possible to form a film capable of shielding light in the wavelength range of 400 to 950 nm and transmitting near-infrared ray at a wavelength of more than 1,040 nm.

In addition, in the composition according to the embodiment of the present invention, in a case of forming a film having a film thickness of 1 μm after drying, it is preferable that the film satisfies spectral characteristics that the maximum value of light transmittance in the wavelength range of 400 to 640 nm in a thickness direction of the film is 20% or less, and a value of light transmittance at the wavelength of 1,500 nm in the thickness direction of the film is 70% or more. The maximum value in the wavelength range of 400 to 640 nm is more preferably 15% or less and still more preferably 10% or less. The lower limit thereof is not particularly limited, and it is sufficient to be 0% or more. The value at the wavelength of 1,500 nm is more preferably 75% or more and still more preferably 80% or more. The upper limit thereof is not particularly limited, and it is sufficient to be 100% or less.

In addition, it is more preferable that the composition according to the embodiment of the present invention satisfies any of the following spectral characteristics (1B) to (4B).

(1B): aspect in which, in a case of forming a film having a film thickness of 1 μm, 2 μm, 3 μm, 4 μm, or 5 μm after drying, the maximum value of light transmittance in a wavelength range of 400 to 640 nm in a thickness direction of the film is 20% or less (preferably 15% or less and more preferably 10% or less), and the minimum value of light transmittance in a wavelength range of 800 to 1,500 nm in the thickness direction of the film is 70% or more (preferably 75% or more and more preferably 80% or more)

(2B): aspect in which, in a case of forming a film having a film thickness of 1 μm, 2 μm, 3 μm, 4 μm, or 5 μm after drying, the maximum value of light transmittance in a wavelength range of 400 to 750 nm in a thickness direction of the film is 20% or less (preferably 15% or less and more preferably 10% or less), and the minimum value of light transmittance in a wavelength range of 900 to 1,500 nm in the thickness direction of the film is 70% or more (preferably 75% or more and more preferably 80% or more)

(3B): aspect in which, in a case of forming a film having a film thickness of 1 μm, 2 μm, 3 μm, 4 μm, or 5 μm after drying, the maximum value of light transmittance in a wavelength range of 400 to 830 nm in a thickness direction of the film is 20% or less (preferably 15% or less and more preferably 10% or less), and the minimum value of light transmittance in a wavelength range of 1,000 to 1,500 nm in the thickness direction of the film is 70% or more (preferably 75% or more and more preferably 80% or more)

(4B): aspect in which, in a case of forming a film having a film thickness of 1 μm, 2 μm, 3 μm, 4 μm, or 5 μm after drying, the maximum value of light transmittance in a wavelength range of 400 to 950 nm in a thickness direction of the film is 20% or less (preferably 15% or less and more preferably 10% or less), and the minimum value of light transmittance in a wavelength range of 1,100 to 1,500 nm in the thickness direction of the film is 70% or more (preferably 75% or more and more preferably 80% or more)

<Film Thickness Due to Heating>

In a case where a film having a thickness of 0.60 μm is formed by heating the composition according to the embodiment of the present invention at 200° C. for 30 minutes, a thickness of the film after performing a heating treatment of the film at 320° C. for 3 hours in a nitrogen atmosphere is preferably 70% or more of a thickness of the film before the heating treatment, more preferably 80% or more thereof, and still more preferably 90% or more thereof.

In addition, a thickness of the film after performing a heating treatment of the film at 350° C. for 5 hours in a nitrogen atmosphere is preferably 70% or more of a thickness of the film before the heating treatment, more preferably 80% or more thereof, and still more preferably 90% or more thereof.

In addition, a thickness of the film after performing a heating treatment of the film at 400° C. for 5 hours in a nitrogen atmosphere is preferably 70% or more of a thickness of the film before the heating treatment, more preferably 80% or more thereof, and still more preferably 90% or more.

The above-described physical properties can be achieved by a method such as adjusting the type and content of the specific resin to be used or other resins.

<Spectroscopic Change Due to Heating>

In addition, in a case where a film having a thickness of 0.60 μm is formed by heating the composition according to the embodiment of the present invention at 200° C. for 30 minutes, a rate of change ΔA in absorbance of the film after the heating treatment at 320° C. for 3 hours in a nitrogen atmosphere, which is represented by Expression (1), is preferably 50% or less, more preferably 45% or less, still more preferably 40% or less, and particularly preferably 35% or less.

ΔA (%)=|100−(A2/A1)×100| Expression (1):

ΔA is the rate of change in absorbance of the film after the heating treatment; A1 is a maximum value of an absorbance of the film before the heating treatment in a wavelength range of 400 to 1,500 nm; and A2 is an absorbance of the film after the heating treatment, and is an absorbance at a wavelength showing the maximum value of the absorbance of the film before the heating treatment in the wavelength range of 400 to 1,500 nm.

The above-described physical properties can be achieved by a method such as adjusting the type and content of the specific resin to be used or other resins.

In addition, in a case where a film having a thickness of 0.60 μm is formed by heating the composition according to the embodiment of the present invention at 200° C. for 30 minutes, an absolute value of a difference between a wavelength λ1 showing the maximum value of the absorbance of the film in the wavelength range of 400 to 1,500 nm and a wavelength λ2 showing the maximum value of the absorbance of the film after the heating treatment at 320° C. for 3 hours in a nitrogen atmosphere is preferably 50 nm or less, more preferably 45 nm or less, and still more preferably 40 nm or less.

The above-described physical properties can be achieved by a method such as adjusting the type and content of the specific resin to be used or other resins.

In addition, in a case where a film having a thickness of 0.60 μm is formed by heating the composition according to the embodiment of the present invention at 200° C. for 30 minutes, the maximum value of a rate of change ΔA_{λ} in absorbance of the film after the heating treatment at 320° C. for 3 hours in a nitrogen atmosphere in the wavelength range of 400 to 1,500 nm is preferably 30% or less, more preferably 27% or less, and still more preferably 25% or less. The rate of change ΔA_{λ} in the absorbance is a value calculated from Expression (2).

ΔA_{λ}=|100−(A2_{λ}/A1_{λ})×100| (2)

ΔA_{λ} is the rate of change in the absorbance of the film after the heating treatment at a wavelength λ;

A1_{λ} is the absorbance of the film before the heating treatment at the wavelength λ; and

A2_{λ} is the absorbance of the film after the heating treatment at the wavelength λ.

The above-described physical properties can be achieved by a method such as adjusting the type and content of the specific resin to be used or other resins.

In addition, in a case where a film having a thickness of 0.60 μm is formed by heating the composition according to the embodiment of the present invention at 200° C. for 30 minutes, the maximum value of a rate of change ΔB in the absorbance B of the film after the heating treatment at 320° C. for 3 hours in a nitrogen atmosphere at the wavelength of 1,500 nm is preferably 30% or less, more preferably 27% or less, and still more preferably 25% or less. The rate of change ΔB in the absorbance is a value calculated from Expression (3).

ΔB=|100−(B2/B1)×100| (3)

ΔB is the rate of change in the absorbance of the film after the heating treatment at the wavelength of 1,500 nm; B1 is an absorbance of the film before the heating treatment at the wavelength of 1,500 nm; and B2 is an absorbance of the film after the heating treatment at the wavelength of 1,500 nm.

The above-described physical properties can be achieved by a method such as adjusting the type and content of the specific resin to be used or other resins.

A wavelength of a film, which is formed from the composition according to the embodiment of the present invention and has a film thickness of 1 μm, indicating a light transmittance of 50% in a thickness direction of the film is preferably 700 to 950 nm, more preferably 700 to 900 nm, still more preferably 700 to 850 nm, and particularly preferably 700 to 800 nm.

In addition, in the film which is formed from the composition according to the embodiment of the present invention and has a film thickness of 1 μm, it is preferable that the minimum value of a light transmittance in the thickness direction of the film in a wavelength range of 950 to 1,300 nm is 90% or more, it is more preferable that the minimum value of a light transmittance in the thickness direction of the film in a wavelength range of 900 to 1,300 nm is 90% or more, it is still more preferable that the minimum value of a light transmittance in the thickness direction of the film in a wavelength range of 850 to 1,300 nm is 90% or more, and it is particularly preferable that the minimum value of a light transmittance in the thickness direction of the film in a wavelength range of 800 to 1,300 nm is 90% or more.

Among these, an aspect described in the following (T1) is preferable, and an aspect described in the following (T2) is more preferable.

(T1) wavelength of the film, which is formed from the composition according to the embodiment of the present invention and has a film thickness of 1 μm, indicating a light transmittance of 50% in a thickness direction of the film is 700 to 950 nm, and the minimum value of a light transmittance of the film in a wavelength range of 950 to 1,300 nm is 90% or more.

(T2) wavelength of the film, which is formed from the composition according to the embodiment of the present invention and has a film thickness of 1 μm, indicating a light transmittance of 50% in a thickness direction of the film is 700 to 800 nm, and the minimum value of a light transmittance of the film in a wavelength range of 800 to 1,300 nm is 90% or more.

The film which is formed from the composition according to the embodiment of the present invention and has a film thickness of 1 μm can be formed, for example, by applying the composition to a glass substrate and heating the composition at 100° C. for 120 seconds.

<Application>

The composition according to the embodiment of the present invention can be preferably used as a composition for a near-infrared transmitting filter. Specifically, the composition according to the embodiment of the present invention can be preferably used as a composition for forming a pixel of a near-infrared transmitting filter.

In addition, the composition according to the embodiment of the present invention is preferably used for a solid-state imaging element. For example, the composition according to the embodiment of the present invention can be preferably used as a composition for forming a pixel of a near-infrared transmitting filter used in a solid-state imaging element.

In addition, the composition according to the embodiment of the present invention is also preferably a composition used for forming a pattern in a photolithography method. According to this aspect, finely sized pixels can be easily formed. Therefore, the composition according to the embodiment of the present invention can be particularly preferably used as a composition for forming a pixel of a color filter used in a solid-state imaging element. For example, a composition containing a component having a polymerizable group (for example, a resin or polymerizable compound having a polymerizable group) and a photopolymerization initiator can be preferably used as a composition used for forming a pattern in a photolithography method. The composition for forming a pattern in the photolithography method preferably further includes an alkali-soluble resin (for example, a resin 1 described later or a resin having alkali developability described later).

Hereinafter, each component used in the composition according to the embodiment of the present invention will be described.

<Colorant>

The composition according to the embodiment of the present invention contains a colorant. Examples of the colorant include a white coloring material, a black coloring material, and a chromatic coloring material. In the present invention, the white coloring material includes not only a pure white coloring material but also a bright gray (for example, grayish-white, light gray, and the like) coloring material close to white.

In addition, the coloring material preferably includes at least one coloring material selected from the group consisting of a chromatic coloring material and a black coloring material, more preferably includes a chromatic coloring material, and still more preferably includes at least one coloring material selected from the group consisting of a red coloring material, a green coloring material, a blue coloring material, a yellow coloring material, and a violet coloring material.

In addition, the colorant also preferably includes a black coloring material.

Examples of the colorant include a dye and a pigment, and from the viewpoint of heat resistance, a pigment is preferable. In addition, the pigment may be an inorganic pigment or an organic pigment, but from the viewpoint of many color variations, ease of dispersion, safety, and the like, an organic pigment is preferable. In addition, it is preferable that the pigment includes at least one selected from chromatic pigments, and it is more preferable to include a chromatic pigment.

In addition, it is preferable that the pigment includes at least one selected from a phthalocyanine pigment, a dioxazine pigment, a quinacridone pigment, an anthraquinone pigment, a perylene pigment, an azo pigment, a diketopyrrolopyrrole pigment, a pyrrolopyrrole pigment, an isoindoline pigment, or a quinophthalone pigment, it is more preferable to include at least one selected from a phthalocyanine pigment, a diketopyrrolopyrrole pigment, or a pyrrolopyrrole pigment, and it is still more preferable to include a phthalocyanine pigment or a diketopyrrolopyrrole pigment. In addition, from the reason that it is easy to form a film in which spectral characteristics do not easily fluctuate even after heating to a high temperature (for example, 320° C. or higher), the phthalocyanine pigment is preferably a phthalocyanine pigment having no central metal or a phthalocyanine pigment having copper or zinc as a central metal.

In addition, from the reason that it is easy to form a film in which spectral characteristics do not easily fluctuate even after heating to a high temperature (for example, 320° C. or higher), it is preferable that the colorant included in the composition includes at least one selected from a red pigment, a yellow pigment, or a blue pigment, it is more preferable to include at least one selected from a red pigment or a blue pigment, and it is still more preferable to include a blue pigment.

The colorant included in the composition preferably includes a pigment A exhibiting the following requirement 1. By using a colorant having such characteristics, it is possible to form a film in which spectral characteristics do not easily fluctuate even after heating to a high temperature (for example, 320° C. or higher). A proportion of the pigment A in the total amount of pigments included in the composition is preferably 20 to 100 mass %, more preferably 30 to 100 mass %, and still more preferably 40 to 100 mass %.

Requirement 1)

In a case where a film having a thickness of 0.60 μm is formed by heating, at 200° C. for 30 minutes, a composition which includes 6 mass % of the pigment A, 10 mass % of a resin B-5, and 84 mass % of propylene glycol monomethyl ether acetate, in a case where the film is subjected to a heating treatment at 320° C. for 3 hours in a nitrogen atmosphere, the rate of change ΔA10 in an absorbance of the film after the heating treatment, which is represented by Expression (10), is 50% or less:

ΔA10=|100−(A12/A11)×100| (10)

ΔA10 is the rate of change in the absorbance of the film after the heating treatment; A11 is a maximum value of an absorbance of the film before the heating treatment in a wavelength range of 400 to 1,100 nm; A12 is an absorbance of the film after the heating treatment, and is an absorbance at a wavelength showing the maximum value of the absorbance of the film before the heating treatment in a wavelength range of 400 to 1,100 nm; and the resin B-5 is a resin having the following structure, in which a numerical value added to a main chain represents a molar ratio, the weight-average molecular weight is 11,000, and the acid value is 32 mgKOH/g.

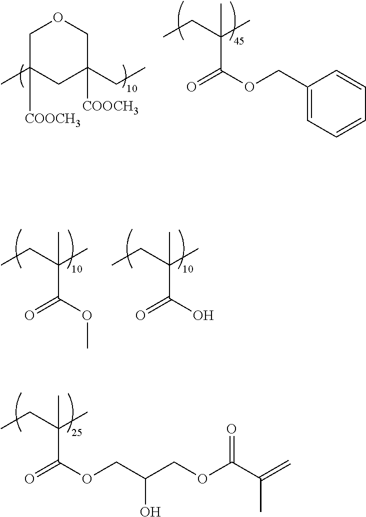

Examples of the pigment A satisfying the above-described requirement 1 include C. I. Pigment Red 254, C. I. Pigment Red 264, Pigment Red 272, Pigment Red 122, Pigment Red 177, C. I. Pigment Blue 15:3, C. I. Pigment Blue 15:4, C. I. Pigment Blue 15:6, and C. I. Pigment Blue 16.

The average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the composition is good. In the present invention, the primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

[Chromatic Coloring Material]

Examples of the chromatic coloring material include a coloring material having a maximal absorption wavelength in a wavelength range of 400 to 700 nm. Examples thereof include a yellow coloring material, a red coloring material (including an orange coloring material), a green coloring material, a violet coloring material, and a blue coloring material. From the viewpoint of heat resistance, the chromatic coloring material is preferably a pigment (chromatic pigment), more preferably a red pigment (including an orange pigment), a yellow pigment, or a blue pigment, and still more preferably a red pigment or a blue pigment. Specific examples of the chromatic pigment include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments):

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based. Organo Ultramarine. Bluish Red), 295 (monoazo-based), 296 (diazo-based), 297 (aminoketone-based), and the like (all of which are red pigments):

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

Among these chromatic pigments, as the red pigment, from the reason that it is easy to form a film in which spectral characteristics do not easily fluctuate even after heating to a high temperature (for example, 320° C. or higher), C. I. Pigment Red 254, C. I. Pigment Red 264, Pigment Red 272, Pigment Red 122, or Pigment Red 177 is preferable. In addition, as the blue pigment, C. I. Pigment Blue 15:3, C. I. Pigment Blue 15:4. C. I. Pigment Blue 15:6, or C. I. Pigment Blue 16 is preferable. In addition, as the yellow pigment, C. I. Pigment Yellow 215 or a pteridin coloring agent is preferable.

In addition, as the green coloring material, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue coloring material, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow coloring material, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765B (JP-S48-032765B), quinophthalone compounds described in JP2019-008014A, a compound represented by Formula (QP1), and a compound represented by Formula (QP2) can also be used.

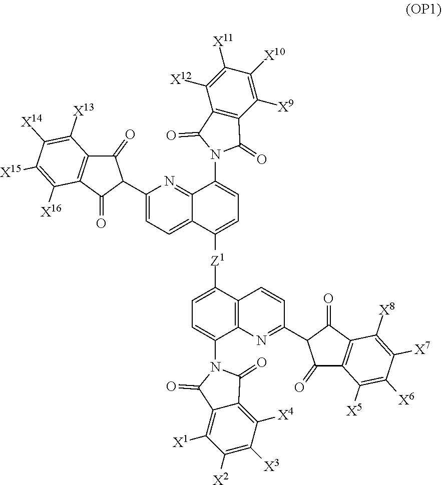

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

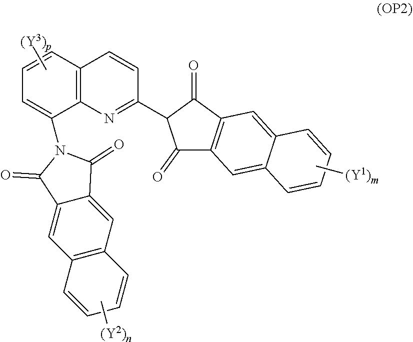

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red coloring material, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, compounds described in JP6516119B, compounds described in JP6525101B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

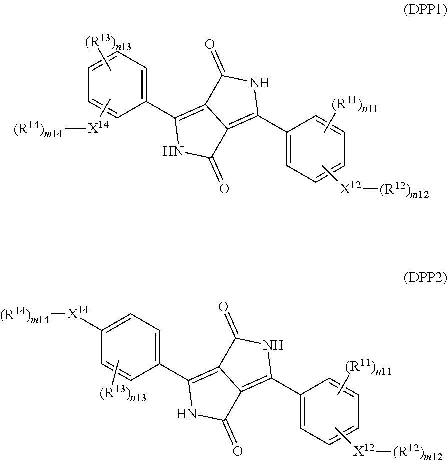

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Preferred specific examples of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

The chromatic coloring material may be used in combination of two or more kinds thereof. In addition, in a case where the chromatic coloring material is used in combination of two or more kinds thereof, the combination of two or more chromatic coloring materials may form black. Examples of such a combination include the following aspects (1) to (8). In a case where two or more chromatic coloring materials are included in the composition and the combination of two or more chromatic coloring materials forms black, the composition according to the embodiment of the present invention can be preferably used as a near-infrared transmitting filter.

(1) aspect in which a red coloring material and a blue coloring material are contained.

(2) aspect in which a red coloring material and a green coloring material are contained.

(3) aspect in which a red coloring material, a blue coloring material, and a yellow coloring material are contained.

(4) aspect in which a red coloring material, a blue coloring material, a yellow coloring material, and a violet coloring material are contained.

(5) aspect in which a red coloring material, a blue coloring material, a yellow coloring material, a violet coloring material, and a green coloring material are contained.

(6) aspect in which a red coloring material, a blue coloring material, a yellow coloring material, and a green coloring material are contained.
(7) aspect in which a red coloring material, a blue coloring material, and a green coloring material are contained.
(8) aspect in which a yellow coloring material and a violet coloring material are contained.

[White Coloring Material]

Examples of the w % bite coloring material include inorganic pigments (white pigments) such as titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-mentioned refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published on Jun. 25, 1991, published by Gihodo Shuppan Co., Ltd.” can also be used.

The white pigment is not limited to a compound formed of a single inorganic substance, and may be particles combined with other materials. For example, it is preferable to use a particle having a pore or other materials therein, a particle having a large number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

[Black Coloring Material]

The black coloring material is not particularly limited, and a known black coloring material can be used. Examples thereof include inorganic pigments (black pigments) such as carbon black, titanium black, and graphite, and carbon black or titanium black is preferable and titanium black is more preferable. The titanium black is a black particle containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name, manufactured by Akokasei Co., Ltd.).

In addition, as the black coloring material, organic black coloring materials such as a bisbenzofuranone compound, an azomethine compound, a perylene compound, and an azo compound can also be used. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF. Examples of the perylene compound include compounds described in paragraph Nos. 0016 to 0020 of JP2017-226821A, and C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

The colorant used in the composition according to the embodiment of the present invention may be only the above-described black coloring material, or may further include the chromatic coloring material. According to this aspect, it is easy to obtain a composition with which a film having a high light shielding properties in the visible region can be formed. In a case where the black coloring material and the chromatic coloring material are used in combination as the colorant, a mass ratio of the two is preferably black coloring material:chromatic coloring material=100:10 to 300, and more preferably 100:20 to 200. In addition, it is preferable to use the black pigment as the black coloring material, and it is preferable to use the chromatic pigment as the chromatic coloring material.

Examples of the chromatic coloring material include a red coloring material, a green coloring material, a blue coloring material, a yellow coloring material, a violet coloring material, and an orange coloring material.

As the chromatic coloring material, a chromatic pigment is preferable, and examples of the chromatic pigment include a red pigment (including an orange pigment), a green pigment, a blue pigment, a yellow pigment, and a violet pigment.

In addition, as the chromatic pigment, a material in which an inorganic pigment or an organic-inorganic pigment is substituted with an organic chromophore can also be used. By substituting an inorganic pigment or an organic-inorganic pigment with an organic chromophore, hue design can be easily performed. As the pigment A, a pigment including at least one selected from a red pigment, a blue pigment, or a yellow pigment is preferably used, a pigment including at least one selected from a blue pigment or a yellow pigment is more preferably used, and a pigment including a blue pigment is still more preferably used. According to this aspect, it is easy to form a film having excellent light shielding properties in the visible region. In addition, by using a blue pigment, a film having excellent light resistance can be formed. In addition, by using a yellow pigment, a visible transmittance of the obtained film can be uniform.

From the reason that it is easy to form a film having excellent light resistance, the blue pigment is preferably a phthalocyanine compound. In addition, examples of the blue pigment include Color Index (C. I.) Pigment Blue 1, 2, 15, 15:1, 15:2, 15:3, 15:4, 15:6, 16, 22, 29, 60, 64, 66, 79, 80, 87 (monoazo-based), and 88 (methine/polymethine-based), and at least one selected from C. I. Pigment Blue 15:3, C. I. Pigment Blue 15:6, or C. I. Pigment Blue 16 is preferable and C. I. Pigment Blue 15:6 is more preferable.

In addition, an aluminum phthalocyanine compound having a phosphorus atom can also be used as the blue pigment. Examples of such a compound include an aluminum phthalocyanine compound in which the ligand is a phosphoric acid ester. Specific examples of the aluminum phthalocyanine compound having a phosphorus atom include compounds described in paragraphs 0022 to 0030 of JP2012-247591A and paragraph 0047 of JP2011-157478A.

Examples of the yellow pigment include an azo compound, a quinophthalone compound, an isoindolinone compound, an isoindoline compound, and an anthraquinone compound, and an isoindoline compound is preferable. In addition, examples of the yellow pigment include C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 231, and 232 (methine/polymethine-based).

In addition, a pigment described in JP2017-201003A and a pigment described in JP2017-197719A can be used as the yellow pigment. In addition, as the yellow pigment, a metal azo pigment which includes at least one kind of an anion selected from an azo compound represented by Formula (I) or an azo compound having a tautomeric structure of the azo compound represented by Formula (I), two or more kinds of metal ions, and a melamine compound can be used.

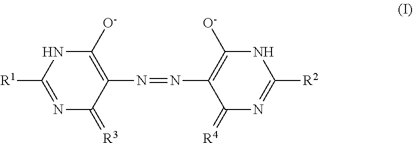

In the formula. R¹ and R² each independently represent —OH or —NR⁵R⁶, R³ and R⁴ each independently represent ═O or ═NR⁷, and R⁵ to R⁷ each independently represent a hydrogen atom or an alkyl group. The alkyl group represented by R⁵ to R⁷ preferably has 1 to 10 carbon atoms, more preferably has 1 to 6 carbon atoms, and still more preferably has 1 to 4 carbon atoms. The alkyl group may be linear, branched, or cyclic, and is preferably linear or branched and more preferably linear. The alkyl group may have a substituent. The substituent is preferably a halogen atom, a hydroxy group, an alkoxy group, a cyano group, or an amino group.

The details of the metal azo pigment can be found in paragraph Nos. 0011 to 0062 and 0137 to 0276 of JP2017-171912A, paragraph Nos. 0010 to 0062 and 0138 to 0295 of JP2017-171913A, paragraph Nos. 0011 to 0062 and 0139 to 0190 of JP2017-171914A, and paragraph Nos. 0010 to 0065 and 0142 to 0222 of JP2017-171915A, the contents of which are incorporated herein by reference.

Examples of the red pigment include a diketopyrrolopyrrole compound, an anthraquinone compound, an azo compound, and a quinacridone compound, and a diketopyrrolopyrrole compound is preferable. In addition, examples of the red pigment include C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, and 294 (xanthene-based, Organo Ultramarine, Bluish Red).

In addition, as the red pigment, a diketopyrrolopyrrole-based pigment described in JP2017-201384A, in which the structure has at least one substituted bromine atom, a diketopyrrolopyrrole-based pigment described in paragraph Nos. 0016 to 0022 of JP6248838B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

Examples of the orange pigment include C. I. Pigment Orange 2, 5, 13, 16, 17:1, 31, 34, 36, 38, 43, 46, 48, 49, 51, 52, 55, 59, 60, 61, 62, 64, 71, and 73. Examples of the violet pigment include C. I. Pigment Violet 1, 19, 23, 27, 32, 37, 42, 60 (triarylmethane-based), and 61 (xanthene-based). Examples of the green pigment include C. I. Pigment Green 7, 10, 36, 37, 58, 59, 62, and 63. In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include compounds described in WO2015/118720A.

Examples of preferred combinations of the organic black coloring material and the chromatic coloring material include the following.

(A-1) aspect in which the organic black coloring material and the blue coloring material are contained

(A-2) aspect in which the organic black coloring material, the blue coloring material, and the yellow coloring material are contained

(A-3) aspect in which the organic black coloring material, the blue coloring material, the yellow coloring material, and the red coloring material are contained

(A-4) aspect in which the organic black coloring material, the blue coloring material, the yellow coloring material, and the violet coloring material are contained

In the above-described aspect (A-1), the mass ratio of the organic black coloring material and the blue coloring material is preferably organic black coloring material:blue coloring material=100:1 to 70, more preferably 100:5 to 60, and still more preferably 100:10 to 50.

In the above-described aspect (A-2), the mass ratio of the organic black coloring material, the blue coloring material, and the yellow coloring material is preferably organic black coloring material:blue coloring material:yellow coloring material=100:10 to 90:10 to 90, more preferably 100:15 to 85:15 to 80, and still more preferably 100:20 to 80:20 to 70.

In the above-described aspect (A-3), the mass ratio of the organic black coloring material, the blue coloring material, the yellow coloring material, and the red coloring material is preferably organic black coloring material:blue coloring material:yellow coloring material:red coloring material=100:20 to 150:1 to 60:10 to 100, more preferably 100:30 to 130:5 to 50:20 to 90, and still more preferably 100:40 to 120:10 to 40:30 to 80.

In the above-described aspect (A-4), the mass ratio of the organic black coloring material, the blue coloring material, the yellow coloring material, and the violet coloring material is preferably organic black coloring material:blue coloring material:yellow coloring material:violet coloring material=100:20 to 150:1 to 60:10 to 100, more preferably 100:30 to 130:5 to 50:20 to 90, and still more preferably 100:40 to 120:10 to 40:30 to 80.

In addition, the content of the above-described organic black coloring material in the colorant is 10 mass % or more, preferably 20 mass % or more, more preferably 30 mass % or more, still more preferably 40 mass % or more, and even more preferably 50 mass % or more, and even still more preferably 60 mass % or more. A composition in the related art tends to contaminate an inside of a piping tube as the content of the organic black coloring material increases, but in the composition according to the embodiment of the present invention, since the inside of the piping tube can be less likely to be contaminated even in a case where the content of the organic black coloring material increases, the effects of the present invention are remarkably exhibited as the content of the organic black coloring material is higher.

In addition, the content of a lactam-based pigment as the organic black coloring material in the colorant is 10 mass % or more, preferably 15 mass % or more, more preferably 20 mass % or more, still more preferably 30 mass % or more, and even still more preferably 40 mass % or more, and particularly preferably 50 mass % or more.

In addition, the content of the above-described organic black coloring material in the total solid content of the composition according to the embodiment of the present invention is preferably 5 to 70 mass %. The lower limit is preferably 10 mass % or more and more preferably 15 mass % or more. The upper limit is preferably 65 mass % or less and more preferably 60 mass % or less.

A content of the colorant in the total solid content of the composition is preferably 20 mass % or more, more preferably 25 mass % or more, and still more preferably 30 mass % or more. In addition, the upper limit of the above-described content is preferably 90 mass % or less, more preferably 80 mass % or less, and still more preferably 70 mass % or less. In addition, a content of the pigment as the colorant in the total solid content of the composition is preferably 20 mass % or more, more preferably 25 mass % or more, and still more preferably 30 mass % or more. In addition, the upper limit of the above-described content is preferably 90 mass % or less, more preferably 80 mass % or less, and still more preferably 70 mass % or less.

In addition, a content of the dye in the colorant is preferably 50 mass % or less, more preferably 40 mass % or less, and still more preferably 30 mass % or less.

In addition, from the reason that it is easy to more effectively suppress the change in film thickness in a case where the obtained film is heated to a high temperature, it is also preferable that the composition according to the embodiment of the present invention does not substantially include the dye. The case where the composition according to the embodiment of the present invention does not substantially include the dye means that the content of the dye in the total solid content of the composition according to the embodiment of the present invention is preferably 0.1 mass % or less, more preferably 0.05 mass % or less, and particularly preferably 0 mass %.

In addition, a total content of the colorant and a near-infrared absorber described later is 30 mass % or more with respect to the total solid content of the composition, preferably 30 to 90 mass %, more preferably 30 to 80 mass %, and still more preferably 30 to 70 mass %. However, in the above-described aspect, the content of the near-infrared absorber may be 0 mass %.

A total content of the pigment as the colorant and a pigment as the near-infrared absorber is preferably 30 mass % or more, more preferably 30 to 90 mass %, still more preferably 30 to 80 mass % and particularly preferably 30 to 70 mass % with respect to the total solid content of the composition. However, in the above-described aspect, the content of the pigment as the near-infrared absorber may be 0 mass %.

<Near-Infrared Absorber>

In addition, it is preferable that the composition according to the embodiment of the present invention further includes a near-infrared absorber in addition to the colorant.

In addition, the composition according to the embodiment of the present invention preferably includes the chromatic coloring material and a near-infrared absorber, more preferably includes two or more kinds of chromatic coloring materials and a near-infrared absorber, and still more preferably includes the red coloring material, the blue coloring material, and a near-infrared absorber.

In addition, it is also preferable that the colorant includes the black coloring material and a near-infrared absorber described later.

According to these aspects, the composition according to the embodiment of the present invention can be preferably used as a composition for forming a near-infrared transmitting filter.

For the combination of these colorants, JP2013-77009A, JP2014-130338A, WO2015/166779A, and the like can be referred to.

The near-infrared absorber is preferably a pigment, and more preferably an organic pigment. In addition, the near-infrared absorber preferably has a maximal absorption wavelength in a wavelength range of more than 700 nm and 1,400 nm or less. In addition, the maximal absorption wavelength of the near-infrared absorber is preferably 1,200 nm or less, more preferably 1,000 nm or less, and still more preferably 950 nm or less. In addition, in the near-infrared absorber, A₅₅₀/Aₘₐₓ, which is a ratio of an absorbance A₅₅₀ at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorber excellent in visible light transparency and near-infrared shielding properties can be obtained. In the present invention, the maximal absorption wavelength of the near-infrared absorber and values of absorbance at each wavelength are values obtained from an absorption spectrum of a film formed of a composition including the near-infrared absorber.

As the near-infrared absorber, a near-infrared absorber having a maximal absorption wavelength in a wavelength range of more than 700 nm and 800 nm or less can also be used. By using a near-infrared absorber including a pigment having such spectral characteristics as the near-infrared absorber, a wavelength of light transmitted through the obtained film can be shifted to a longer wavelength side. In the near-infrared absorber having a maximal absorption wavelength in the wavelength range of more than 700 nm and 800 nm or less, a ratio A¹/A² of an absorbance A¹ at a wavelength of 500 nm to an absorbance A² at the maximal absorption wavelength is preferably 0.08 or less and more preferably 0.04 or less.

The near-infrared absorber is not particularly limited, and examples thereof include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, and a dithiolene metal complex. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B.

In addition, as the near-infrared absorber, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the a-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, coloring materials described in JP2013-77009A, JP2014-130338A, and WO2015/166779A, combinations of coloring materials described in these references, and the like can also be used.

In a case w % here the composition includes a near-infrared absorber, a content of the near-infrared absorber in the total solid content of the composition is preferably 0.1 to 70 mass % and more preferably 1 to 40 mass %.

<Pigment Derivative>

The composition according to the embodiment of the present invention can include a pigment derivative as the above-described colorant or the above-described near-infrared absorber. Examples of the pigment derivative include a compound having a structure in which a part of a chromophore is substituted with an acid group, a basic group, or a phthalimidomethyl group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. As the acid group included in the pigment derivative, a sulfo group or a carboxy group is preferable and a sulfo group is more preferable. As the basic group included in the pigment derivative, an amino group is preferable and a tertiary amino group is more preferable.

As the pigment derivative, a pigment derivative having excellent visible light transparency (hereinafter, also referred to as a transparent pigment derivative) can be used. The maximum value (εmax) of the molar absorption coefficient of the transparent pigment derivative in a wavelength region of 400 to 700 nm is preferably 3,000 L·mol⁻¹·cm⁺¹ or less, more preferably 1,000 L·mol⁻¹·cm⁻¹ or less, and still more preferably 100 L·mol⁻¹ cm⁻¹ or less. The lower limit of εmax is, for example, 1 L·mol⁻¹ cm⁻¹ or more and may be 10 L·mol⁻¹ cm⁻¹ or more.

Specific examples of the pigment derivative include compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, JP2008-081565A, JP2019-109512A, and JP2019-133154A.

The content of the pigment derivative is preferably 1 to 30 parts by mass and still more preferably 3 to 20 parts by mass with respect to 100 parts by mass of the pigment. The pigment derivative may be used singly or in combination of two or more kinds thereof.

<Specific Resin>

The composition according to the embodiment of the present invention includes a resin (specific resin) which includes at least one repeating unit selected from the group consisting of repeating units each represented by any one of Formula (1-1), . . . , or Formula (1-5) and in which a proportion of a total amount of the repeating units each represented by any one of Formula (1-1), . . . , or Formula (1-5) with respect to a total molar amount of all repeating units included in the resin is 10 mol % or more.

The proportion of the total amount of the repeating units each represented by any one of Formula (1-1), . . . , or Formula (1-5) with respect to a total molar amount of all repeating units included in the specific resin is measured by the following method.

The specific resin is thermally decomposed by a thermal decomposition GC-MS, and mass spectrometry is performed to identify the structure of the decomposed repeating units. From the molar mass of the identified structure, the molar amount of the repeating unit present in the specific resin can be identified.

From the viewpoint of heat resistance and exposure sensitivity of the obtained film, the above-described proportion of the total amount is preferably more than 60 mol %, more preferably 70 mol % or more, and still more preferably 80 mol % or more. The upper limit is not particularly limited, and it is sufficient to be 100 mol % or less.

In addition, from the viewpoint of heat resistance of the obtained film, a proportion of a total amount of the repeating unit represented by Formula (1-1) is preferably 10 mol % or more, more preferably 20 mol % or more, and still more preferably 30 mol % or more with respect to the total molar amount of all repeating units included in the specific resin.

[Formula (1-1)]

—R¹¹, R¹², and R¹³—

In Formula (1-1), R¹¹, R¹², and R¹³ each independently represent a hydrogen atom, a fluorine atom, an alkyl group which may be substituted with a fluorine atom, or an aromatic hydrocarbon group which may be substituted with a fluorine atom, and a hydrogen atom or an alkyl group is preferable and a hydrogen atom is more preferable.

As the above-described alkyl group, an alkyl group having 1 to 10 carbon atoms is preferable, an alkyl group having 1 to 4 carbon atoms is more preferable, and a methyl group is still more preferable.

In the present specification, unless otherwise specified, the description of “alkyl group” or “aliphatic hydrocarbon group” includes all alkyl groups or aliphatic hydrocarbon groups having a linear, branched, or a cyclic structure.

As the above-described aromatic hydrocarbon group, an aromatic hydrocarbon ring having 6 to 20 carbon atoms is preferable, and a phenyl group is more preferable.

The above-described alkyl group or the above-described aromatic hydrocarbon group may have a substituent as long as the effects of the present invention can be obtained.

In addition, the above-described aromatic hydrocarbon group may be bonded to another aromatic hydrocarbon ring or another aromatic heterocyclic ring as long as the effects of the present invention can be obtained. Examples of an aspect of the above-described bonding include a fused ring, a crosslinked ring, and a spiro ring.

—Ar—

In Formula (1-1), Ar represents an aromatic group having 5 to 30 ring members, and an aromatic hydrocarbon group having 6 to 20 carbon atoms or an aromatic heterocyclic group having 5 to 20 ring members is preferable and an aromatic hydrocarbon group having 6 to 20 carbon atoms is more preferable.

As the above-described aromatic hydrocarbon group, a phenyl group or a naphthyl group is preferable, and a phenyl group is more preferable.

As the above-described aromatic heterocyclic group, an aromatic heterocyclic group including a nitrogen atom, a sulfur atom, or an oxygen atom as a heteroatom is preferable. Only one of the above-described heteroatom may be present in the aromatic heterocyclic group, or two or more thereof may be present. In a case where two or more heteroatoms are present in the aromatic heterocyclic group, the above-described heteroatoms may be the same or different from each other. Examples of the above-described aromatic heterocyclic group include a thienyl group, a pyridyl group, and a 1-imidazolyl group.

The above-described aromatic group may have a substituent as long as the effects of the present invention can be obtained. As the substituent, it is preferable to have a substituent including a heteroatom. As the heteroatom in the above-described substituent including a heteroatom, an oxygen atom, a nitrogen atom, a sulfur atom, or a phosphorus atom is preferable. The above-described substituent including a heteroatom may include one kind of these heteroatoms alone, or may include two or more kinds thereof. In addition, the number of heteroatoms in the above-described substituent including a heteroatom is not particularly limited, but for example, is preferably 1 to 10.

Examples of the above-described substituent including a heteroatom include acid groups such as a hydroxy group, a carboxy group, a sulfo group, a phosphoric acid group, a phosphonic acid group, an active imide group (substituted sulfonamide group, —S(═O)₂NHC(═O)R, —S(═O)₂NHS(═O)₂R, or —C(═O)NHS(═O)₂R; R is a hydrocarbon group which may have a substituent), or a sulfonamide group (—S(═O)₂NR^{S1}₂ or R^{S2}—S(═O)₂—NR^{S3}—; R^{S1} represents a hydrogen atom or a hydrocarbon group which may have a substituent, and it is preferable that at least one of R^{S1}'s is a hydrogen atom and it is more preferable that both R^{S1}'s are hydrogen atoms; R^{S2} represents a monovalent substituent, and a hydrocarbon group is preferable; R^{S3} represents a hydrogen atom or a hydrocarbon group, and a hydrocarbon group is preferable), an amino group, an alkyl group, an aromatic hydrocarbon group, an aromatic heterocyclic group, and a halogen atom.

In addition, these substituents may be bonded to the above-described aromatic group through a linking group. Examples of the linking group include an aliphatic hydrocarbon group, an aromatic hydrocarbon group, —O—, —C(═O)—, —S—, —S(═O)₂—, —NR^{N}—, or a group in which two or more of these groups are bonded. R^{N} represents a hydrogen atom or a hydrocarbon group, and a hydrogen atom, an alkyl group, or an aromatic hydrocarbon group is preferable, a hydrogen atom or an alkyl group is more preferable, and a hydrogen atom is particularly preferable. In addition, two or more of the above-described substituents may be bonded to the above-described linking group.

Examples of a preferred aspect of the present invention include an aspect in which the above-described substituent is directly bonded to the above-described aromatic group without the above-described linking group.

From the viewpoint of imparting alkali developability to the composition, it is preferable that Ar has the above-described acid group such as a hydroxy group, a carboxy group, a sulfo group, a phosphoric acid group, a phosphonic acid group, an active imide group, and a sulfonamide group.

In addition, the above-described acid group may form an ester bond with other structures. Examples of the other structures include a structure which includes a group having an alkyl group (for example, a methyl group, an ethyl group, and the like), a polymer chain, or an ethylenically unsaturated bond. Examples of the above-described polymer chain include a molecular chain described later, which has a molecular weight of 500 to 10,000 and does not have an acid group and a basic group.

In addition, the above-described amino group may form an amide bond, a urethane bond, or a urea bond with other structures. The above-described other structure has the same meaning as the other structures described as the object to which the acid group is ester-bonded.

[Formula (1-1-1), Formula (1-1-2), and Formula (1-1-3)]

The repeating unit represented by Formula (1-1) is preferably a repeating unit represented by Formula (1-1-1), a repeating unit represented by Formula (1-1-2), or a repeating unit represented by Formula (1-1-3).

In addition, as the repeating unit represented by Formula (1-1), the specific resin preferably includes a repeating unit represented by Formula (1-1-2), and more preferably includes a repeating unit represented by Formula (1-1-2) and a repeating unit represented by Formula (1-1-3).

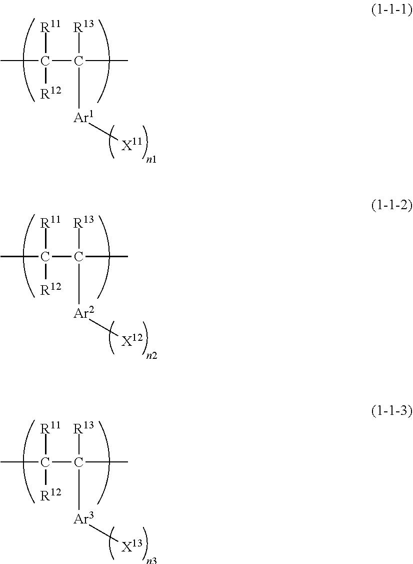

In Formulae (1-1-1), (1-1-2), and (1-1-3), R¹¹, R¹², and R¹³ each independently represent a hydrogen atom, a fluorine atom, an alkyl group which may be substituted with a fluorine atom, or an aromatic hydrocarbon group which may be substituted with a fluorine atom, Ar¹ represents an aromatic group having 5 to 30 ring members, X¹¹ represents an alkyl group having 1 to 30 carbon atoms, an aromatic hydrocarbon group having 6 to 20 carbon atoms, or a group represented by a combination of at least one group selected from the group consisting of a saturated aliphatic hydrocarbon group having 1 to 30 carbon atoms and an aromatic hydrocarbon group having 6 to 20 carbon atoms and —C(═O)O— or —C(═O)NR^{N}—, n1 represents an integer of 0 to a maximum number of substitutions of Ar¹, Ar² represents an aromatic group having 5 to 30 ring members, X¹²'s each independently represent a hydroxy group, a carboxy group, a sulfo group, a phosphoric acid group, a phosphonic acid group, an active imide group, or a sulfonamide group, n2 represents an integer of 1 to a maximum number of substitutions of Ar², Ar³ represents an aromatic group having 5 to 30 ring members, X¹³'s each independently represent a group represented by any one of Formula (E-1), . . . , or (E-11), and n3 represents an integer of 1 to a maximum number of substitutions of Ar³. R^{N} represents a hydrogen atom or a hydrocarbon group, and a hydrogen atom, an alkyl group, or an aromatic hydrocarbon group is preferable, a hydrogen atom or an alkyl group is more preferable, and a hydrogen atom is particularly preferable.

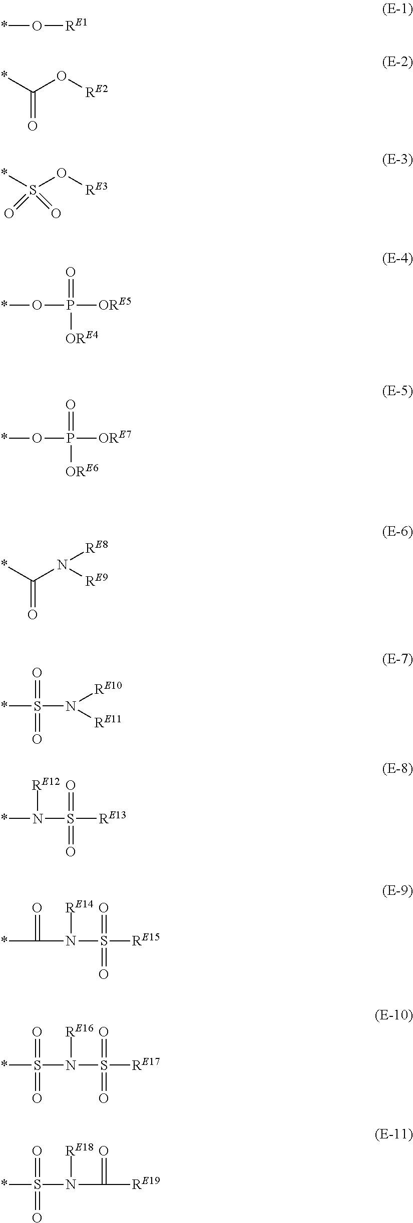

In Formulae (E-1) to (E-11). R^{E1} to R^{E3}, R^{E13}, R^{E15}, R^{E17}, and R^{E19} each independently represent a monovalent substituent, R^{E4} to R^{E12}, R^{E14}, R^{E16}, and R^{E18} each independently represent a hydrogen atom or a monovalent substituent, at least one of R^{E4} or R^{E5} is a monovalent substituent, at least one of R^{E6} or R^{E7} is a monovalent substituent, at least one of R^{E8} or R^{E9} is a monovalent substituent, at least one of R^{E10} or R^{E11} is a monovalent substituent, at least one of R^{E12} or R^{E13} is a monovalent substituent, at least one of R^{E14} or R^{E15} is a monovalent substituent, at least one of R^{E16} or R^{E17} is a monovalent substituent, at least one of R^{E18} or R^{E19} is a monovalent substituent, and * represents a bonding site with Ar³ in Formula (1-1-3).

—R¹¹, R¹², and R¹³—

R¹¹, R¹², and R¹³ in Formulae (1-1-1), (1-1-2), and (1-1-3) have the same meaning as R¹¹, R¹², and R¹³ in Formula (1-1), respectively, and the preferred aspects thereof are also the same.

—Ar¹—

Ar¹ in Formula (1-1-1) has the same meaning as Ar in Formula (1-1), and the preferred aspect thereof is also the same.

### —X¹¹—

In Formula (1-1-1), X¹¹ represents an alkyl group having 1 to 30 carbon atoms, an aromatic hydrocarbon group having 6 to 20 carbon atoms, or a group represented by a combination of at least one group selected from the group consisting of an alkyl group having 1 to 30 carbon atoms and an aromatic hydrocarbon group having 6 to 20 carbon atoms and —C(═O)O— or —C(═O)NR^{N}—. From the viewpoint of heat resistance and affinity with an organic solvent, it is preferable to be a group represented by a combination of at least one group selected from the group consisting of a saturated aliphatic hydrocarbon group having 1 to 30 carbon atoms and an aromatic hydrocarbon group having 6 to 20 carbon atoms and —C(═O)O— or —C(═O)NR^{N}—.

As the above-described alkyl group having 1 to 30 carbon atoms, an alkyl group having 1 to 20 carbon atoms is preferable, an alkyl group having 1 to 10 carbon atoms is more preferable, and an alkyl group having 1 to 4 carbon atoms is still more preferable.

As the above-described aromatic hydrocarbon group having 6 to 20 carbon atoms, a phenyl group or a naphthyl group is preferable, and a phenyl group is more preferable.

As the above-described saturated aliphatic hydrocarbon group having 1 to 30 carbon atoms, a saturated aliphatic hydrocarbon group having 1 to 20 carbon atoms is preferable, a saturated aliphatic hydrocarbon group having 1 to 10 carbon atoms is more preferable, and a saturated aliphatic hydrocarbon group having 1 to 4 carbon atoms is still more preferable.

From the viewpoint of heat resistance and affinity with an organic solvent, as the group represented by a combination of at least one group selected from the group consisting of a saturated aliphatic hydrocarbon group having 1 to 30 carbon atoms and an aromatic hydrocarbon group having 6 to 20 carbon atoms, and —C(═O)O— or —C(═O)NR^{N}—, a group in which the bonding site with Ar¹ in Formula (1-1-1) is *—C(═O)O— or *—C(═)NR^{N}—. * represents a bonding site with Ar¹.

In addition, as the group represented by a combination of at least one group selected from the group consisting of a saturated aliphatic hydrocarbon group having 1 to 30 carbon atoms and an aromatic hydrocarbon group having 6 to 20 carbon atoms, and —C(═O)O— or —C(═O)NR^{N}—, a group represented by Formula (D-1) or Formula (D-2) is preferable and a group represented by Formula (D-1) is more preferable.

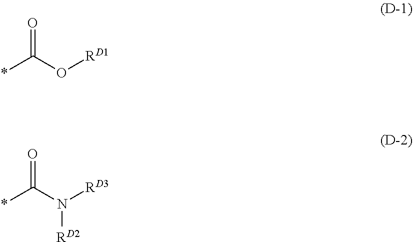

In Formula (D-1) or Formula (D-2), *'s each independently represent a bonding site with Ar¹ in Formula (1-1-1), R^{D1} represents a substituent D described later, R^{D2} and R^{D3} each independently represent a hydrogen atom or a substituent D described later.

The substituent D is a group represented by a combination of at least one group selected from the group consisting of an alkyl group having 1 to 30 carbon atoms, an aromatic hydrocarbon group having 6 to 20 carbon atoms, an aliphatic saturated hydrocarbon group having 1 to 30 carbon atoms, and an aromatic hydrocarbon group having 6 to 20 carbon atoms, and —C(═O)O— or —C(═O)NR^{N}—.

Preferred aspects of the alkyl group having 1 to 30 carbon atoms, the aromatic hydrocarbon group having 6 to 20 carbon atoms, or the aliphatic saturated hydrocarbon group having 1 to 30 carbon atoms in the substituent D have the same meanings as the preferred aspects of these groups in X¹¹ described above.

From the viewpoint of heat resistance and affinity with an organic solvent, the substituent D in R^{D1} is preferably an alkyl group having 1 to 30 carbon atoms or an aromatic hydrocarbon group having 6 to 20 carbon atoms, more preferably an alkyl group having 1 to 30 carbon atoms, still more preferably an alkyl group having 1 to 10 carbon atoms, particularly preferably an alkyl group having 1 to 4 carbon atoms, and most preferably a methyl group.

Both R^{D2} and R^{D3} may be hydrogen atoms, but it is preferable that at least one thereof is the above-described substituent D, and it is more preferable that one is a hydrogen atom and the other is the above-described substituent D.

The substituent D in R^{D2} and R^{D3} is preferably an alkyl group having 1 to 30 carbon atoms or an aromatic hydrocarbon group having 6 to 20 carbon atoms, more preferably an alkyl group having 1 to 30 carbon atoms, still more preferably an alkyl group having 1 to 10 carbon atoms, and particularly preferably an alkyl group having 1 to 4 carbon atoms.

—n1—

In Formula (1-1-1), n1 represents an integer of 0 to a maximum number of substitutions of Ar¹, and 0 or 1 is preferable and 0 is more preferable.

The maximum number of substitutions of Ar¹ refers to the maximum number of substituents which can be included in the aromatic group having 5 to 30 ring members, represented by Ar¹, and in a case where Ar¹ is a benzene ring structure, the maximum number of substitutions is 5. Hereinafter, the above-described contents are the same in the description of the maximum number of substitutions.

—Ar²—

Ar² in Formula (1-1-2) has the same meaning as Ar in Formula (1-1), and the preferred aspect thereof is also the same.

—X¹²—

In Formula (1-1-2), X¹² represents a hydroxy group, a carboxy group, a sulfo group, a phosphoric acid group, or a phosphonic acid group, and a hydroxy group or a carboxy group is preferable and a carboxy group is more preferable.

—n2—

In Formula (1-1-2), n2 represents an integer of 1 to a maximum number of substitutions of Ar², and 1 or 2 is preferable and 1 is more preferable.

—Ar³—

Ar³ in Formula (1-1-3) has the same meaning as Ar in Formula (1-1), and the preferred aspect thereof is also the same.

—X¹³—

In Formula (1-1-3), X¹³ represents a group represented by any one of Formula (E-1), . . . , or (E-11), and a group represented by Formula (E-1) or Formula (E-2) is preferable and a group represented by Formula (E-2) is more preferable.

In Formulae (E-1) to (E-11), R^{E}a to R^{E19} are each independently preferably a group represented by an aliphatic hydrocarbon group, an aromatic group, or at least two bonds selected from the group consisting of an aliphatic hydrocarbon group, an aromatic group, —O—, —C(═O)—, —S—, —S(═O)₂—, —C(═O)O—, —C(═O)NR^{N}—, —OC(═O)NR^{N}—, —NR^{N}C(═O)NR^{N}, —CH₂CH(OH)CH₂—, an ethylenically unsaturated bond, and a polymer chain.

As the above-described aliphatic hydrocarbon group, an aliphatic hydrocarbon group having 1 to 20 carbon atoms is preferable and an aliphatic saturated hydrocarbon group having 1 to 20 carbon atoms is more preferable.

As the above-described aromatic group, a group same as Ar in Formula (1-1) is preferable.

Examples of the above-described group having an ethylenically unsaturated bond include an acryloyl group, an acryloyloxy group, an acrylamide group, a vinylphenyl group, and an allyl group, and from the viewpoint of reactivity, an acryloyloxy group is preferable.

As the above-described polymer chain, a polymer chain including at least one repeating unit selected from the group consisting of repeating units each represented by Formulae (1-1) to (1-5), a repeating unit derived from a (meth)acrylic acid, and a repeating unit derived from a (meth)acrylic acid ester compound is preferable, and a polymer chain including at least one repeating unit selected from the group consisting of repeating units each represented by Formulae (1-1) to (1-5) and a repeating unit derived from a (meth)acrylic acid ester compound is more preferable.

The repeating unit represented by Formulae (1-1) to (1-5) included in the polymer chain is preferably a repeating unit not having the above-described polymer chain, more preferably the repeating unit represented by Formula (1-1-1), a repeating unit represented by Formula (1-2-1) described later, the repeating unit represented by Formula (1-3), the repeating unit represented by Formula (1-4), or the repeating unit represented by Formula (1-5), and still more preferably the repeating unit represented by Formula (1-1-1) or a repeating unit represented by Formula (1-2-1) described later.

The repeating unit derived from a (meth)acrylic acid in the polymer chain is preferably a repeating unit represented by Formula (1-6) described later, and the repeating unit derived from a (meth)acrylic acid ester compound is preferably a repeating unit represented by Formula (1-7) described later (more preferably, a repeating unit represented by Formula (1-7) in which R^{A2} in Formula (1-7) is Formula (F-1)).

In addition, the repeating unit included in the polymer chain is included in the total molar amount of all repeating units included in the specific resin.

Among these, R^{E1} to R^{E19} are preferably a group represented by any one of Formula (F-1), . . . , or Formula (F-5). In the following formulae, *'s each independently represent a bonding site with other structures.

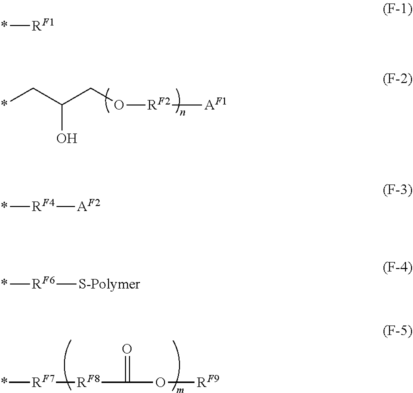

In Formula (F-1), R^{F1} represents an alkyl group which may have a substituent or an aryl group, and is preferably an alkyl group, an aromatic hydrocarbon group, an arylalkyl group, or a group represented by a bond between an alkyl group or an aromatic hydrocarbon group and —O—, more preferably an alkyl group, an arylalkyl group, or an alkoxyalkyl group, and still more preferably an alkyl group.

As the above-described alkyl group, an alkyl group having 1 to 8 carbon atoms is preferable, and an alkyl group having 1 to 4 carbon atoms is more preferable.

As the above-described aryl group, an aromatic hydrocarbon group is preferable.

As the above-described aromatic hydrocarbon group, an aromatic hydrocarbon group having 6 to 30 carbon atoms is preferable, a phenyl group or a naphthyl group is more preferable, and a phenyl group is still more preferable.

As an aryl group in the above-described arylalkyl group, an aromatic hydrocarbon group having 6 to 30 carbon atoms is preferable, a phenyl group or a naphthyl group is more preferable, and a phenyl group is still more preferable.

As an alkyl group in the arylalkyl group, an alkyl group having 1 to 8 carbon atoms is preferable and an alkyl group having 1 to 4 carbon atoms is more preferable.

As an alkoxy group in the above-described alkoxyalkyl group, an alkoxy group having 1 to 8 carbon atoms is preferable, an alkoxy group having 1 to 4 carbon atoms is more preferable, and a methoxy group is still more preferable.

In addition, the total carbon number of the above-described alkoxyalkyl group is preferably 2 to 10 and more preferably 2 to 6.

In Formula (F-2), R^{F2}'s each independently represent an alkylene group, a divalent aromatic hydrocarbon group, —C(═O)NR^{N}—, —OC(═O)NR^{N}—, —NR^{N}C(═O)NR^{N}—, or a group in which two or more these groups are bonded, and an alkylene group is preferable. R^{N} is as described above.

In the present specification, in a case of being simply described as —C(═O)NR^{N}—, —OC(═O)NR^{N}—, and —NR^{N}C(═O)NR^{N}—, the orientation of these bonds in the structure is not particularly limited.

As the above-described alkylene group, an alkylene group having 2 to 10 carbon atoms is preferable, an alkylene group having 2 to 4 carbon atoms is more preferable, an ethylene group or a propylene group is still more preferable.

As the above-described divalent aromatic hydrocarbon group, a phenylene group is preferable.

In Formula (F-2), n represents an integer of 0 or more, and is preferably an integer of 0 to 20, more preferably an integer of 0 to 10, still more preferably 0, 1, or 2, and particularly preferably 0 or 1.

In Formula (F-2), A^{F1} represents a polymerizable group, and is preferably a (meth)acryloxy group, a (meth)acrylamide group, a vinylphenyl ether group, an allyl ether group, a vinylphenyl group, an allyl group, or a vinyl group, and from the viewpoint of reactivity, a (meth)acryloxy group is more preferable.

In Formula (F-3), R^{F4} represents an alkylene group, a divalent aromatic hydrocarbon group, —C(═O)NR^{N}—, —OC(═O)NR^{N}—, —NR^{N}C(═O)NR^{N}—, or a group in which two or more these groups are bonded, and an alkylene group is preferable. R^{N} is as described above.

As the above-described alkylene group, an alkylene group having 2 to 10 carbon atoms is preferable, and an alkylene group having 2 to 4 carbon atoms is more preferable.

As the above-described divalent aromatic hydrocarbon group, a phenylene group is preferable.

In Formula (F-3), A^{F2} represents a polymerizable group, and is preferably a (meth)acryloxy group, a (meth)acrylamide group, a vinylphenyl ether group, an allyl ether group, a vinylphenyl group, an allyl group, or a vinyl group, and from the viewpoint of reactivity, a (meth)acryloxy group is more preferable.

In addition, in Formula (F-3), R^{F4} represents an alkylene group, a divalent aromatic hydrocarbon group, —C(═O)NR^{N}—, —OC(═O)NR^{N}—, —NR^{N}C(═O)NR^{N}—, or a group in which two or more of these groups are bonded, and it is also preferable that A^{F2} is a (meth)acryloxy group, or R^{F4} is a methylene group and A^{F2} is a vinyl group.

In Formula (F-4), R^{F6} represents an alkylene group, an arylene group, —C(═O)NR^{N}—, —OC(═O)NR^{N}—, —NR^{N}C(═O)NR^{N}—, or a group in which two or more these groups are bonded, and an alkylene group or a group in which two or more alkylene groups are bonded by —OC(═O)NR^{N}— is preferable. R^{N} is as described above.

As the above-described alkylene group, an alkylene group having 2 to 20 carbon atoms is preferable, and an alkylene group having 2 to 10 carbon atoms is more preferable.

In Formula (F-4), Polymer represents the polymer chain in the above description of R^{E1} to R^{E19}, and the preferred aspect thereof is also the same.

In Formula (F-5), R^{F7} represents a single bond, an alkylene group, or a divalent aromatic hydrocarbon group, and a single bond is preferable.

As the above-described alkylene group, an alkylene group having 2 to 20 carbon atoms is preferable, and an alkylene group having 2 to 10 carbon atoms is more preferable.

As the above-described divalent aromatic hydrocarbon group, a phenylene group is preferable.

In Formula (F-5), R^{F8} represents an alkylene group or a divalent aromatic hydrocarbon group, and an alkylene group is preferable.

As the above-described alkylene group, an alkylene group having 2 to 20 carbon atoms is preferable, and an alkylene group having 2 to 10 carbon atoms is more preferable.

As the above-described divalent aromatic hydrocarbon group, a phenylene group is preferable.

In Formula (F-5), m represents an integer of 1 or more, and is preferably an integer of 2 to 50 and more preferably an integer of 2 to 30.

In Formula (F-5), R^{E9} represents an alkyl group or a monovalent aromatic hydrocarbon group, and an alkyl group is more preferable.

As the above-described alkyl group, an alkyl group having 1 to 20 carbon atoms is preferable, and an alkyl group having 1 to 10 carbon atoms is more preferable.

As the above-described monovalent aromatic hydrocarbon group, a phenyl group is preferable.

—n3—

In Formula (1-1-3), n3 represents an integer of 1 to a maximum number of substitutions of Ar³, and 1 or 2 is preferable and 1 is more preferable.

The repeating unit represented by Formula (1-1) is preferably a repeating unit derived from a vinyl aromatic hydrocarbon compound (for example, vinylstyrene, vinylnaphthalene, and the like) which may have a substituent or a vinyl aromatic compound (for example, vinylthiophene, vinylpyridine, vinylimidazole, and the like) which may have a substituent.

[Repeating Unit Represented by Formula (1-2)]

—R²¹, R²², and R²³—

R²¹, R²², and R²³ in Formula (1-2) have the same meaning as R¹¹, R¹², and R¹³ in Formula (1-1), respectively, and the preferred aspects thereof are also the same.

—R²⁴ and R²⁵—

R²⁴ and R²⁵ each independently represent a hydrogen atom, an alkyl group having 1 to 30 carbon atoms, or an aromatic hydrocarbon group having 6 to 30 carbon atoms, and R²⁴ and R²⁵ may be bonded to each other to form a ring structure.

It is preferable that at least one of R²⁴ or R²⁵ represents an alkyl group having 1 to 30 carbon atoms or an aromatic hydrocarbon group having 6 to 30 carbon atoms, or R²⁴ and R²⁵ are bonded to each other to form a ring structure.

R²⁴ and R²⁵ are each independently preferably an alkyl group having 1 to 30 carbon atoms, and more preferably an alkyl group having 1 to 20 carbon atoms.

As the aromatic hydrocarbon group having 6 to 30 carbon atoms in R²⁴ and R²⁵, a phenyl group or a naphthyl group is preferable, and a phenyl group is more preferable.

Examples of the ring structure formed by bonding R²⁴ and R²³ include aliphatic heterocyclic ring structures such as a piperidine ring, a piperazine ring, and a morpholine ring.

The alkyl group having 1 to 30 carbon atoms or the aromatic hydrocarbon group having 6 to 30 carbon atoms in R²⁴ and R²⁵, or the ring structure formed by bonding R²⁴ and R²⁵ may have a substituent as long as the effects of the present invention can be obtained. Examples of the substituent include acid groups such as a carboxy group, a sulfo group, a phosphoric acid group, a phosphonic acid group, an active imide group, and a sulfonamide group, an amino group, an alkyl group, an aryl group, and a halogen atom. In addition, the aromatic hydrocarbon group having 6 to 30 carbon atoms in R²⁴ and R²⁵ may have a hydroxy group as a substituent.

From the viewpoint of imparting alkali developability to the composition, it is preferable that the alkyl group having 1 to 30 carbon atoms or the aromatic hydrocarbon group having 6 to 30 carbon atoms, or the ring structure formed by bonding R²⁴ and R²⁵ has the above-described acid group such as a carboxy group, a sulfo group, a phosphoric acid group, a phosphonic acid group, an active imide group, and a sulfonamide group. In addition, in a case where at least one of R²⁴ or R²⁵ is an aromatic hydrocarbon group having 6 to 30 carbon atoms, the aromatic hydrocarbon group may have a hydroxy group as an acid group.

In addition, the above-described acid group may form an ester bond with other structures. Examples of the other structures include a structure which includes a group having a polymer chain or an ethylenically unsaturated bond. Examples of the above-described polymer chain include a molecular chain described later, which has a molecular weight of 500 to 10,000 and does not have an acid group and a basic group.

In addition, the above-described amino group may form an amide bond, a urethane bond, or a urea bond with other structures. The above-described other structure has the same meaning as the other structures described as the object to which the acid group is ester-bonded.

[Formula (1-2-1), Formula (1-2-2), and Formula (1-2-3)]

The repeating unit represented by Formula (1-2) is preferably a repeating unit represented by Formula (1-2-1), a repeating unit represented by Formula (1-2-2), or a repeating unit represented by Formula (1-2-3).

In addition, as the repeating unit represented by Formula (1-2), the specific resin preferably includes a repeating unit represented by Formula (1-2-2), and more preferably includes a repeating unit represented by Formula (1-2-2) and a repeating unit represented by Formula (1-2-3).

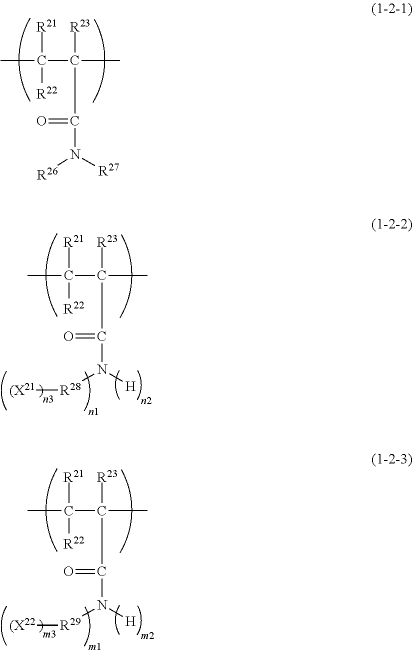

In Formulae (1-2-1), (1-2-2), and (1-2-3), R²¹, R²², and R²³ are the same meaning as R¹¹, R¹², and R¹³ in Formula (1-1), R²⁶ and R²⁷ each independently represent an alkyl group having 1 to 30 carbon atoms, R²⁸ represents an aliphatic hydrocarbon group or an aromatic hydrocarbon group, X²¹'s each independently represents a hydroxy group, a carboxy group, a sulfo group, a phosphoric acid group, a phosphonic acid group, an active imide group, or a sulfonamide group, n1 is 1 or 2, n2 is 0 or 1, n1+n2 is 2, n3 is an integer of 1 or more. R²⁹ represents an aliphatic hydrocarbon group or an aromatic hydrocarbon group, X²²'s each independently represent a group represented by any one of Formula (E-1), . . . , or (E-11), m1 represents 1 or 2, m2 represents 0 or 1, m1+m2 is 2, and m3 is an integer of 1 or more.

R²¹, R²², and R²³ in Formulae (1-2-1), (1-2-2), and (1-2-3) have the same meaning as R²¹, R²², and R²³ in Formula (1-2), respectively, and the preferred aspects thereof are also the same.

—R²⁶ and R²⁷—

In Formula (1-2-1). R²⁶ and R²⁷ each independently represent an alkyl group having 1 to 30 carbon atoms, and an alkyl group having 1 to 10 carbon atoms is preferable and an alkyl group having 1 to 4 carbon atoms is more preferable.

—R²⁸—

In Formula (1-2-2), R²⁸ represents an aliphatic hydrocarbon group or an aromatic hydrocarbon group, and an aliphatic hydrocarbon group is preferable and an aliphatic saturated hydrocarbon group is more preferable.

As the above-described aliphatic hydrocarbon group, an aliphatic hydrocarbon group having 2 to 30 carbon atoms is preferable and an aliphatic hydrocarbon group having 2 to 20 carbon atoms is more preferable.

As the above-described aromatic hydrocarbon group, a group obtained by removing (1+n3) hydrogen atoms from a benzene ring is preferable.

—X²¹—

In Formula (1-2-2), in a case where R²⁸ is an aliphatic hydrocarbon group, X²¹'s are each independently preferably a carboxy group, a sulfo group, a phosphoric acid group, a phosphonic acid group, an active imide group, or a sulfonamide group, and more preferably a carboxy group.

In Formula (1-2-2), in a case where R²⁸ is an aromatic hydrocarbon group, X²¹'s are each independently preferably a hydroxy group or a carboxy group, and more preferably a carboxy group.

—n1, n2, and n3—

In Formula (1-2-2), it is preferable that n1 is 1 and n2 is 1.

In Formula (1-2-2), n3 is an integer of 1 or more, and is preferably 1 to 10, more preferably 1 to 4, still more preferably 1 or 2, and particularly preferably 1.

—R²⁹—

In Formula (1-2-3), R²⁹ represents an aliphatic hydrocarbon group or an aromatic hydrocarbon group, and an aliphatic hydrocarbon group is preferable and an aliphatic saturated hydrocarbon group is more preferable.

As the above-described aliphatic hydrocarbon group, an aliphatic hydrocarbon group having 2 to 30 carbon atoms is preferable and an aliphatic hydrocarbon group having 2 to 20 carbon atoms is more preferable.

As the above-described aromatic hydrocarbon group, a group obtained by removing (1+m3) hydrogen atoms from a benzene ring is preferable.

—X²²—

In Formula (1-2-3), in a case where R²⁹ is an aliphatic hydrocarbon group. X²²'s are each independently preferably a group represented by any one of Formula (E-2), Formula (E-3), Formula (E-4), or Formula (E-5), and more preferably a group represented by Formula (E-2).

In Formula (1-2-3), in a case where R²⁹ is an aromatic hydrocarbon group, X²²'s are each independently preferably a group represented by any one of Formula (E-1) or Formula (E-2), and more preferably a group represented by Formula (E-2).

—m1, m2, and m3—

In Formula (1-2-3), it is preferable that m1 is 1 and m2 is 1.

In Formula (1-2-3), m3 is an integer of 1 or more, and is preferably 1 to 10, more preferably 1 to 4, still more preferably 1 or 2, and particularly preferably 1.

The repeating unit represented by Formula (1-2) is preferably a repeating unit derived from an acrylamide compound which may have a substituent.

[Repeating unit represented by Formula (1-3)]

—R³¹, R³², and R³³—

R³¹, R³², and R³³ in Formula (1-3) have the same meaning as R¹¹, R¹², and R¹³ in Formula (1-1), respectively, and the preferred aspects thereof are also the same.

—R³⁴ and R³⁵—

In Formula (1-3), R³⁴ and R³⁵ each independently represent a hydrogen atom, an alkyl group having 1 to 30 carbon atoms, or an aromatic hydrocarbon group having 6 to 30 carbon atoms, and an alkyl group having 1 to 30 carbon atoms is preferable.

As the above-described alkyl group having 1 to 30 carbon atoms, an alkyl group having 1 to 10 carbon atoms is preferable, and an alkyl group having 1 to 4 carbon atoms is more preferable.

As the above-described aromatic hydrocarbon group having 6 to 30 carbon atoms, a phenyl group or a naphthyl group is preferable, and a phenyl group is more preferable.

The above-described alkyl group having 1 to 30 carbon atoms or the above-described aromatic hydrocarbon group having 6 to 30 carbon atoms may have a substituent as long as the effects of the present invention can be obtained.

In Formula (1-3), it is preferable that at least one of R³⁴ or R³⁵ represents an alkyl group having 1 to 30 carbon atoms or an aromatic hydrocarbon group having 6 to 30 carbon atoms.

In addition, it is preferable that R³⁴ and R³⁵ are bonded to each other to form a ring structure. As the ring structure to be formed, a lactam ring structure having 5 to 20 ring members is preferable, and a lactam ring structure having 5 to 10 ring members is more preferable.

The repeating unit represented by Formula (1-3) is preferably a repeating unit derived from an N-vinyl-N-acyl compound (N-vinylacetamide and the like) or an N-vinyllactam compound (N-vinyl-2-pyrrolidone, N-vinyl-ε-caprolactam, and the like).

[Repeating Unit Represented by Formula (1-4)]

—R⁴¹ and R⁴²—

R¹¹ and R⁴² in Formula (1-4) have the same meaning as R¹¹ and R¹³ in Formula (1-1), respectively, and the preferred aspects thereof are also the same.

—R⁴³—

In Formula (14), R⁴³ represents a hydrogen atom, an alkyl group having 1 to 30 carbon atoms, or an aromatic hydrocarbon group having 6 to 30 carbon atoms, and an alkyl group having 1 to 30 carbon atoms or an aromatic hydrocarbon group having 6 to 30 carbon atoms is preferable and an aromatic hydrocarbon group having 6 to 30 carbon atoms is more preferable.

As the above-described alkyl group having 1 to 30 carbon atoms, an alkyl group having 1 to 20 carbon atoms is preferable, and an alkyl group having 1 to 10 carbon atoms is more preferable.

As the above-described aromatic hydrocarbon group having 6 to 30 carbon atoms, an aromatic hydrocarbon group having 6 to 20 carbon atoms is preferable, a phenyl group or a naphthyl group is more preferable, and a phenyl group is still more preferable.

The above-described alkyl group having 1 to 30 carbon atoms or the above-described aromatic hydrocarbon group having 6 to 30 carbon atoms may have a substituent as long as the effects of the present invention can be obtained.

The repeating unit represented by Formula (1-4) is preferably a repeating unit derived from a maleimide compound (maleimide, N-alkylmaleimide, N-phenylmaleimide, and the like).

[Repeating Unit Represented by Formula (1-5)]

—R⁵¹ and R⁵²—

R⁵¹ and R⁵² in Formula (1-5) have the same meaning as R¹¹ and R¹² in Formula (1-1), respectively, and the preferred aspects thereof are also the same.

—R⁵³ and R⁵⁴—

In Formula (1-5), R⁵³ and R⁵⁴ each independently represent a hydrogen atom, an alkyl group, or an aromatic hydrocarbon group, and a hydrogen atom or an alkyl group is preferable and a hydrogen atom is more preferable.

As the above-described alkyl group, an alkyl group having 1 to 10 carbon atoms is preferable, an alkyl group having 1 to 4 carbon atoms is more preferable, and a methyl group is still more preferable.

As the above-described aromatic hydrocarbon group, an aromatic hydrocarbon ring having 6 to 20 carbon atoms is preferable, and a phenyl group is more preferable.

The above-described alkyl group or the above-described aromatic hydrocarbon group may have a substituent as long as the effects of the present invention can be obtained.

In addition, the above-described aromatic hydrocarbon group may be bonded to another aromatic hydrocarbon ring or another aromatic heterocyclic ring as long as the effects of the present invention can be obtained. Examples of an aspect of the above-described bonding include a fused ring, a crosslinked ring, and a spiro ring.

—R⁵⁵—

In Formula (1-5), R⁵⁵ represents a hydrogen atom, an alkyl group having 1 to 30 carbon atoms, or an aromatic hydrocarbon group having 6 to 30 carbon atoms, and an alkyl group having 1 to 30 carbon atoms or an aromatic hydrocarbon group having 6 to 30 carbon atoms is preferable and an aromatic hydrocarbon group having 6 to 30 carbon atoms is more preferable.

As the above-described alkyl group having 1 to 30 carbon atoms, an alkyl group having 1 to 20 carbon atoms is preferable, and an alkyl group having 1 to 10 carbon atoms is more preferable.

As the above-described aromatic hydrocarbon group having 6 to 30 carbon atoms, an aromatic hydrocarbon group having 6 to 20 carbon atoms is preferable, a phenyl group or a naphthyl group is more preferable, and a phenyl group is still more preferable.

The above-described alkyl group having 1 to 30 carbon atoms or the above-described aromatic hydrocarbon group having 6 to 30 carbon atoms may have a substituent as long as the effects of the present invention can be obtained.

The repeating unit represented by Formula (1-5) is preferably a repeating unit derived from an itaconimide compound (itaconimide, N-alkylitaconimide, N-phenylitaconimide, and the like).

From the viewpoint of heat resistance, the content of the repeating unit derived from a (meth)acrylic acid or a (meth)acrylic acid ester compound in the specific resin is preferably 0 to 70 mol % with respect to the total molar amount of all repeating units included in the specific resin.

The above-described content is preferably 0 to 40 mol % and more preferably 0 to 20 mol %.

In addition, in the present invention, an aspect in which the above-described content is 0 to 1 mol % (preferably 0 to 0.5 mol % and more preferably 0 to 0.1 mol %) is also a preferred aspect.

The repeating unit derived from a (meth)acrylic acid, which may be included in the specific resin, is preferably a repeating unit represented by Formula (1-6). In addition, the repeating unit derived from a (meth)acrylic acid ester compound, which may be included in the specific resin, is preferably a repeating unit represented by Formula (1-7).

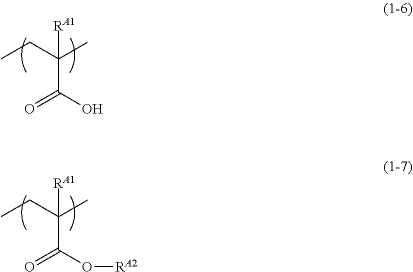

In Formula (1-6), R^{A1} represents a hydrogen atom or a methyl group, and a hydrogen atom is more preferable.

In Formula (1-7), R^{A1} represents a hydrogen atom or a methyl group, and a hydrogen atom is more preferable.

In Formula (1-7), R^{A2} is a group represented by any one of Formula (F-1), . . . , or Formula (F-5), and preferred aspects of these groups are as described above.

[Specific Substituent]

The specific resin preferably has at least one group selected from the group consisting of a hydroxy group, a carboxy group, a sulfo group, a phosphoric acid group, and an amino group, and more preferably has a hydroxy group or a carboxy group.

For example, by introducing, into the specific resin, the above-described repeating unit represented by Formula (1-1-2), the above-described repeating unit represented by Formula (1-2-2), or the like, these groups are introduced into the specific resin.

[Acid group]

From the viewpoint of improving alkali developability, the specific resin preferably has an acid group. Examples of the acid group include a phenolic hydroxy group, a carboxy group, a sulfo group, a phosphoric acid group, an active imide group, and a sulfonamide group.

From the viewpoint of improving film-forming properties and alkali developability, an acid value of the specific resin is preferably 0 to 500 mgKOH/g.

The lower limit of the above-described acid value is preferably 20 mgKOH/g or more, more preferably 30 mgKOH/g or more, and still more preferably 50 mgKOH/g or more. The upper limit of the above-described acid value is preferably 300 mgKOH/g or less, more preferably 200 mgKOH/g or less, and still more preferably 150 mgKOH/g or less. Examples of a particularly preferred aspect include an aspect in which the acid value of the specific resin is 0 to 150 mgKOH/g.

The acid value of the specific resin is calculated by the same method as a measuring method in Examples described later.

[Ethylenically Unsaturated Bond]

The specific resin preferably has an ethylenically unsaturated bond.

In addition, the specific resin preferably includes a group having an ethylenically unsaturated bond.

Examples of the group having an ethylenically unsaturated bond include an acryloyl group, an acryloyloxy group, an acrylamide group, a vinylphenyl group, and an allyl group, and from the viewpoint of reactivity, an acryloyloxy group is preferable.

For example, by introducing, into the specific resin, a repeating unit which is the above-described repeating unit represented by Formula (1-1-2) or repeating unit represented by Formula (1-2-2) and has a group represented by Formula (F-2) or Formula (F-3) described above, or the like, the group having an ethylenically unsaturated bond is introduced into the specific resin.

From the viewpoint of storage stability and curing properties, the C═C value of the specific resin is preferably 0 to 5 mmol/g.

The lower limit of the above-described C═C value is preferably 0.01 mmol/g or more, more preferably 0.03 mmol/g or more, still more preferably 0.05 mmol/g or more, and particularly preferably 0.1 mmol/g or more.

The upper limit of the above-described C═C value is preferably 3 mmol/g or less, more preferably 2 mmol/g or less, still more preferably 1.5 mmol/g or less, and particularly preferably 1 mmol/g or less.

In the present invention, the C═C value of the specific resin refers to the number of ethylenically unsaturated bonds included in 1 g of the specific resin, and is a value measured by the method in Examples described later.

[Graft Polymer and Star Polymer]

The specific resin may be any of a linear polymer, a star polymer, or a graft polymer compound. In addition, the specific resin may be a star polymer having a specific terminal group described in JP2007-277514A and the like, which has a plurality of branching points, but is preferably a graft polymer or a star polymer.

—Graft Polymer—

In a case where the specific resin is a graft polymer, the specific resin preferably has, as a graft chain, a molecular chain described later, which has a molecular weight of 500 to 10,000 and does not have an acid group and a basic group.

In addition, in a case where the specific resin is a graft polymer, the specific resin preferably has, as a main chain, a repeating unit which is represented by Formula (1-1-3) described above and has a group represented by Formula (F-4) or Formula (F-5) described above, or a repeating unit which is represented by Formula (1-2-3) described and has a group represented by Formula (F-4) or Formula (F-5) described above. In this case, it is preferable that the group represented by Formula (F-4) or Formula (F-5) is a graft chain in the graft polymer.

—Star Polymer—

In a case where the specific resin is a star polymer, the specific resin is preferably a resin represented by Formula (S-1).

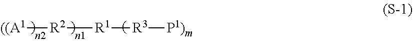

In Formula (S-1), R¹ represents an (m+n1)-valent organic linking group, R²'s each independently represent a single bond or an (n2+1)-valent linking group, A¹'s each independently represent at least one group selected from the group consisting of a hydroxy group, a carboxy group, a sulfo group, a phosphoric acid group, and an amino group, R³'s each independently represent a single bond or an (n2+1)-valent linking group, P¹'s each independently represent a polymer chain, m represents an integer of 1 to 8, n1 represents an integer of 2 to 9, m+n1 is 3 to 10, n2 is an integer of 1 or more, and the proportion of the total amount of repeating units each represented by any one of Formula (1-1), . . . , or Formula (1-5) is 10 mol % or more with respect to the total molar amount of all repeating units included in the resin represented by Formula (S-1).

—R¹—

In Formula (S-1), R¹ is preferably a group composed of 1 to 100 carbon atoms, 0 to 10 nitrogen atoms, 0 to 50 oxygen atoms, 1 to 200 hydrogen atoms, and 0 to 20 sulfur atoms, more preferably a group composed of 1 to 60 carbon atoms, 0 to 10 nitrogen atoms, 0 to 40 oxygen atoms, 1 to 120 hydrogen atoms, and 0 to 10 sulfur atoms, still more preferably a group composed of 1 to 50 carbon atoms, 0 to 10 nitrogen atoms, 0 to 30 oxygen atoms, 1 to 100 hydrogen atoms, and 0 to 7 sulfur atoms, and particularly preferably a group composed of 1 to 40 carbon atoms, 0 to 8 nitrogen atoms, 0 to 20 oxygen atoms, 1 to 80 hydrogen atoms, and 0 to 5 sulfur atoms.

—R²—

In Formula (S-1), R² is preferably a single bond or a divalent organic linking group composed of 1 to 50 carbon atoms, 0 to 8 nitrogen atoms, 0 to 25 oxygen atoms, 1 to 100 hydrogen atoms, and 0 to 10 sulfur atoms, more preferably a single bond or a divalent organic linking group composed of 1 to 30 carbon atoms, 0 to 6 nitrogen atoms, 0 to 15 oxygen atoms, 1 to 50 hydrogen atoms, and 0 to 7 sulfur atoms, and particularly preferably a single bond or a divalent organic linking group composed of 1 to 10 carbon atoms, 0 to 5 nitrogen atoms, 0 to 10 oxygen atoms, 1 to 30 hydrogen atoms, and 0 to 5 sulfur atoms.

—R³—

In Formula (S-1), R³'s are each independently preferably a single bond, —S—, or the same group as R² described above, more preferably a single bond or —S—, and particularly preferably —S—.

—P¹—

In Formula (S-1), P¹ is preferably a polymer chain including at least one repeating unit selected from the group consisting of repeating units each represented by Formulae (1-1) to (1-7), and more preferably a polymer chain including at least one repeating unit selected from the group consisting of repeating units each represented by Formulae (1-1) to (1-5), and Formula (1-7).

In addition, P¹ preferably includes the repeating unit represented by Formula (1-1-1), the repeating unit represented by Formula (1-2-1), the repeating unit represented by Formula (1-3), the repeating unit represented by Formula (1-4), or the repeating unit represented by Formula (1-5), and more preferably includes the repeating unit represented by Formula (1-1-1) or the repeating unit represented by Formula (1-2-1).

—m, n1, and n2—

In Formula (S-1), m represents an integer of 1 to 8, and is preferably 1 to 5, more preferably 1 to 4, and particularly preferably 2 to 4.

In Formula (S-1), n1 represents an integer of 2 to 9, and is preferably 2 to 8, more preferably 2 to 7, and particularly preferably 2 to 6.

In Formula (S-1), n2 represents an integer of 1 or more, and is preferably 1 or 10, more preferably 1 to 4, and still more preferably 1 or 2.

—Formula (S-2)—

The star polymer represented by Formula (S-1) is preferably a star polymer represented by Formula (S-2).

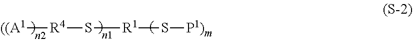

R¹, A¹, P¹, n¹, n², and m in Formula (S-2) have the same meaning as R¹, A¹, P¹, n¹, n², and m in Formula (S-1), respectively, and the preferred aspects thereof are also the same.

In Formula (S-2), R⁴—S— has the same meaning as R² in Formula (S-1), except that the bonding site with R¹ includes a sulfur atom, and the preferred aspect thereof is also the same.

[Molecular Chain]

The specific resin preferably has a molecular chain having a molecular weight of 500 to 10,000 and not having an acid group and a basic group.

The specific resin preferably has the above-described molecular chain as a branched chain.

In a case where the specific resin is a graft polymer, it is preferable that the above-described molecular chain is a graft chain, and it is more preferable that the above-described molecular chain is included as the group which is included in the repeating unit represented by Formula (1-1-3) described above and is represented by Formula (F-4) or Formula (F-5) described above, or a group which is included in the repeating unit represented by Formula (1-2-3) described and is represented by Formula (F-4) or Formula (F-5) described above.

In a case where the specific resin is a star polymer, it is preferable that the above-described molecular chain is included as P¹ in Formula (S-1) described above.

The above-described molecular chain preferably includes at least one selected from the group consisting of a repeating unit derived from a (meth)acrylic acid ester compound, a repeating unit derived from a (meth)acrylamide compound, a repeating unit derived from an aromatic vinyl compound, and a polyester structure.

As the above-described repeating unit derived from a (meth)acrylic acid ester compound, the above-described repeating unit represented by Formula (1-7) is preferable, a repeating unit which is represented by Formula (1-7) described above, in which R^{A2} is a group represented by Formula (F-1), Formula (F-2), or Formula (F-3), is more preferable, and a repeating unit which is represented by Formula (1-7) described above, in which R^{A2} is a group represented by Formula (F-1), is still more preferable.

As the above-described repeating unit derived from a (meth)acrylamide compound, the above-described repeating unit represented by Formula (1-2) is preferable, and the above-described repeating unit represented by Formula (1-2-1) is more preferable.

As the above-described repeating unit derived from an aromatic vinyl compound, the above-described repeating unit represented by Formula (1-1) is preferable, and the above-described repeating unit represented by Formula (1-1-1) is more preferable.

As the above-described polyester structure, a polyester structure represented by Formula (F-5) described above is preferable. The above-described polyester structure is preferably included in the specific resin as the repeating unit which is represented by Formula (1-1-3) described above and has the group represented by Formula (F-5), or the repeating unit which is represented by Formula (1-2-3) described and has the group represented by Formula (F-5).

The composition according to the embodiment of the present invention preferably includes, as the specific resin, at least one resin selected from the group consisting of the following resin 1 and the following resin 2, and more preferably includes the resin 1 and the resin 2.

By including the resin 1, developability of the composition is improved.

By including the resin 2, storage stability of the composition is improved.

Resin 1: a resin which is the specific resin and includes a group having an acid group and an ethylenically unsaturated bond

Resin 2: a resin which is the specific resin, has at least one group selected from the group consisting of a hydroxy group, a carboxy group, a sulfo group, a phosphoric acid group, and an amino group, and has a molecular chain having a molecular weight of 500 to 10,000 and having no acid group and basic group

In the above-described resin 1 and resin 2, the acid group, the group having an ethylenically unsaturated bond, the at least one group selected from the group consisting of a hydroxy group, a carboxy group, a sulfo group, a phosphoric acid group, and an amino group, and the molecular chain which has a molecular weight of 500 to 10,000 and does not have an acid group and a basic group are as described above.

The resin 1 may further have the above-described molecular chain.

In addition, the resin 2 may further have the above-described group having an ethylenically unsaturated bond.

[Molecular Weight]

A weight-average molecular weight (Mw) of the specific resin is preferably 5,000 to 100,000 and more preferably 10,000 to 50,000.

[Molar Absorption Coefficient]

The maximum value of the molar absorption coefficient of the specific resin at a wavelength of 400 to 1,100 nm is preferably 0 to 1,000 l/(mol·cm) and more preferably 0 to 100 l/(mol·cm).

[Heat Resistance]

The specific resin preferably has a 5 mass % reduction temperature of 280° C. or higher, more preferably 300° C. or higher, and still more preferably 320° C. or higher by a thermogravimetry/differential thermal analysis (TG/DTA) under a nitrogen atmosphere. The upper limit of the above-described 5 mass % reduction temperature is not particularly limited, and for example, it is sufficient to be 1,000° C. or lower. The 5 mass % reduction temperature is determined by a known TG/DTA measuring method as a temperature at which a mass reduction rate is 5% in a case of being allowed to stand at a specific temperature for 5 hours under a nitrogen atmosphere.

In addition, the specific resin preferably has a mass reduction rate of within 10%, more preferably 5% or less, and still more preferably 2% or less in a case of being allowed to stand at 320° C. for 3 hours under a nitrogen atmosphere. The lower limit of the above-described mass reduction rate is not particularly limited, and it is sufficient to be 0% or more.

The mass reduction rate is a value calculated as a proportion of mass reduction in the specific resin before and after being allowed to stand at 320° C. for 3 hours under a nitrogen atmosphere.

[Synthesis Method]

A method for synthesizing the specific resin is not particularly limited, and the specific resin can be synthesized by a known method. For example, the specific resin can be synthesized by the method described in Examples described later.

### Specific Example

Specific examples of the specific resin are shown below, but the present invention is not limited thereto.

In the following tables, the column of “Item 1” describes a proportion (mol %) of the total amount of repeating units represented by any one of Formula (1-1), . . . , or Formula (1-5) with respect to the total molar amount of all repeating units included in the specific resin, the column of “Item 2” describes a content (mol %) of the repeating unit derived from a (meth)acrylic acid or a (meth)acrylic acid ester compound, the column of “Acid value” describes an acid value (mgKOH/g) of the specific resin, and the column of “C═C value” describes a C═C value (mmol/g) of the specific resin.

In the following chemical formulae, x, y, z, and w represent the content ratio (mol %) of each repeating unit, and can be appropriately set within a range satisfying the item 1, the item 2, the acid value, and the C═C value.

In addition, in the following chemical formulae, for example, the description of “polymer” in (A-22) shows that a polymer chain in which a repeating unit derived from diethylacrylamide and a repeating unit derived from styrene are randomly bonded to a sulfur atom described in (A-22) at a content ratio (molar ratio) of the parenthesized subscript is bonded. The above-described molar ratio can be appropriately set within a range satisfying the item 1, the item 2, the acid value, and the C═C value.

In addition, for example, among six *'s in R of (A-34), two thereof are bonded to the structure shown in square brackets on the left side, and four thereof are bonded to the structure shown in square brackets on the right side. In addition, the description in square brackets on the right side indicates a polymer chain in which a repeating unit derived from methyl vinylbenzoate and a repeating unit derived from butyl acrylate are randomly bonded.

TABLE 1

| | Item | Item | Acid | C═C |
|---|---|---|---|---|
| Resin | 1 | 2 | value | value |
| 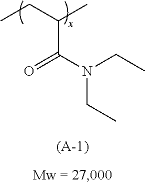 | 100 | 0 | 0 | 0 |
| 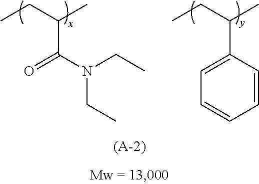 | 100 | 0 | 0 | 0 |
| 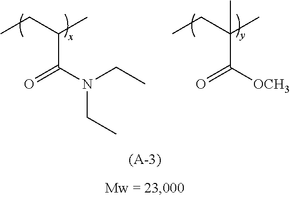 | 80 | 20 | 0 | 0 |
| 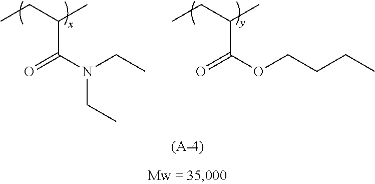 | 65 | 35 | 0 | 0 |
| 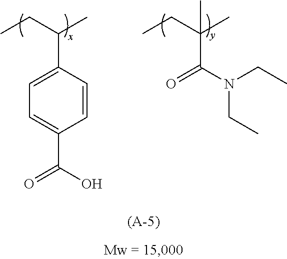 | 100 | 0 | 85 | 0 |
| 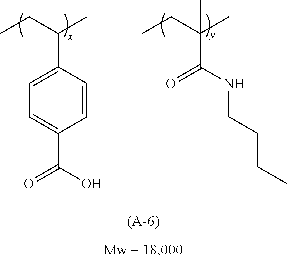 | 100 | 0 | 105 | 0 |

TABLE 2

| | Item | Item | Acid | C═C |
|---|---|---|---|---|
| Resin | 1 | 2 | value | value |
| 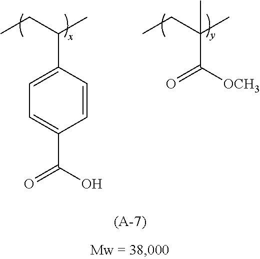 | 65 | 35 | 140 | 0 |
| 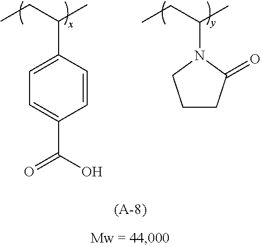 | 100 | 0 | 115 | 0 |
| 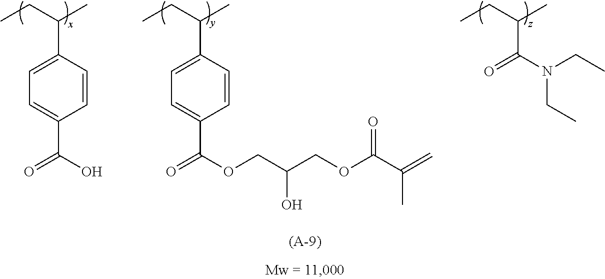 | 100 | 0 | 70 | 1.5 |
| 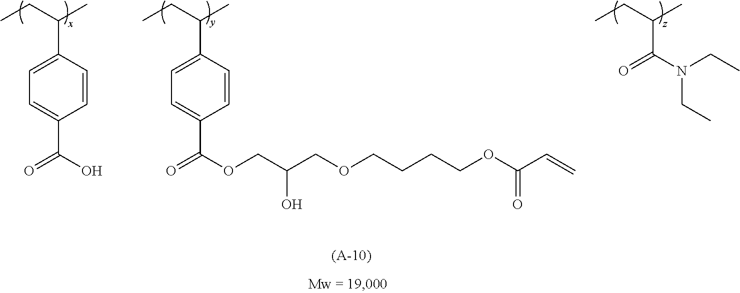 | 100 | 0 | 85 | 1.4 |
| 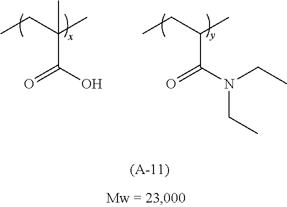 | 90 | 10 | 70 | 0 |

TABLE 3

| | Item | Item | Acid | C≡C |
|---|---|---|---|---|
| Resin | 1 | 2 | value | value |
| 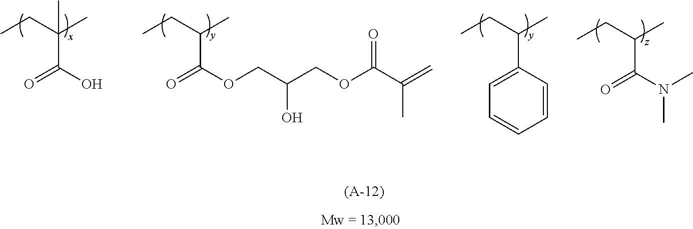 | 73 | 27 | 46 | 1.8 |
| 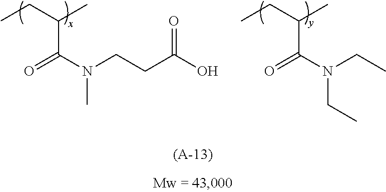 | 100 | 0 | 60 | 0 |
| 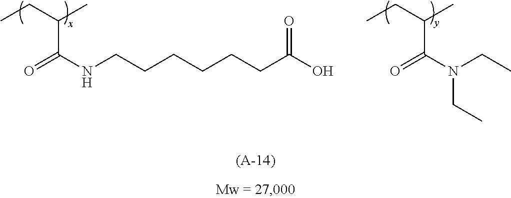 | 100 | 0 | 83 | 0 |
| 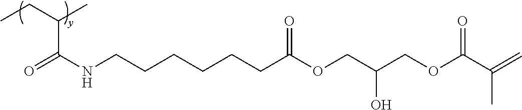 | 100 | 0 | 45 | 1.9 |
| 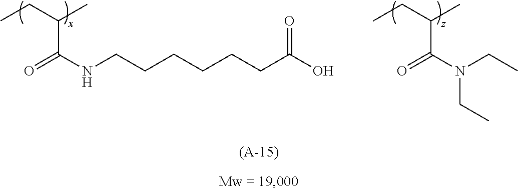 | | | | |
| 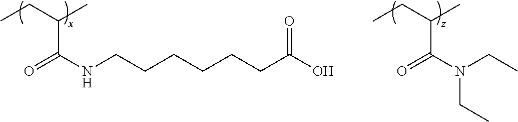 | 100 | 0 | 49 | 1.7 |
| 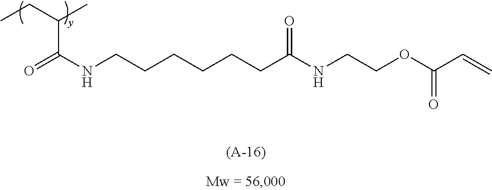 | | | | |

TABLE 4

| | Item | Item | Acid | C≡C |
|---|---|---|---|---|
| Resin | 1 | 2 | value | value |
| 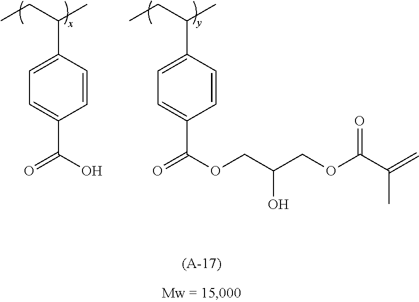 | 100 | 0 | 100 | 2.2 |
| 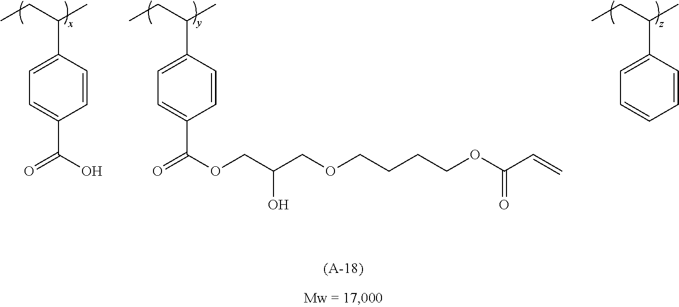 | 100 | 0 | 70 | 1.3 |
| 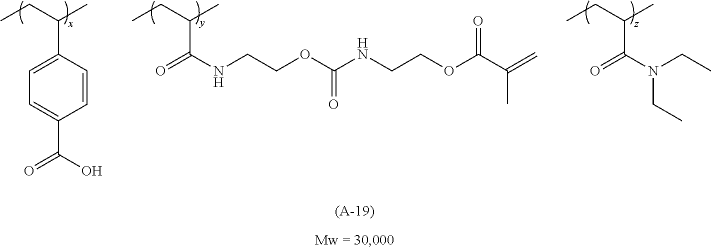 | 100 | 0 | 38 | 1.0 |
| 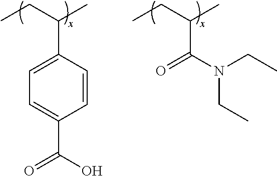 | 85 | 15 | 46 | 0 |
| 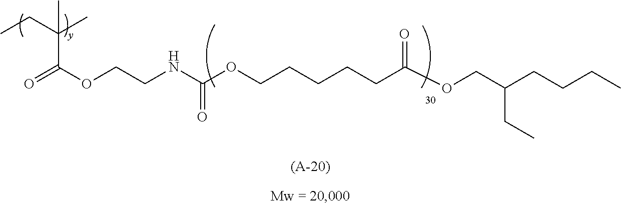 | | | | |

TABLE 5

| | Item | Item | Acid | C≡C |
|---|---|---|---|---|
| Resin | 1 | 2 | value | value |
| 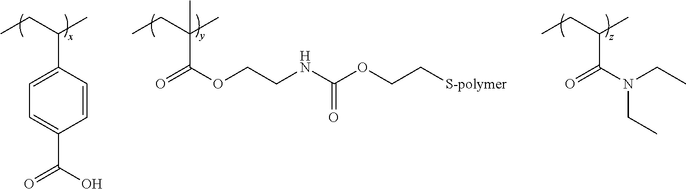 | 68 | 32 | 60 | 0 |
| 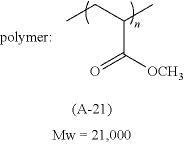 | | | | |
| 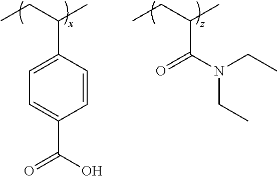 | 87 | 13 | 30 | 0 |
| 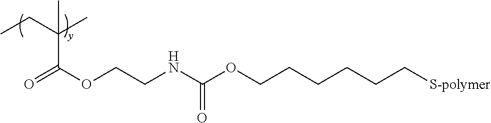 | | | | |
| 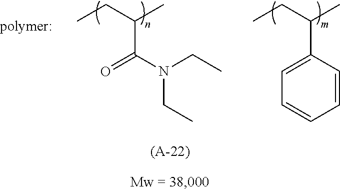 | | | | |
| 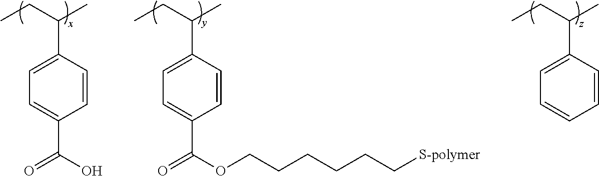 | 100 | 0 | 89 | 0 |
| 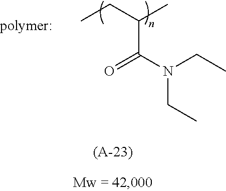 | | | | |

TABLE 6

| | Item | Item | Acid | C═C |
|---|---|---|---|---|
| Resin | 1 | 2 | value | value |
| 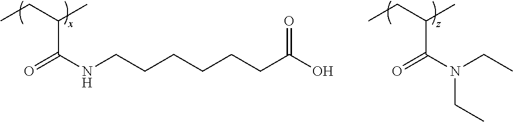 | 100 | 0 | 48 | 0 |
| 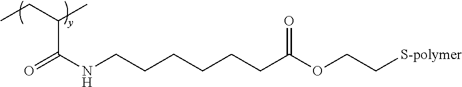 | | | | |
| 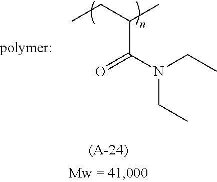 | | | | |
| 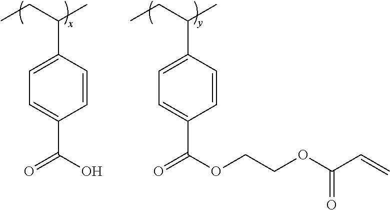 | 90 | 10 | 70 | 0.7 |
| 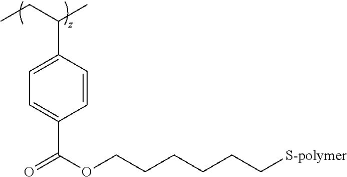 | | | | |
| 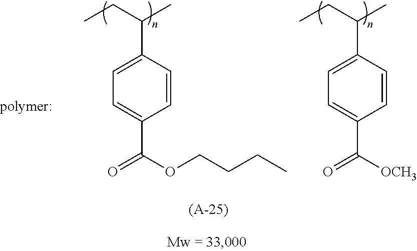 | | | | |

TABLE 7

| | Item | Item | Acid | C═C |
|---|---|---|---|---|
| Resin | 1 | 2 | value | value |
| 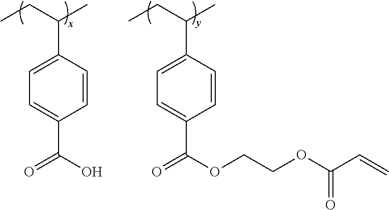 | 95 | 5 | 76 | 0.6 |
| 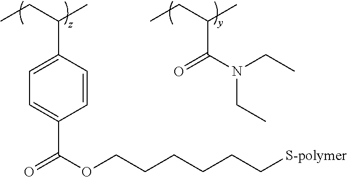 | | | | |
| 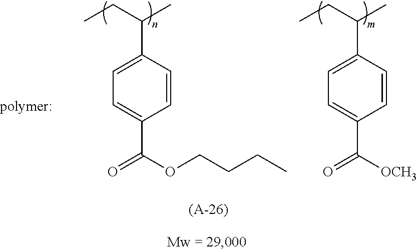 | | | | |
| 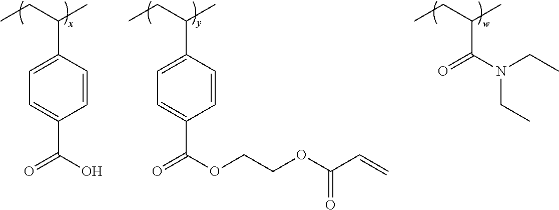 | 100 | 0 | 50 | 0.5 |
| 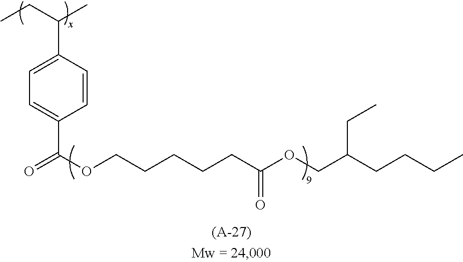 | | | | |

TABLE 8

| | Item | Item | Acid | C═C |
|---|---|---|---|---|
| Resin | 1 | 2 | value | value |
| 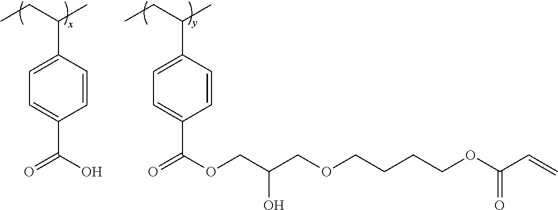 | 100 | 0 | 57 | 0.5 |
| 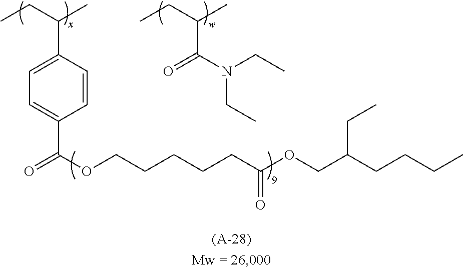 | | | | |
| 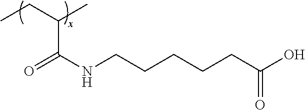 | 100 | 0 | 29 | 0.3 |
| 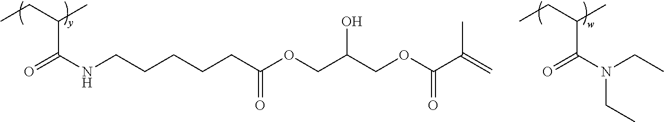 | | | | |
| 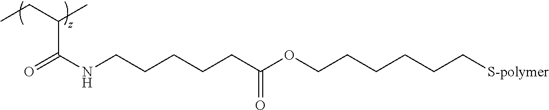 | | | | |
| 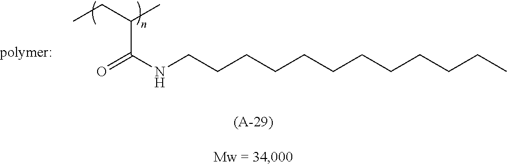 | | | | |

TABLE 9

| | Item | Item | Acid | C═C |
|---|---|---|---|---|
| Resin | 1 | 2 | value | value |
| 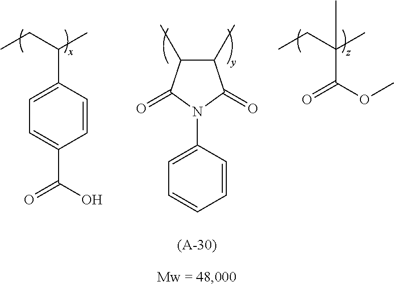 | 85 | 15 | 120 | 0 |
| 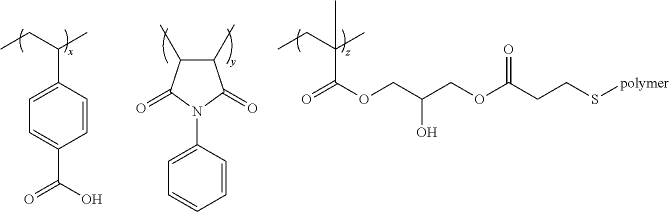 | 87 | 13 | 66 | 0 |
| 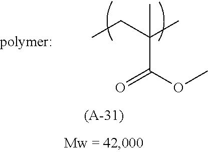 | | | | |
| 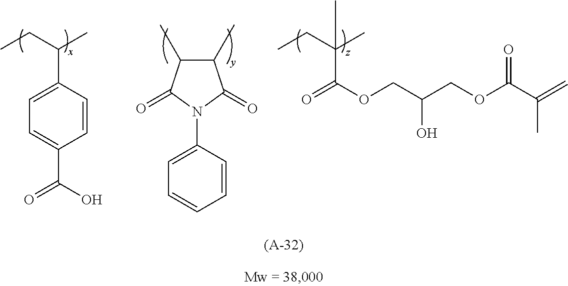 | 81 | 19 | 91 | 1.8 |
| 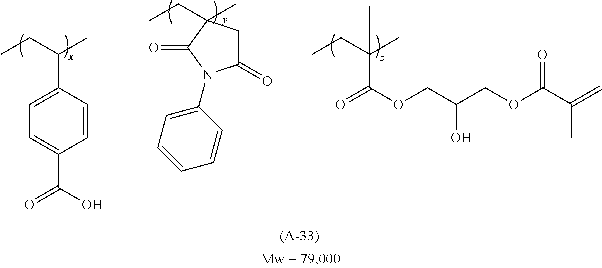 | 78 | 22 | 77 | 1.2 |

TABLE 10

| | Item | Item | Acid | C═C |
|---|---|---|---|---|
| Resin | 1 | 2 | value | value |
| 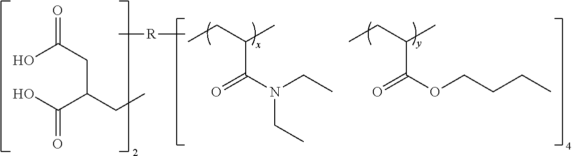 | 61 | 39 | 22 | 0 |
| 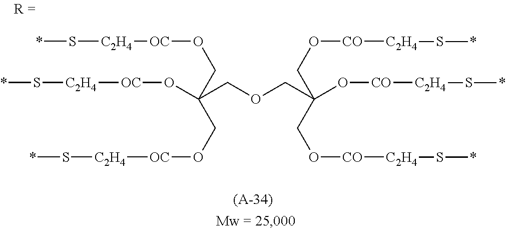 | | | | |
| 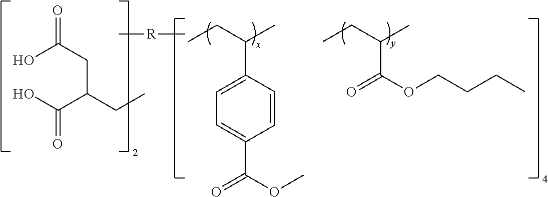 | 90 | 10 | 24 | 0 |
| 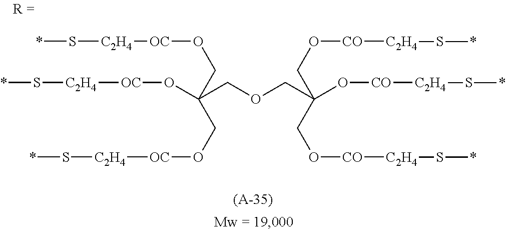 | | | | |
| 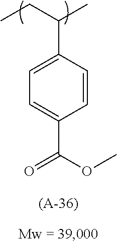 | 100 | 0 | 0 | 0 |

TABLE 11

| | Item | Item | Acid | C═C |
|---|---|---|---|---|
| Resin | 1 | 2 | value | value |
| 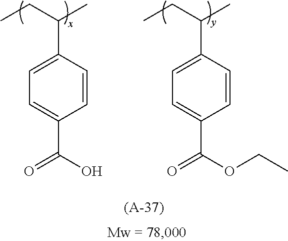 | 100 | 0 | 90 | 0 |
| 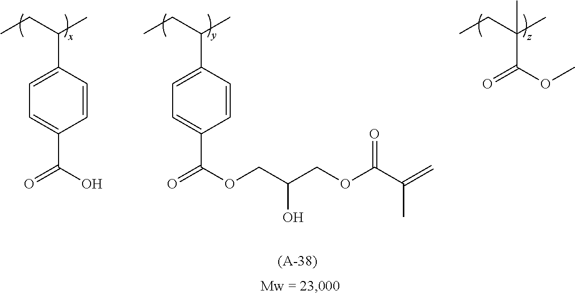 | 95 | 5 | 65 | 1.9 |
| 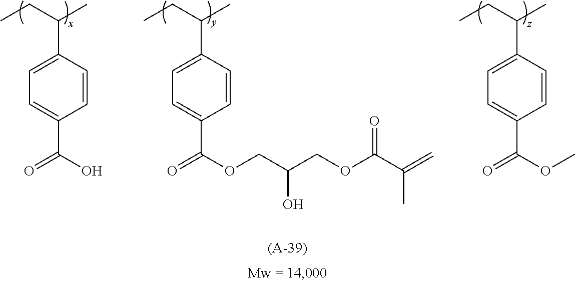 | 100 | 0 | 50 | 2.0 |
| 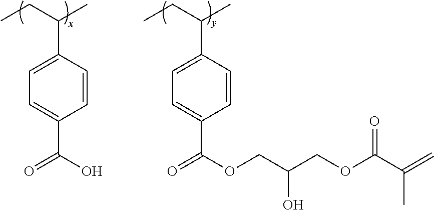 | 85 | 15 | 50 | 0.7 |
| 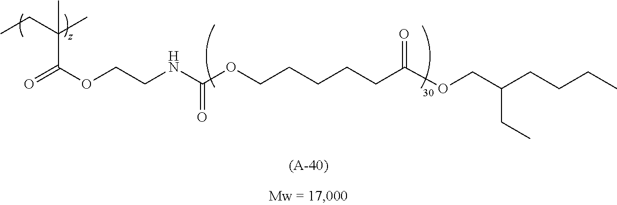 | | | | |

TABLE 12

| | Item | Item | Acid | C═C |
|---|---|---|---|---|
| Resin | 1 | 2 | value | value |
| 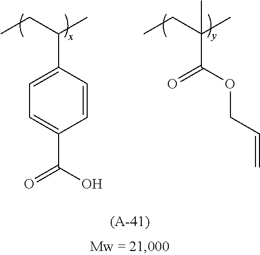 | 50 | 50 | 205 | 3.6 |
| 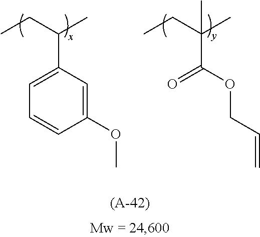 | 40 | 60 | 0 | 4.6 |
| 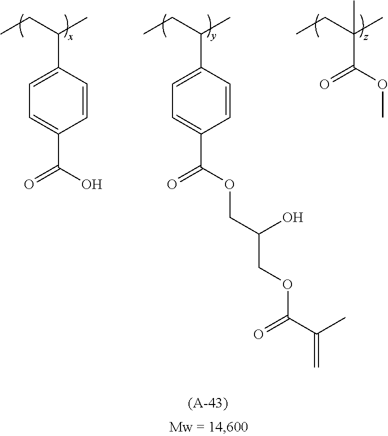 | 70 | 30 | 26 | 2.7 |
| 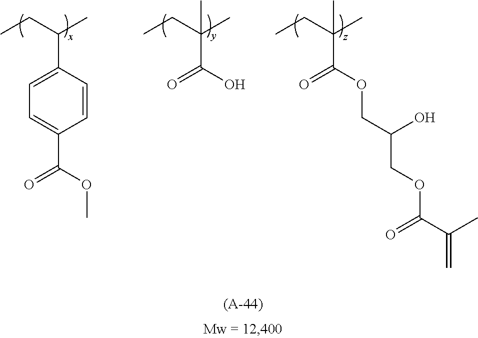 | 50 | 50 | 48 | 2.0 |

TABLE 13

| | Item | Item | Acid | C═C |
|---|---|---|---|---|
| Resin | 1 | 2 | value | value |
| 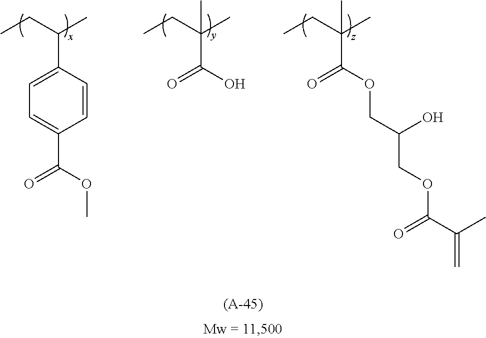 | 30 | 70 | 62 | 2.8 |
| 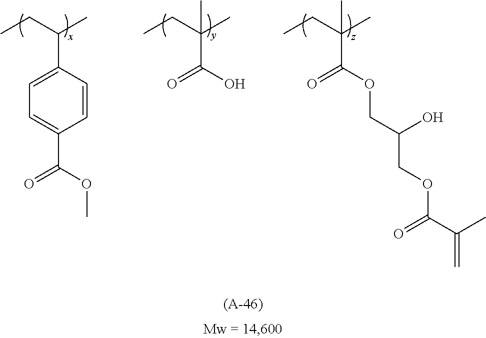 | 10 | 90 | 94 | 3.4 |
| 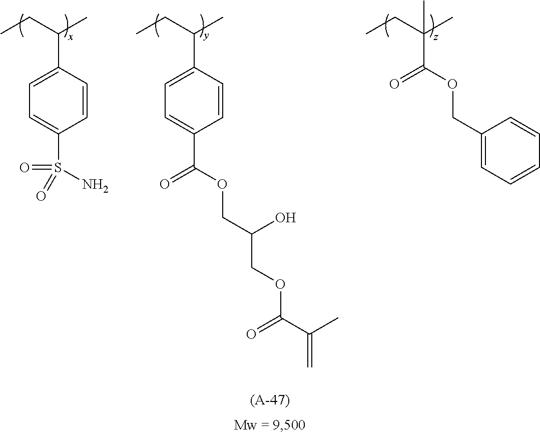 | 50 | 50 | 53 | 1.4 |
| 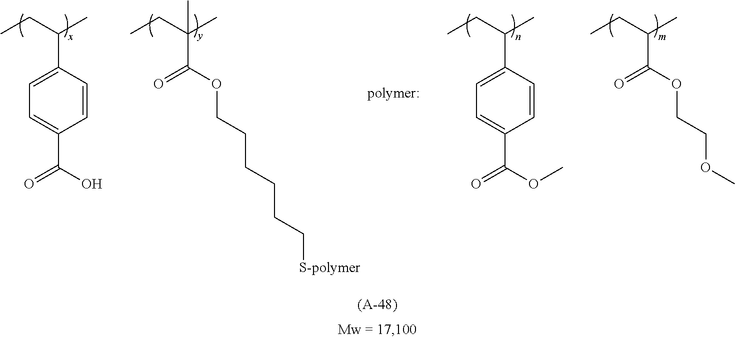 | 70 | 30 | 65 | 0 |

[Content]

A content of the specific resin in the composition according to the embodiment of the present invention is preferably 10 to 95 mass % with respect to the total solid content of the composition. The lower limit is more preferably 20 mass % or more and still more preferably 30 mass % or more. The upper limit is more preferably 90 mass % or less and still more preferably 85 mass % or less.

The composition according to the embodiment of the present invention may include the specific resin alone or in combination of two or more kinds thereof. In a case where two or more kinds of specific resins are used in combination, the total amount thereof is preferably within the above-described range.

In addition, in a case where the composition according to the embodiment of the present invention includes the above-described resin 1 as the specific resin, a content of the resin 1 is preferably 1 to 30 mass % with respect to the total solid content of the composition. The lower limit is more preferably 3 mass % or more and still more preferably 5 mass % or more. The upper limit is more preferably 25 mass % or less and still more preferably 20 mass % or less.

In addition, in a case where the composition according to the embodiment of the present invention includes the above-described resin 2 as the specific resin, a content of the resin 2 is preferably 10 to 60 mass % with respect to the total solid content of the composition. The lower limit is more preferably 15 mass % or more and still more preferably 20 mass % or more. The upper limit is more preferably 55 mass % or less and still more preferably 50 mass % or less.

In addition, in a case where the composition according to the embodiment of the present invention includes the above-described resin 2 as the specific resin and includes the pigment as the colorant, the content of the resin 2 is preferably 25 to 85 mass % with respect to the total mass of the pigment included in the composition. The lower limit is more preferably 28 mass % or more and still more preferably 30 mass % or more. The upper limit is more preferably 80 mass % or less and still more preferably 50 mass % or less.

In addition, in the present invention, in components in which the colorant is excepted from the total solid content of the composition, the specific resin is included preferably in an amount of 20 mass % or more, more preferably in an amount of 30 mass % or more, and still more preferably in an amount of 40 mass % or more. The upper limit may be 100 mass %, 90 mass % or less, or 85 mass % or less. In a case where the content of the specific resin is within the above-described range, it is easy to form a film having excellent heat resistance, and it is easy to suppress film contraction after heating. Further, in a case where an inorganic film is formed on a surface of the film obtained using the composition according to the embodiment of the present invention, it is also possible to suppress the occurrence of cracks in the inorganic film even in a case where this laminate is exposed to a high temperature.

In addition, the total content of the colorant and the specific resin described above in the total solid content of the composition is preferably 25 to 100 mass %. The lower limit is more preferably 30 mass % or more and still more preferably 40 mass % or more. The upper limit is more preferably 90 mass % or less and still more preferably 80 mass % or less.

<Other Resins>

The composition according to the embodiment of the present invention may include other resins.

A compound corresponding to the specific resin does not correspond to the above-described other resins.

In a case where the composition according to the embodiment of the present invention includes other resins, it is preferable that the proportion of the total amount of repeating units each represented by any one of Formula (1-1), . . . , or Formula (1-5) with respect to the total molar amount of all repeating units included in all resin components included in the composition according to the embodiment of the present invention is 10 mol % or more. The above-described proportion of the total amount is preferably 60 mol % or more, more preferably 70 mol % or more, and still more preferably 80 mol % or more. The upper limit is not particularly limited, and it is sufficient to be 100 mol % or less.

Examples of the other resins include a resin having alkali developability and a resin as a dispersant.

Here, in a case where the composition according to the embodiment of the present invention includes other resins, the aspect shown in the following (1) or the following (2) is also preferable.

(1) the above-described resin 1 and the resin as a dispersant are included.

(2) the resin having alkali developability and the above-described resin 2 are included.

In addition, in the aspect of (1), the above-described resin 2 may be further included, and in the aspect of (2), the above-described resin 1 may be further included.

[Resin Having Alkali Developability]

A weight-average molecular weight (Mw) of the resin having alkali developability is preferably 3,000 to 2,000,000. The upper limit is more preferably 1,000,000 or less and still more preferably 500,000 or less. The lower limit is more preferably 4,000 or more and still more preferably 5,000 or more.

Examples of the resin having alkali developability include a (meth)acrylic resin, a polyimine resin, a polyether resin, a polyolefin resin, a cyclic olefin resin, a polyester resin, and a styrene resin, and a (meth)acrylic resin or a polyimine resin is preferable and a (meth)acrylic resin is more preferable. In addition, as the other resin, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, and resins described in JP2017-066240A can also be used.

In addition, as the resin having alkali developability, it is preferable to use a resin having an acid group. According to this aspect, developability of the composition can be further improved. Examples of the acid group include a phenolic hydroxy group, a carboxy group, a sulfo group, a phosphoric acid group, a phosphonic acid group, an active imide group, and a sulfonamide group, and a carboxy group is preferable. The resin having an acid group can be used, for example, as an alkali-soluble resin.

The resin having an acid group preferably includes a repeating unit having an acid group in the side chain, and more preferably includes 1 to 70 mol % of repeating units having an acid group in the side chain with respect to the total repeating units of the resin. The upper limit of the content of the repeating unit having an acid group in the side chain is preferably 50 mol % or less and more preferably 40 mol % or less. The lower limit of the content of the repeating unit having an acid group in the side chain is preferably 2 mol % or more and more preferably 5 mol % or more.

An acid value of the resin having an acid group is preferably 200 mgKOH/g or less, more preferably 150 mgKOH/g or less, still more preferably 120 mgKOH/g or less, and particularly preferably 100 mgKOH/g or less. In addition, the acid value of the resin having an acid group is preferably 5 mgKOH/g or more, more preferably 10 mgKOH/g or more, and still more preferably 20 mgKOH/g or more.

The resin having an acid group also preferably has an ethylenically unsaturated bond-containing group. Examples of the ethylenically unsaturated bond-containing group include a vinyl group, an allyl group, and a (meth)acryloyl group, and an allyl group or a (meth)acryloyl group is preferable and a (meth)acryloyl group is more preferable.

The resin having an ethylenically unsaturated bond-containing group preferably includes a repeating unit having an ethylenically unsaturated bond-containing group in the side chain, and more preferably includes 5 to 80 mol % of the repeating unit having an ethylenically unsaturated bond-containing group in the side chain with respect to the total repeating units of the resin. The upper limit of the content of the repeating unit having an ethylenically unsaturated bond-containing group in the side chain is preferably 60 mol % or less and more preferably 40 mol % or less. The lower limit of the content of the repeating unit having an ethylenically unsaturated bond-containing group in the side chain is preferably 10 mol % or more and more preferably 15 mol % or more.

It is also preferable that the resin having alkali developability includes a repeating unit derived from a monomer component including a compound represented by Formula (ED1) and/or a compound represented by Formula (ED2) (hereinafter, these compounds may be referred to as an “ether dimer”).

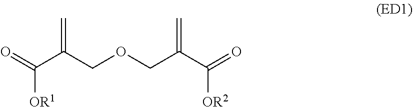

In Formula (ED1), R¹ and R² each independently represent a hydrogen atom or a hydrocarbon group having 1 to 25 carbon atoms, which may have a substituent.

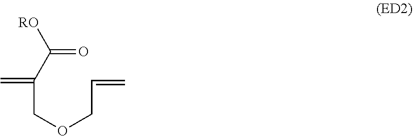

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

It is also preferable that the resin having alkali developability includes a repeating unit derived from a compound represented by Formula (X).

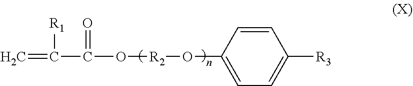

In Formula (X), R₁ represents a hydrogen atom or a methyl group. R₂ represents an alkylene group having 2 to 10 carbon atoms, and R₃ represents a hydrogen atom or an alkyl group having 1 to 20 carbon atoms which may include a benzene ring. n represents an integer of 1 to 15.

Examples of the resin having an acid group include resins having the following structures. In the following structural formulae, Me represents a methyl group.

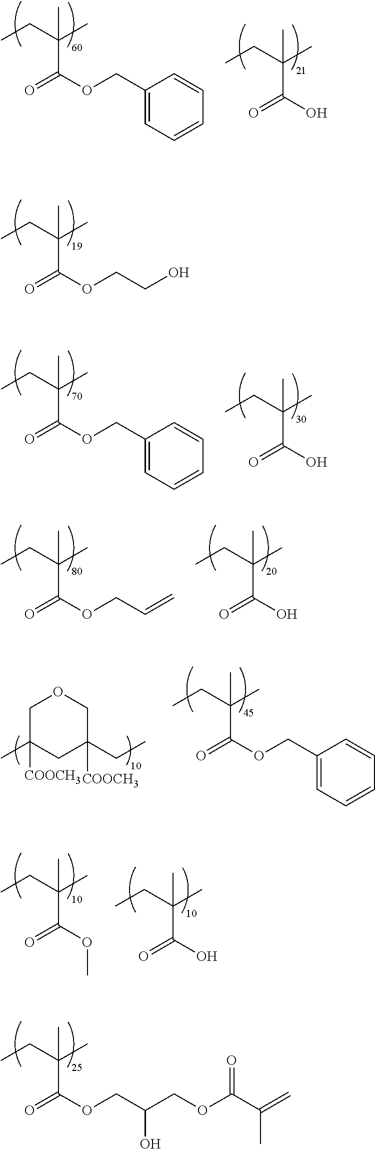

[Dispersant]

The composition according to the embodiment of the present invention can also include the resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxy group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a repeating unit having an acid group.

It is also preferable that the resin used as a dispersant is a graft resin. Examples of the graft resin include resins described in paragraph Nos. 0025 to 0094 of JP2012-255128A, the contents of which are incorporated herein by reference.

It is also preferable that the resin used as a dispersant is a polyimine-based dispersant (polyimine resin) including a nitrogen atom in at least one of the main chain or the side chain. As the polyimine-based dispersant, a resin having a main chain which has a partial structure having a functional group of pKa14 or less, and a side chain which has 40 to 10,000 atoms, in which at least one of the main chain or the side chain has a basic nitrogen atom, is preferable. The basic nitrogen atom is not particularly limited as long as it is a nitrogen atom exhibiting basicity. Examples of the polyimine-based dispersant include resins described in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

A commercially available product is also available as the dispersant, and specific examples thereof include DISPERBYK series (for example, DISPERBYK-111, 161, and the like) manufactured by BYK Chemie, and Solsperse series (for example, Solsperse 36000) manufactured by Lubrizol Corporation. In addition, pigment dispersants described in paragraph Nos. 0041 to 0130 of JP2014-130338A can also be used, the contents of which are incorporated herein by reference. In addition, as the dispersant, compounds described in JP2018-150498A, JP2017-100116A, JP2017-100115A, JP2016-108520A, JP2016-108519A, and JP2015-232105A may be used.

The resin described as a dispersant can be used for an application other than the dispersant. For example, the resin can also be used as a binder.

A content of the total resin component in the total solid content of the composition is preferably 10 to 95 mass %. The lower limit is more preferably 20 mass % or more and still more preferably 30 mass % or more. The upper limit is more preferably 90 mass % or less and still more preferably 85 mass % or less.

In addition, in the composition, the content of the other resins described above is preferably 230 parts by mass or less, more preferably 200 parts by mass or less, and still more preferably 150 parts by mass or less with respect to 100 parts by mass of the above-described specific resin. The lower limit may be 0 part by mass, 5 parts by mass or more, or 10 parts by mass or more. In addition, it is also preferable that the composition does not substantially include the above-described other resins. According to this aspect, it is easy to form a film having more excellent heat resistance. The case where the composition does not substantially include the other resins means that the content of the other resins in the total solid content of the composition is 0.1 mass % or less, preferably 0.05 mass % or less, and more preferably 0 mass %.

<Solvent>

The composition according to the embodiment of the present invention includes a solvent. Basically, the solvent is not particularly limited as long as it satisfies the solubility of the respective components and the application properties of the composition, but an organic solvent is preferable. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph No. 0223 of WO2015/166779A, the contents of which are incorporated herein by reference. In addition, an ester-based solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, 3-butoxy-N,N-dimethylpropanamide, y-butyrolactone, and N-methyl-2-pyrrolidone. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015). Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms but having a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the organic solvent in the composition is preferably 10 to 95 mass %, more preferably 20 to 90 mass %, and still more preferably 30 to 90 mass %.

<Polymerizable Compound>

It is preferable that the composition according to the embodiment of the present invention includes a polymerizable compound. The polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. A molecular weight of the polymerizable compound is preferably 100 to 3.000. The upper limit is more preferably 2,000 or less and still more preferably 1,500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.). ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E. A-GLY-20E. A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in a non-exposed portion is easily removed during development and the generation of the development residue can be suppressed. Examples of the acid group include a carboxy group, a sulfo group, and a phosphoric acid group, and a carboxy group is preferable. Examples of a commercially available product of the polymerizable compound having an acid group include ARONIX M-305, M-510, M-520, and ARONIX TO-2349 (manufactured by TOAGOSEI CO., LTD.). An acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330, manufactured by Nippon Kayaku Co., Ltd., which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600, AI-600, and LINC-202UA (manufactured by KYOEISHA CHEMICAL Co., Ltd.) can also be used.

In a case of including a polymerizable compound, the content of the polymerizable compound in the total solid content of the composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof.

<Polymerization Initiator>

The composition according to the embodiment of the present invention preferably includes a polymerization initiator. As the polymerization initiator, a photopolymerization initiator is preferable. The photopolymerization initiator is not particularly limited, and can be appropriately selected from known photopolymerization initiators. For example, a compound having photosensitivity to rays in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton, a compound having an oxadiazole skeleton, a compound having an imidazole skeleton, and the like), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a biimidazole compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from a biimidazole compound, an oxime compound, an α-hydroxyketone compound, an α-aminoketone compound, or an acylphosphine compound is more preferable, and an oxime compound is still more preferable. Examples of the photopolymerization initiator include compounds described in paragraphs 0065 to 0111 of JP2014-130173A, and JP6301489B, the contents of which are incorporated herein by reference.

Examples of the biimidazole compound include 2,2-bis(2-chlorophenyl)-4,4′,5,5′-tetraphenylbiimidazole, 2,2′-bis(o-chlorophenyl)-4,4′,5,5-tetrakis(3,4,5-trimethoxyphenyl)-1,2′-biimidazole, 2,2′-bis(2,3-dichlorophenyl)-4,4′,5,5′-tetraphenylbiimidazole, and 2,2′-bis (o-chlorophenyl)-4,4,5,5′-tetraphenyl-1,2′-biimidazole. Examples of a commercially available product of the α-hydroxyketone compound include Omnirad 184, Omnirad 1173, Omnirad 2959, and Omnirad 127 (all of which are manufactured by 1GM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), and Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin ii (1979, pp. 1653-1660), the compounds described in J. C. S. Perkin II (1979, pp. 156-162), the compounds described in Journal of Photopolymer Science and Technology (1995. pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

In addition, as the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

As the photopolymerization initiator, an oxime compound in which a substituent having a hydroxy group is bonded to a carbazole skeleton can also be used. Examples of such a photopolymerization initiator include compounds described in WO2019/088055A.

An oxime compound having a nitro group can be used as the photopolymerization initiator. It is preferable that the oxime compound having a nitro group is a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

Specific examples of the oxime compound are shown below, but the present invention is not limited thereto.

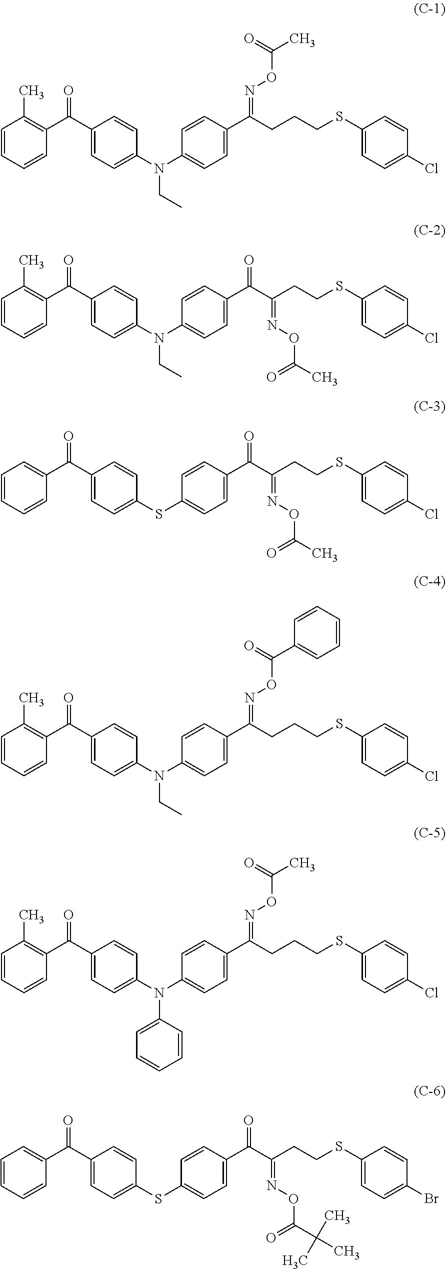 [SMILES: CCN(c1ccc(C(=O)c2ccccc2C)cc1)c1ccc(/C(CCCSc2ccc(Cl)cc2)=N/OC(C)=O)cc1 ; CCN(c1ccc(C(=O)/C(CCSc2ccc(Cl)cc2)=N/OC(C)=O)cc1)c1ccc(C(=O)c2ccccc2C)cc1 ; CC(=O)O/N=C(\CCSc1ccc(Cl)cc1)C(=O)c1ccc(Sc2ccc(C(=O)c3ccccc3)cc2)cc1 ; CCN(c1ccc(C(=O)c2ccccc2C)cc1)c1ccc(/C(CCCSc2ccc(Cl)cc2)=N/OC(=O)c2ccccc2)cc1 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

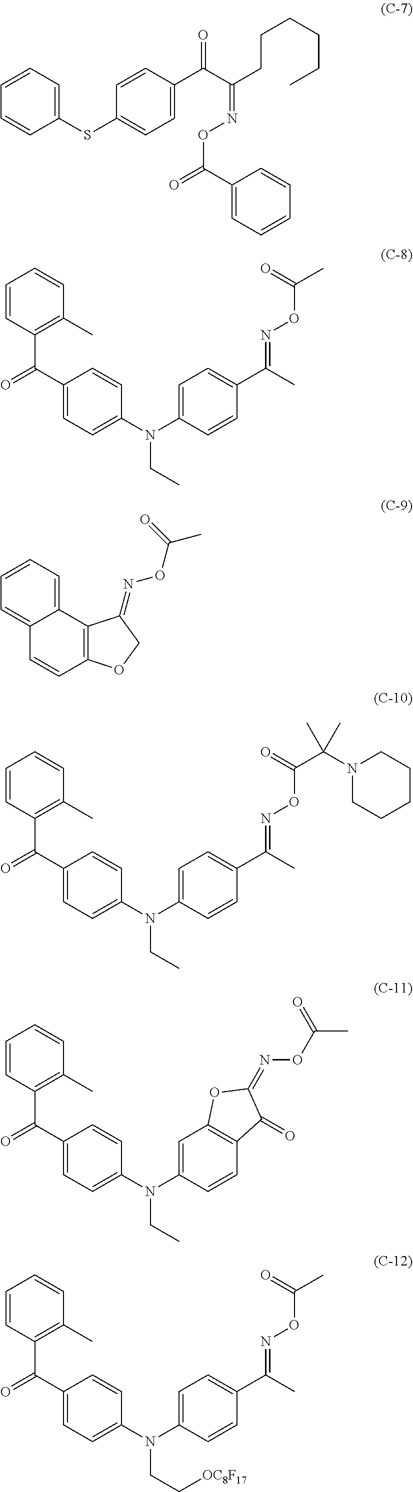

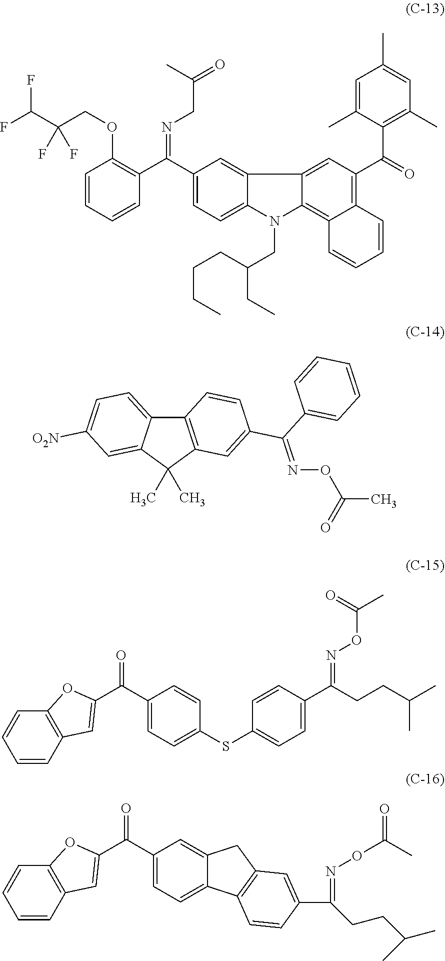 [SMILES: CCCCC(CC)Cn1c2ccc(/C(=N\CC(C)=O)c3ccccc3OCC(F)(F)C(F)F)cc2c2cc(C(=O)c3c(C)cc(C)cc3C)c3ccccc3c21 ; CC(=O)O/N=C(\c1ccccc1)c1ccc2c(c1)C(C)(C)c1cc([N+](=O)[O-])ccc1-2 ; CC(=O)O/N=C(\CCC(C)C)c1ccc(Sc2ccc(C(=O)c3cc4ccccc4o3)cc2)cc1 ; CC(=O)O/N=C(\CCC(C)C)c1ccc2c(c1)Cc1cc(C(=O)c3cc4ccccc4o3)ccc1-2]

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1,000 to 300,000, still more preferably 2,000 to 300,000, and particularly preferably 5,000 to 200,000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case where a compound having an asymmetric structure is used, crystallinity is reduced, solubility in a solvent or the like is improved, and the compound is hardly precipitated over time, and the temporal stability of the composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime compound described in JP6469669B.

In a case of including a photopolymerization initiator, the content of the photopolymerization initiator in the total solid content of the composition is preferably 0.1 to 30 mass %. The lower limit is preferably 0.5 mass % or more and more preferably 1 mass % or more. The upper limit is preferably 20 mass % or less and more preferably 15 mass % or less. The photopolymerization initiator may be used singly or in combination of two or more kinds thereof.

<Compound Having Cyclic Ether Group>

The composition according to the embodiment of the present invention can include a compound having a cyclic ether group. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound two or more epoxy groups in one molecule is preferable. It is preferable to have 1 to 100 epoxy groups in one molecule. The upper limit of the number of epoxy groups may be, for example, 10 or less or 5 or less. The lower limit of the number of epoxy groups is preferably 2 or more. As the compound having a cyclic ether group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, the compounds described in JP2017-179172A, and the compounds described in JP2019-133052A can also be used. The contents of the publications are incorporated herein by reference.

The compound having an epoxy group may be either a low-molecular-weight compound (for example, having a molecular weight of less than 2.000, and further, a molecular weight of less than 1,000) or a high-molecular-weight compound (macromolecule) (for example, having a molecular weight of 1,000 or more, and in a case of a polymer, having a weight-average molecular weight of 1,000 or more). A weight-average molecular weight of the compound having an epoxy group is preferably 200 to 100,000 and more preferably 500 to 50,000. The upper limit of the weight-average molecular weight is preferably 10,000 or less, more preferably 5,000 or less, and still more preferably 3,000 or less.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. An epoxy equivalent of the epoxy resin is preferably 310 to 3,300 g/eq, more preferably 310 to 1,700 g/eq, and still more preferably 310 to 1,000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

In a case where the composition according to the embodiment of the present invention includes a compound having a cyclic ether group, the content of the compound having a cyclic ether group in the total solid content of the composition is preferably 0.1 to 20 mass %. The lower limit is, for example, preferably 0.5 mass % or more and more preferably 1 mass % or more. The upper limit is, for example, preferably 15 mass % or less and still more preferably 10 mass % or less. The compound having a cyclic ether group may be used singly or in combination of two or more kinds thereof. In a case of using two or more kinds thereof, the total amount thereof is preferably within the above-described range.

<Silane Coupling Agent>

The composition according to the embodiment of the present invention may include a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof.

<Curing Accelerator>

For the purpose of promoting the reaction of the resin and the polymerizable compound and lowering the curing temperature, the composition according to the embodiment of the present invention can further include a curing accelerator. As the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used.

In a case where the composition according to the embodiment of the present invention includes a curing accelerator, the content of the curing accelerator is preferably 0.3 to 8.9 mass % and more preferably 0.8 to 6.4 mass % with respect to the total solid content of the composition.

<Polymerization Inhibitor>

The composition according to the embodiment of the present invention can include a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. The content of the polymerization inhibitor in the total solid content of the composition is preferably 0.0001 to 5 mass %.

<Surfactant>

The composition according to the embodiment of the present invention can include a surfactant. As the surfactant, various surfactants such as a fluorine-based surfactant, a nonionic surfactant, a cationic surfactant, an anionic surfactant, or a silicon-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By including a fluorine-based surfactant in the composition, liquid characteristics (particularly, fluidity) are further improved, and liquid saving properties can be further improved. In addition, it is possible to form a film with a small thickness unevenness.

The fluorine content in the fluorine-based surfactant is suitably 3 to 40 mass %, and more preferably 5 to 30 mass % and particularly preferably 7% to 25 mass %. The fluorine-based surfactant in which the fluorine content is within the above-described range is effective from the viewpoint of the uniformity in the thickness of the coating film and liquid saving properties, and the solubility in the composition is also excellent.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.), SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

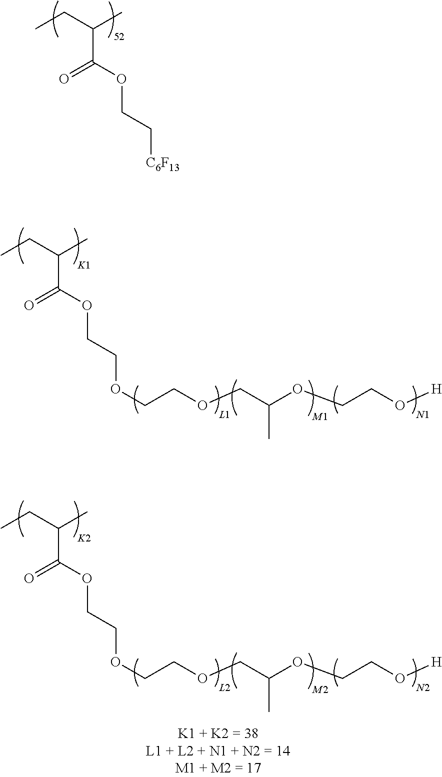

In the above-described structural formulae, the parenthesized subscript indicating a repeating unit described in the main chain represents a content ratio (molar ratio) of each repeating unit, and the subscript of an alkyleneoxy group described in the side chain represents the repetition number of each alkyleneoxy group.

A weight-average molecular weight of the compounds is preferably 3,000 to 50,000, and is, for example, 14.000. In the compound. “%” representing the proportion of a repeating unit is mol %.

In addition, as the fluorine-based surfactant, a fluorine-containing polymer having an ethylenically unsaturated bond-containing group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

The content of the surfactant in the total solid content of the composition is preferably 0.001 mass % to 5.0 mass % and more preferably 0.005 to 3.0 mass %. The surfactant may be used singly or in combination of two or more kinds thereof. In a case of using two or more kinds thereof, the total amount thereof is preferably within the above-described range.

<Ultraviolet Absorber>

The composition according to the embodiment of the present invention can include an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. The content of the ultraviolet absorber in the total solid content of the composition is preferably 0.01 to 10 mass % and more preferably 0.01 to 5 mass %. The ultraviolet absorber may be used singly or in combination of two or more kinds thereof. In a case where two or more kinds thereof are used, it is preferable that the total amount thereof is within the above-described range.

<Antioxidant>

The composition according to the embodiment of the present invention can include an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. The content of the antioxidant in the total solid content of the composition is preferably 0.01 to 20 mass % and more preferably 0.3 to 15 mass %. The antioxidant may be used singly or in combination of two or more kinds thereof. In a case where two or more kinds thereof are used, it is preferable that the total amount thereof is within the above-described range.

<Other Components>

Optionally, the composition according to the embodiment of the present invention may further contain a sensitizer, a filler, a thermal polymerization initiator such as an azo-based compound and a peroxide-based compound, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the composition may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation). In addition, as described in JP2018-155881A, C. I. Pigment Yellow 129 may be added for the purpose of improving weather fastness.

In addition, a thermosetting agent can be added to increase the degree of curing of the film by post-heating after development. Examples of the thermosetting agent include a thermal polymerization initiator such as an azo compound and a peroxide, a novolac resin, a resole resin, an epoxy compound, and a styrene compound.

In order to adjust the refractive index of the obtained film, the composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The composition according to the embodiment of the present invention may include a light-resistance improver. Examples of the light-resistance improver include the compounds described in paragraph Nos. 0036 and 0037 of JP2017-198787A, the compounds described in paragraph Nos 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP201l-145668A, and the compounds described in paragraph Nos. 0103 to 0153 of JP2011-253174A.

In the composition according to the embodiment of the present invention, the content of liberated metal which is not bonded to or coordinated with a pigment or the like is preferably 100 ppm or less, more preferably 50 ppm or less, and still more preferably 10 ppm or less, it is particularly preferable to not contain the liberated metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe. Cr, Co, Mg, Al, Sn, Zr, Ga, Ge. Ag, Au, Pt, Cs, Ni, Cd, Pb, and Bi. In addition, in the composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F. Cl, Br, I, and anions thereof. Examples of a method for reducing liberated metals and halogens in the composition include washing with ion exchange water, filtration, ultrafiltration, and purification with an ion exchange resin.

It is also preferable that the composition according to the embodiment of the present invention does not substantially include terephthalic acid ester. Here, the “does not substantially include” means that the content of terephthalic acid ester is 1,000 mass ppb or less in the total amount of the composition, and it is more preferable to be 100 mass ppb or less and particularly preferable to be 0.

<Viscosity>

For example, in a case where a film is formed by coating, a viscosity (23° C.) of the composition according to the embodiment of the present invention is preferably 1 to 100 mPa·s. The lower limit is more preferably 2 mPa·s or more and still more preferably 3 mPa·s or more. The upper limit is more preferably 50 mPa·s or less, still more preferably 30 mPa·s or less, and particularly preferably 15 mPa·s or less.

<Storage Container>

A storage container of the composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A. In addition, for the purpose of preventing metal elution from the container interior wall, improving storage stability of the composition, and suppressing the alteration of components, it is also preferable that the container interior wall is formed of glass, stainless steel, or the like.

<Method for Preparing Composition>

The composition according to the embodiment of the present invention can be prepared by mixing the above-described components. During the preparation of the composition, all the components may be dissolved and/or dispersed in an organic solvent at the same time to prepare the composition. Optionally, two or more solutions or dispersion liquids in which the respective components are appropriately blended may be prepared, and the solutions or dispersion liquids may be mixed with each other during use (during application) to prepare the composition.

In addition, in the preparation of the composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department. Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the composition, it is preferable that the composition is filtered through a filter, for example, in order to remove foreign matters or to reduce defects. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha, Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

(Film and Cured Film)

A film according to an embodiment of the present invention is a film obtained from the composition according to the embodiment of the present invention.

A cured film according to an embodiment of the present invention is a cured film obtained by curing the composition according to the embodiment of the present invention.

The film according to the embodiment of the present invention or the cured film according to the embodiment of the present invention can be preferably used as a near-infrared transmitting filter. The film according to the embodiment of the present invention or the cured film according to the embodiment of the present invention may have a pattern, or may be a film (flat film) not having a pattern. In addition, the film according to the embodiment of the present invention or the cured film according to the embodiment of the present invention may be used in a state of being laminated on a support, or the film according to the embodiment of the present invention or the cured film according to the embodiment of the present invention may be used in a state of being peeled off from a support. Examples of the support include a semiconductor base material such as a silicon substrate, and a transparent base material.

A charge coupled device (CCD), a complementary metal-oxide semiconductor (CMOS), a transparent conductive film, or the like may be formed on the semiconductor base material used as the support. In addition, a black matrix which separates pixels from each other may be formed on the semiconductor base material. In addition, optionally, an undercoat layer may be provided on the semiconductor base material to improve adhesiveness with a layer above the semiconductor base material, to prevent diffusion of materials, or to make a surface of the substrate flat.

The transparent base material used as the support is not particularly limited as long as it is formed of a material which can allow transmission of at least visible light. Examples thereof include a base material formed of a material such as glass and resin. Examples of the resin include polyester resins such as polyethylene terephthalate and polybutylene terephthalate, polyolefin resins such as polyethylene, polypropylene, and ethylene vinyl acetate copolymer, norbornene resin, acrylic resins such as polyacrylate and polymethylmethacrylate, urethane resin, vinyl chloride resin, fluororesin, polycarbonate resin, polyvinyl butyral resin, and polyvinyl alcohol resin. Examples of the glass include soda lime glass, borosilicate glass, non-alkali glass, quartz glass, and copper-containing glass. Examples of the copper-containing glass include a phosphate glass containing copper and a fluorophosphate glass containing copper. As the copper-containing glass, a commercially available product may also be used. Examples of a commercially available product of the copper-containing glass include NF-50 (manufactured by AGC Techno Glass Co., Ltd.).

A thickness of the film according to the embodiment of the present invention or the cured film according to the embodiment of the present invention can be appropriately adjusted according to the purpose. The thickness of the film of the cured film is preferably 20 μm or less, more preferably 10 μm or less, and still more preferably 5 μm or less. The lower limit of the thickness of the film or the cured film is preferably 0.1 μm or more and more preferably 0.2 μm or more.

In the film according to the embodiment of the present invention or the cured film according to the embodiment of the present invention, it is preferable that Amin/B, which is a ratio of a minimum value Amin of an absorbance in a wavelength range of 400 to 640 nm to an absorbance B of the above-described composition at a wavelength of 1,500 nm, is 5 or more. The value of Amin/B described above is preferably 10 or more, more preferably 15 or more, and still more preferably 30 or more.

It is more preferable that the film according to the embodiment of the present invention or the cured film according to the embodiment of the present invention satisfies spectral characteristics of any one of (1C) to (4C) below.

(1C): Amin1/Bmax1, which is a ratio of a minimum value Amin1 of an absorbance in a wavelength range of 400 to 640 nm to a maximum value Bmax1 of an absorbance in a wavelength range of 800 to 1,500 nm, is 5 or more, preferably 7.5 or more, more preferably 15 or more, and still more preferably 30 or more. According to this aspect, for example, it is possible to form a film or a cured film capable of shielding light in the wavelength range of 400 to 640 nm and transmitting near-infrared ray at a wavelength of more than 670 nm.

(2C): Amin2/Bmax2, which is a ratio of a minimum value Amin2 of an absorbance in a wavelength range of 400 to 750 nm to a maximum value Bmax2 of an absorbance in a wavelength range of 900 to 1,500 nm, is 5 or more, preferably 7.5 or more, more preferably 15 or more, and still more preferably 30 or more. According to this aspect, for example, it is possible to form a film or a cured film capable of shielding light in the wavelength range of 400 to 750 nm and transmitting near-infrared ray at a wavelength of more than 850 nm.

(3C): Amin3/Bmax3, which is a ratio of a minimum value Amin3 of an absorbance in a wavelength range of 400 to 830 nm to a maximum value Bmax3 of an absorbance in a wavelength range of 1,000 to 1,500 nm, is 5 or more, preferably 7.5 or more, more preferably 15 or more, and still more preferably 30 or more. According to this aspect, for example, it is possible to form a film or a cured film capable of shielding light in the wavelength range of 400 to 830 nm and transmitting near-infrared ray at a wavelength of more than 940 nm.

(4C): Amin4/Bmax4, which is a ratio of a minimum value Amin4 of an absorbance in a wavelength range of 400 to 950 nm to a maximum value Bmax4 of an absorbance in a wavelength range of 1,100 to 1,500 nm, is 5 or more, preferably 7.5 or more, more preferably 15 or more, and still more preferably 30 or more. According to this aspect, for example, it is possible to form a film or a cured film capable of shielding light in the wavelength range of 400 to 950 nm and transmitting near-infrared ray at a wavelength of more than 1.040 nm.

In addition, in the film according to the embodiment of the present invention or the cured film according to the embodiment of the present invention, it is preferable that the film satisfies spectral characteristics that the maximum value of light transmittance in the wavelength range of 400 to 640 nm in a thickness direction of the film is 20% or less, and the minimum value of light transmittance in a wavelength range of 1.200 to 1,500 nm in the thickness direction of the film is 70% or more. The maximum value in the wavelength range of 400 to 640 nm is more preferably 15% or less and still more preferably 10% or less. The lower limit thereof is not particularly limited, and it is sufficient to be 0% or more. The minimum value in the wavelength range of 1,200 to 1,500 nm is more preferably 75% or more and still more preferably 80% or more. The upper limit thereof is not particularly limited, and it is sufficient to be 100% or less.

In addition, it is more preferable that the film according to the embodiment of the present invention or the cured film according to the embodiment of the present invention satisfies spectral characteristics of any one of (1D) to (4D) below.

(1D): aspect in which the maximum value of light transmittance in a wavelength range of 400 to 640 nm in a thickness direction of the film or the cured film is 20% or less (preferably 15% or less and more preferably 10% or less), and the minimum value of light transmittance in a wavelength range of 800 to 1,500 nm in the thickness direction of the film or the cured film is 70% or more (preferably 75% or more and more preferably 80% or more)

(2D): aspect in which the maximum value of light transmittance in a wavelength range of 400 to 750 nm in a thickness direction of the film or the cured film is 20% or less (preferably 15% or less and more preferably 10% or less), and the minimum value of light transmittance in a wavelength range of 900 to 1,500 nm in the thickness direction of the film or the cured film is 70% or more (preferably 75% or more and more preferably 80% or more)

(3D): aspect in which the maximum value of light transmittance in a wavelength range of 400 to 830 nm in a thickness direction of the film or the cured film is 20% or less (preferably 15% or less and more preferably 10% or less), and the minimum value of light transmittance in a wavelength range of 1,000 to 1,500 nm in the thickness direction of the film or the cured film is 70% or more (preferably 75% or more and more preferably 80% or more)

(4D): aspect in which the maximum value of light transmittance in a wavelength range of 400 to 950 nm in a thickness direction of the film or the cured film is 20% or less (preferably 15% or less and more preferably 10% or less), and the minimum value of light transmittance in a wavelength range of 1,100 to 1,500 nm in the thickness direction of the film or the cured film is 70% or more (preferably 75% or more and more preferably 80% or more)

In the film according to the embodiment of the present invention or the cured film according to the embodiment of the present invention, a wavelength of the film or the cured film indicating a light transmittance of 50% in a thickness direction of the film or the cured film is preferably 700 to 950 nm, more preferably 700 to 900 nm, still more preferably 700 to 850 nm, and particularly preferably 700 to 800 nm.

In addition, in the film according to the embodiment of the present invention or the cured film according to the embodiment of the present invention, it is preferable that the minimum value of a light transmittance in the thickness direction of the film or the cured film in a wavelength range of 950 to 1,300 nm is 90% or more, it is more preferable that the minimum value of a light transmittance in the thickness direction of the film or the cured film in a wavelength range of 900 to 1,300 nm is 90% or more, it is still more preferable that the minimum value of a light transmittance in the thickness direction of the film or the cured film in a wavelength range of 850 to 1,300 nm is 90% or more, and it is particularly preferable that the minimum value of a light transmittance in the thickness direction of the film or the cured film in a wavelength range of 800 to 1,300 nm is 90% or more.

Among these, an aspect described in the following (S1) is preferable, and an aspect described in the following (S2) is more preferable.

(S1) wavelength of the film or the cured film indicating a light transmittance of 50% in a thickness direction of the film or the cured film is 700 to 950 nm, and the minimum value of a light transmittance of the film or the cured film in a wavelength range of 950 to 1,300 nm is 90% or more.

(S2) wavelength of the film or the cured film indicating a light transmittance of 50% in a thickness direction of the film or the cured film is 700 to 800 nm, and the minimum value of a light transmittance of the film in a wavelength range of 800 to 1,300 nm is 90% or more.

The film according to the embodiment of the present invention or the cured film according to the embodiment of the present invention can be used for various devices such as a solid-state imaging element such as a charge coupled device (CCD) and a complementary metal oxide semiconductor (CMOS), and an infrared sensor.

(Method for Manufacturing Film)

A method for manufacturing the film according to the embodiment of the present invention preferably includes a step (applying step) of applying the composition according to the embodiment of the present invention to a support to obtain a film formed from the composition.

<Applying Step>

The applying step is a step of applying the composition according to the embodiment of the present invention to a support to obtain a film formed from the composition.

Examples of the support are as described above.

Examples of a method for applying the composition include coating. As a coating method, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A.

In addition, it is also possible to adopt a method of transferring a coating film formed in advance by applying the composition according to the embodiment of the present invention to a temporary support by the above-described applying method.

For example, production methods described in paragraphs 0036 to 0051 of JP2006-023696A, paragraphs 0096 to 0108 of JP2006-047592A, or the like can be also suitably used in the present invention.

The film formed by applying the composition may be dried (pre-baked). In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 seconds to 3,000 seconds, more preferably 40 seconds to 2,500 seconds, and still more preferably 80 seconds to 220 seconds. Drying can be performed using a hot plate, an oven, or the like.

(Method for Manufacturing Cured Film)

<First Aspect>

A manufacturing method according to a first aspect of a method for manufacturing the cured film according to the embodiment of the present invention includes a step (curing step) of curing a film formed from the composition according to the embodiment of the present invention by at least one of exposure or heating.

In addition, the manufacturing method according to the first aspect of the method for manufacturing the cured film according to the embodiment of the present invention preferably includes, before the curing step, a step (applying step) of applying the composition according to the embodiment of the present invention to a support to obtain a film formed from the composition.

In a case where the method for manufacturing the cured film according to the embodiment of the present invention includes the applying step, the film formed from the composition, which is obtained in the applying step, is cured in the curing step to obtain a cured film.

The first aspect of the method for manufacturing the cured film according to the embodiment of the present invention is preferably a method for manufacturing a cured film (flat film) not having a pattern.

[Curing Step]

The curing step is a step of curing a film formed from the composition according to the embodiment of the present invention by at least one of exposure or heating, and is preferably a step of curing the film formed from the composition according to the embodiment of the present invention by exposure.

In addition, the curing step is preferably a step of curing the entire film formed from the composition according to the embodiment of the present invention.

—Exposure—

In the first aspect of the method for manufacturing the cured film according to the embodiment of the present invention, in a case of performing exposure, the exposure is preferably performed to the entire surface of the film formed from the composition according to the embodiment of the present invention.

Examples of a radiation (light) which can be used during the exposure in the curing step include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable.

In addition, in a case of exposure, the film formed from the composition according to the embodiment of the present invention may be irradiated with light continuously to expose the film formed from the composition according to the embodiment of the present invention, or the film formed from the composition according to the embodiment of the present invention may be irradiated with light in a pulse to expose the film formed from the composition according to the embodiment of the present invention (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. In addition, the upper limit of the maximum instantaneous illuminance is preferably 1,000,000,000 W/m² or less, more preferably 800,000,000 W/m² or less, and still more preferably 500,000,000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation amount (exposure amount) is, for example, preferably 0.03 to 2.5 J/cm² and more preferably 0.05 to 1.0 J/cm².

The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air.

In addition, the exposure illuminance can be appropriately set, and usually, can be selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

—Heating—

In the first aspect of the method for manufacturing the cured film according to the embodiment of the present invention, in a case of performing heating, the film formed from the composition according to the embodiment of the present invention may be heated without exposure, may be heated during exposure, may be heated before exposure, or may be heated after exposure, but it is preferable to heat without exposure or to heat after exposure, and from the viewpoint of further curing, it is more preferable to heat after exposure.

A heating unit is not particularly limited, and a known heating unit such as a hot plate, a convection oven (hot air circulation dryer), and a high frequency heater can be used.

The heating temperature is, for example, preferably 100° C. to 240° C., and more preferably 200° C. to 240° C.

The heating time is, for example, preferably 3 minutes to 180 minutes, and more preferably 5 minutes to 120 minutes.

[Applying Step]

The applying step according to the first aspect of the method for manufacturing the cured film according to the embodiment of the present invention is the same as the applying step in the method for manufacturing the film according to the embodiment of the present invention described above, and the preferred aspect thereof is also the same.

<Second Aspect>

A manufacturing method according to a second aspect of the method for manufacturing the cured film according to the embodiment of the present invention includes an exposing step of exposing a part of the film formed from the composition and a developing step of developing the film after exposure.

The manufacturing method according to the second aspect of the method for manufacturing the cured film according to the embodiment of the present invention is preferably a method for manufacturing a cured film having a pattern.

Such a patterning method including the exposing step and the developing step is also referred to as a photolithography method.

The exposing step and the developing step in the second aspect of the method for manufacturing the cured film according to the embodiment of the present invention can be performed according to a known photolithography method. One aspect of the photolithography method will be described below.

[Exposing Step]

In the exposing step, a part of the film formed from the composition is exposed.

Examples of the method of exposing a part of the above-described film include a method of exposing the film through a mask having a predetermined mask pattern using a stepper exposure device or a scanner exposure device.

An exposed portion can be cured by the above-described exposure.

Exposure conditions such as radiation (light), irradiation amount (exposure amount), and oxygen concentration, which can be used for exposure, are the same as those exposure conditions according to the first aspect of the method for manufacturing the cured film according to the embodiment of the present invention described above, and the preferred aspects thereof are also the same.

In addition, the exposure in the exposing step may be the pulse exposure described above.

[Developing Step]

In the developing step, the non-exposed portion of the film formed from the composition after exposure is removed by development to form a pattern (pixel).

The non-exposed portion of the film formed from the composition can be removed by development using a developer. Thus, the film formed from the composition of the non-exposed portion in the exposing step is eluted into the developer, and as a result, only an exposed part remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkali agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle jetting the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

[Other Steps]

The manufacturing method according to the second aspect of the method for manufacturing the cured film according to the embodiment of the present invention preferably includes, before the exposing step, a step (applying step) of applying the composition according to the embodiment of the present invention to a support to obtain a film formed from the composition.

In a case of including the applying step, the film formed from the composition, which is obtained in the applying step, is exposed in the exposing step, and developed in the developing step to obtain a cured film.

In addition, the manufacturing method according to the second aspect of the method for manufacturing the cured film according to the embodiment of the present invention also preferably includes, after the developing step, an additional exposure treatment or a heating treatment (post-baking) after drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

<Third Aspect>

A manufacturing method according to a third aspect of the method for manufacturing the cured film according to the embodiment of the present invention preferably includes a step (curing step) of curing the film formed from the composition according to the embodiment of the present invention by at least one of exposure or heating to obtain a cured composition layer, a step (photoresist layer forming step) of forming a photoresist layer on the cured composition layer, a step (resist pattern forming step) of forming a resist pattern from the photoresist layer, and a step (dry etching step) of dry-etching the cured composition layer using the resist pattern as a mask using an etching gas.

The manufacturing method according to the third aspect of the method for manufacturing the cured film according to the embodiment of the present invention is preferably a method for manufacturing a cured film having a pattern.

The curing step in the manufacturing method according to the third aspect of the method for manufacturing the cured film according to the embodiment of the present invention can be performed by the same method as the curing step in the first aspect described above, and the preferred aspect thereof is also the same.

Details of the photoresist layer forming step, the resist pattern forming step, and the dry etching step can be found in paragraph Nos. 0010 to 0067 of JP2013-064993A, the content of which is incorporated herein by reference.

In addition, the manufacturing method according to the third aspect of the method for manufacturing the cured film according to the embodiment of the present invention preferably includes, before the curing step, a step (applying step) of applying the composition according to the embodiment of the present invention to a support to obtain a film formed from the composition. The applying step can be performed by the same method as the applying step in the first aspect described above, and the preferred aspect thereof is also the same.

In a case of including the applying step, the film formed from the composition, which is obtained in the applying step, is cured in the curing step, and through the photoresist layer forming step and the resist pattern forming step, patterned in the dry etching step to obtain a cured film.

It is preferable that pre-baking treatment is further performed in order to form the photoresist layer. In particular, as the forming process of the photoresist layer, it is desirable that a heating treatment after exposure and a heating treatment after development (post-baking treatment) are performed.

(Near-Infrared Transmitting Filter)

A near-infrared transmitting filter according to an embodiment of the present invention includes the film according to the embodiment of the present invention or the cured film according to the embodiment of the present invention described above. The cured film according to the embodiment of the present invention may include one layer or two or more layers. In a case where the cured film according to the embodiment of the present invention includes two or more layers, these layers may be adjacent to each other, or the cured film according to the embodiment of the present invention may include another layer therebetween.

The near-infrared transmitting filter according to the embodiment of the present invention can also be used in combination with a color filter including a chromatic colorant. The color filter can be manufactured using a coloring composition including a chromatic colorant. Examples of the chromatic colorant include the chromatic colorant described for the composition according to the embodiment of the present invention. The coloring composition can further contain, for example, a resin, a polymerizable compound, a photopolymerization initiator, a surfactant, a solvent, a polymerization inhibitor, and an ultraviolet absorber. With regard to these details, the materials described for the composition according to the embodiment of the present invention can be mentioned, each of which can be used.

In addition, it is also preferable that the near-infrared transmitting filter according to the embodiment of the present invention includes a pixel of the film according to the embodiment of the present invention or the cured film according to the embodiment of the present invention, and a pixel selected from the group consisting of a red pixel, a green pixel, a blue pixel, a magenta pixel, a yellow pixel, a cyan pixel, a black pixel, and an achromatic pixel.

(Solid-State Imaging Element)

A solid-state imaging element according to an embodiment of the present invention includes the film according to the embodiment of the present invention or the cured film according to the embodiment of the present invention described above. The cured film according to the embodiment of the present invention may include one layer or two or more layers. In a case where the cured film according to the embodiment of the present invention includes two or more layers, these layers may be adjacent to each other, or the cured film according to the embodiment of the present invention may include another layer therebetween. A configuration of the solid-state imaging element according to the embodiment of the present invention is not particularly limited as long as the solid-state imaging element is configured to include the film according to the embodiment of the present invention or the cured film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a support such as a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have the film according to the embodiment of the present invention or the cured film according to the embodiment of the present invention on the device-protective film. Further, the solid-state imaging element may also be configured, for example, such that it has a light collecting unit (for example, a microlens, which is the same hereinafter) on the device-protective film under the film according to the embodiment of the present invention or the cured film according to the embodiment of the present invention (a side closer to the support), or has a light collecting unit on the film according to the embodiment of the present invention or the cured film according to the embodiment of the present invention. In addition, the color filter may have a structure in which a film which forms each pixel is embedded in a space which is partitioned in, for example, a lattice form by a partition wall. In this case, it is preferable that the partition wall has a lower refractive index than each pixel. Examples of an imaging device having such a structure include the devices described in JP2012-227478A, JP2014-179577A, WO2018/043654A, and US2018/0040656A. An imaging device including the solid-state imaging element according to the embodiment of the present invention can also be used as a vehicle camera or a surveillance camera, in addition to a digital camera or electronic apparatus (mobile phones or the like) having an imaging function.

The solid-state imaging element incorporating the film according to the embodiment of the present invention or the cured film according to the embodiment of the present invention may incorporate another color filter, a near-infrared cut filter, a near-infrared transmitting filter, an organic photoelectric conversion film, or the like in addition to the film according to the embodiment of the present invention or the cured film according to the embodiment of the present invention.

(Infrared Sensor)

An infrared sensor according to an embodiment of the present invention includes the film according to the embodiment of the present invention or the cured film according to the embodiment of the present invention described above. The cured film according to the embodiment of the present invention may include one layer or two or more layers. In a case where the cured film according to the embodiment of the present invention includes two or more layers, these layers may be adjacent to each other, or the cured film according to the embodiment of the present invention may include another layer therebetween. The configuration of the infrared sensor is not particularly limited as long as it functions as an infrared sensor. Hereinafter, an embodiment of the infrared sensor according to the present invention will be described using the drawings.

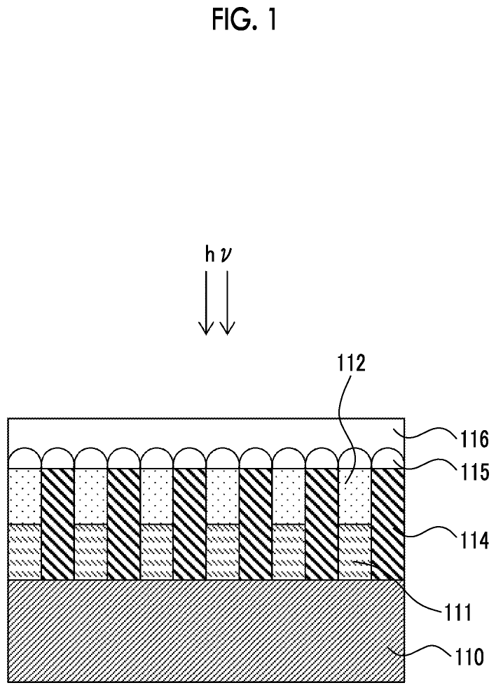

In FIG. 1, reference numeral 110 represents a solid-state imaging element. Near-infrared cut filters 111 and near-infrared transmitting filters 114 are arranged in an imaging region of the solid-state imaging element 110. In addition, color filters 112 are arranged on the near-infrared cut filters 111. A microlens 115 is disposed on an incidence ray hv side of the color filters 112 and the near-infrared transmitting filters 114. A planarizing layer 116 is formed so as to cover the microlenses 115.

Spectral characteristics of the near-infrared cut filter 111 can be selected according to an emission wavelength of an infrared light emitting diode (infrared LED) to be used.

The color filter 112 is not particularly limited as long as pixels which allow transmission of light having a specific wavelength in a visible range and absorbs the light are formed therein, and known color filters in the related art for forming a pixel can be used. For example, pixels of red (R), green (G), and blue (B) are formed in the color filters. For example, details of the color filters can be found in paragraph Nos. 0214 to 0263 of JP2014-043556A, the content of which is incorporated herein by reference.

As the near-infrared transmitting filter 114, the film according to the embodiment of the present invention, the cured film according to the embodiment of the present invention, or the near-infrared transmitting filter according to the embodiment of the present invention can be used.

Characteristics of the near-infrared transmitting filter 114 can be selected according to the emission wavelength of the infrared LED to be used. For example, in a case where the emission wavelength of the infrared LED is 850 nm, the near-infrared transmitting filter 114 preferably has 15% or less of a maximum value of the light transmittance in the thickness direction of the film in a wavelength range of 400 to 640 nm, more preferably has 20% or less thereof, and still more preferably has 10% or less thereof. It is preferable that the transmittance satisfies the above-described conditions in the entire range of the wavelength range of 400 to 640 nm.

In addition, the near-infrared transmitting filter 114 preferably has 70% or more of a minimum value of the light transmittance in the thickness direction of the film in a wavelength range of 800 nm or more (preferably 800 to 1,500 nm), more preferably 75% or more thereof, and still more preferably 80% or more thereof. The above-described transmittance preferably satisfies the above-described conditions in a part of the wavelength range of 800 nm or more, and more preferably satisfies the above-described conditions at a wavelength corresponding to the emission wavelength of the infrared LED.

A film thickness of the near-infrared transmitting filter 114 is preferably 100 μm or less, more preferably 15 μm or less, still more preferably 5 μm or less, and particularly preferably 1 μm or less. The lower limit value is preferably 0.1 μm. In a case where the film thickness is within the above-described range, a film satisfying the above-described spectral characteristics can be obtained.

A method for measuring spectral characteristics, film thickness, and the like of the near-infrared transmitting filter 114 is as follows.

The film thickness is measured by using a stylus type surface shape measuring device (DEKTAK150 manufactured by ULVAC, Inc.) on a dried substrate having the film.

The spectral characteristics of the film are values obtained by measuring the transmittance in a wavelength range of 300 to 1,500 nm using an ultraviolet-visible-near infrared spectrophotometer (U-4100 manufactured by Hitachi High-Tech Corporation).

In addition, for example, in a case where the emission wavelength of the infrared LED is 940 nm, the near-infrared transmitting filter 114 preferably has 20% or less of a maximum value of the light transmittance in the thickness direction of the film in a wavelength range of 450 to 640 nm, and it is preferable that the light transmittance in the thickness direction of the film at a wavelength of 835 nm is 20% or less and the minimum value of the light transmittance in the thickness direction of the film in a wavelength range of 1,000 to 1,300 nm is 70% or more.

In the infrared sensor shown in FIG. 1, a near-infrared cut filter (other near-infrared cut filter) other than the near-infrared cut filter 111 may be further disposed on the planarizing layer 116. Examples of the other near-infrared cut filter include a film which has a layer containing copper and/or a dielectric multi-layer film. The details of the examples are as described above. In addition, as the other near-infrared cut filter, a dual band pass filter may be used.

### EXAMPLES

Hereinafter, the present invention will be described in detail using examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below. Unless otherwise specified, “parts” and “/o” are based on mass.

<Measurement of Weight-Average Molecular Weight (Mw) of Sample>

A weight-average molecular weight (Mw) of a sample was measured by gel permeation chromatography (GPC) according to the following conditions.

Types of columns: columns formed by connection of TOSOH TSKgel Super HZM-H, TOSOH TSKgel Super HZ4000, and TOSOH TSKgel Super HZ2000

Developing solvent: tetrahydrofuran

Column temperature: 40° C.

Flow rate (amount of a sample to be injected): 1.0 μL (sample concentration: 0.1 mass %)

Device name: HLC-8220GPC manufactured by Tosoh Corporation

Detector: refractive index (RI) detector

Calibration curve base resin: polystyrene resin

<Measurement of Acid Value of Sample>

An acid value of a sample represents a mass of potassium hydroxide required to neutralize acidic components per 1 g of solid content of the sample. The acid value of the sample was measured as follows. That is, a measurement sample was dissolved in a mixed solvent of tetrahydrofuran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×Vs×0.5×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the sample (expressed in terms of solid contents)

<Measurement of C═C Value of Sample>

The C═C value was obtained by extracting a low-molecular-weight component (a) of an ethylenically unsaturated bonding site (for example, in a case where the resin has an acryloxy group, acrylic acid) from the resin by an alkali treatment, measuring the content thereof by a high performance liquid chromatography (HPLC), and calculating the C═C value from the following expression based on the measured value.

Specifically, 0.1 g of the resin was dissolved in a tetrahydrofuran and methanol-mixed solution (50 mL/15 mL), 10 mL of a 4 mol/L sodium hydroxide aqueous solution was added thereto, and the mixture was reacted at 40° C. for 2 hours. The reaction solution was neutralized with 10.2 mL of a 4 mol/L methanesulfonic acid aqueous solution, the mixed solution to which 5 mL of ion exchange water and 2 mL of methanol were added was transferred to a 100 mL volumetric flask, and then the mixed solution was diluted in the volumetric flask by methanol to prepare a measurement sample for HPLC. Thereafter, the C═C value was measured under the following conditions. The content of the low-molecular-weight component (a) was calculated from a calibration curve of the low-molecular-weight component (a) prepared separately, and the ethylenically unsaturated bonding value was calculated from the following expression.

C═C value (mmol/g)=(Content (ppm) of low-molecular-weight component (a)/Molecular weight (g/mol) of low-molecular-weight component (a)/(Weighed value (g) of polymer solution)×(Concentration of solid contents (%) of polymer solution/100)×10) [C═C Value Calculation Expression]

### —HPLC Measurement Conditions—

Measuring equipment: Agilent-1200 (manufactured by Agilent Technologies, Inc.)

Column: Synergi 4u Polar-RP 80A manufactured by Phenomenex; 250 mm×4.60 mm (inner diameter)+guard column

Column temperature: 40° C.

Analysis time: 15 minutes

Flow rate: 1.0 mL/min (maximum liquid feeding pressure: 182 bar (18.2 MPa))

Injection amount: 5 μl

Detection wavelength: 210 nm

Eluent: tetrahydrofuran (for stabilizer-free HPLC)/buffer solution (ion exchange aqueous solution containing 0.2 volume % of phosphoric acid and 0.2 volume % of triethylamine)=55/45 (volume %)

In the present specification, % by volume is a value at 25° C.

### Synthesis Example 1: Synthesis of Specific Resin A-20

13.5 g of vinylbenzoic acid, 13.5 g of N,N-diethylacrylamide, and 127 g of a macromonomer MI described in paragraphs 0180 and 0181 of JP2011-89108A was dissolved in 320 g of propylene glycol monomethyl ether acetate. 2.3 g of V-601 was added thereto under a nitrogen stream, and the mixture was heated and stirred at 75° C. for 8 hours. The obtained polymer solution was crystallized with hexane, and the obtained precipitate was dried to obtain a polymer (A-20). Mw of the obtained polymer was 20,000, and the acid value was 46 mgKOH/g.

Other specific resins used in Examples or Comparative Examples were synthesized by the same method as in A-20, except that the type and amount of the monomer used were appropriately changed.

Details of x, y, z, and w, which are the content ratios (molar ratios) of each repeating unit in specific resins A-1 to A-48 used in Examples or Comparative Examples, are as shown in the table below.

In addition, in A-22, A-25, and A-26, n:m was set to 50:50 (molar ratio), and in A-45, n:m was set to 10:4 (molar ratio).

TABLE 14

| | x | y | z | w |
|---|---|---|---|---|
| A-1 | 100 | — | — | — |
| A-2 | 50 | 50 | — | — |
| A-3 | 80 | 20 | — | — |
| A-4 | 65 | 35 | — | — |
| A-5 | 20 | 80 | — | — |
| A-6 | 30 | 70 | — | — |
| A-7 | 65 | 35 | — | — |
| A-8 | 35 | 65 | — | — |
| A-9 | 20 | 60 | 20 | — |
| A-10 | 25 | 55 | 20 | — |
| A-11 | 10 | 90 | — | — |
| A-12 | 5 | 22 | 70 | 3 |
| A-13 | 30 | 70 | — | — |
| A-14 | 30 | 70 | — | — |
| A-15 | 20 | 70 | 10 | — |
| A-16 | 20 | 75 | 5 | — |
| A-17 | 15 | 85 | — | — |
| A-18 | 20 | 50 | 30 | — |
| A-19 | 10 | 40 | 50 | — |
| A-20 | 40 | 15 | 45 | — |
| A-21 | 25 | 32 | 43 | — |
| A-22 | 30 | 30 | 40 | — |
| A-23 | 30 | 50 | 20 | — |
| A-24 | 25 | 30 | 45 | — |
| A-25 | 30 | 60 | 10 | — |
| A-26 | 35 | 30 | 5 | 30 |
| A-27 | 30 | 15 | 50 | 5 |
| A-28 | 20 | 20 | 50 | 10 |
| A-29 | 10 | 10 | 60 | 20 |
| A-30 | 40 | 45 | 15 | — |
| A-31 | 20 | 70 | 10 | — |
| A-32 | 30 | 51 | 19 | — |
| A-33 | 25 | 53 | 22 | — |
| A-34 | 61 | 39 | — | — |
| A-35 | 90 | 10 | — | — |
| A-36 | 100 | — | — | — |
| A-37 | 25 | 75 | — | — |
| A-38 | 25 | 70 | 5 | — |
| A-39 | 20 | 70 | 10 | — |
| A-40 | 30 | 55 | 15 | — |
| A-41 | 50 | 50 | — | — |
| A-42 | 40 | 60 | — | — |
| A-43 | 10 | 60 | 30 | — |
| A-44 | 50 | 15 | 35 | — |
| A-45 | 30 | 20 | 50 | — |
| A-46 | 10 | 30 | 60 | — |
| A-47 | 20 | 30 | 50 | — |
| A-48 | 70 | 30 | — | — |

<Production of Dispersion Liquids R1 to R9, B1 to B6, G1 to G5, Y1 to Y3, I1 to I6, and Bk1 to Bk8>

A mixed solution obtained by mixing raw materials listed in the table below was mixed and dispersed for 3 hours by a beads mill (zirconia beads: 0.3 mm diameter), and then subjected to a dispersion treatment under a pressure of 2,000 MPa at a flow rate of 500 g/min using a high-pressure disperser equipped with a pressure-reducing system NANO-3000-10 (manufactured by Nippon BEE Chemical Co., Ltd.). The dispersion treatment was repeated 10 times to obtain each dispersion liquid.

TABLE 15

| | | Dispersion liquid | | | | | | | | | |
|---|---|---|---|---|---|---|---|---|---|---|---|
| | | R1 | R2 | R3 | R4 | R5 | R6 | R7 | R8 | R9 | B1 |
| Colorant or | PR264 | 10.8 | — | 6.4 | 10.5 | — | 13.1 | — | — | — | — |
| near-infrared | PR254 | — | 11.2 | 5.3 | 1.2 | 7.1 | — | — | — | 13.0 | — |
| absorber | PR179 | — | — | — | — | — | — | 12.9 | 10.1 | — | — |
| | PB15:6 | — | — | — | — | — | — | — | — | — | 9.6 |
| | PB16 | — | — | — | — | — | — | — | — | — | — |
| | PG7 | — | — | — | — | — | — | — | — | — | — |
| | PG36 | — | — | — | — | — | — | — | — | — | — |
| | PY138 | — | — | — | — | 3.1 | — | — | — | — | — |
| | PY150 | — | — | — | — | — | — | — | — | 3.8 | — |
| | PY215 | — | — | — | — | — | 3.6 | — | 4.2 | — | — |
| | PV23 | — | — | — | — | — | — | — | — | — | 1.8 |
| | IR coloring agent | — | — | — | — | — | — | — | — | — | — |
| | Irgaphor Bk | — | — | — | — | — | — | — | — | — | — |
| | PBk32 | — | — | — | — | — | — | — | — | — | — |
| | Derivative 1 | 2.9 | — | — | 2.8 | 1.4 | 2.4 | 2.7 | 2.6 | 2.9 | — |
| | Derivative 2 | — | 3.1 | 2.6 | — | — | — | — | — | — | 2.8 |
| | Derivative 3 | — | — | — | — | — | — | — | — | — | — |
| Resin | A-20 | 5.1 | — | — | — | 3.3 | — | — | — | — | 5.4 |
| | A-22 | — | 5.4 | — | — | — | 5.7 | — | — | — | — |
| | A-26 | — | — | 5.8 | — | — | — | 5.5 | — | — | — |
| | A-29 | — | — | — | — | — | — | — | — | 6.0 | — |
| | A-40 | — | — | — | — | — | — | — | 5.4 | — | — |
| | A-48 | — | — | — | — | — | — | — | — | — | — |
| | CA-4 | — | — | — | 6.8 | — | — | — | — | — | — |
| | CA-5 | — | — | — | — | — | — | — | — | — | — |
| Solvent | S-1 | 81.2 | 80.3 | — | — | 85.1 | 75.2 | 78.9 | 77.7 | 74.3 | — |
| | S-2 | — | — | 79.8 | — | — | — | — | — | — | — |
| | S-3 | — | — | — | 78.7 | — | — | — | — | — | 80.4 |
| | S-4 | — | — | — | — | — | — | — | — | — | — |

| | | Dispersion liquid | | | | | | | | |
|---|---|---|---|---|---|---|---|---|---|---|
| | | B2 | B3 | B4 | B5 | B6 | G1 | G2 | G3 | G4 |
| Colorant or | PR264 | — | — | — | — | — | — | — | — | — |
| near-infrared | PR254 | — | — | — | — | — | — | — | — | — |
| absorber | PR179 | — | — | — | — | — | — | — | — | — |
| | PB15:6 | 12.2 | — | 3.0 | 3.0 | 3.0 | — | — | — | — |
| | PB16 | — | 11.2 | 9.6 | 9.6 | 9.6 | — | — | — | — |
| | PG7 | — | — | — | — | — | 12.3 | — | 10.1 | — |
| | PG36 | — | — | — | — | — | — | 11.9 | — | 10.2 |
| | PY138 | — | — | — | — | — | — | — | — | 2.9 |
| | PY150 | — | — | — | — | — | — | — | — | — |
| | PY215 | — | — | — | — | — | — | — | 2.0 | — |
| | PV23 | — | — | — | — | — | — | — | — | — |
| | IR coloring agent | — | — | — | — | — | — | — | — | — |
| | Irgaphor Bk | — | — | — | — | — | — | — | — | — |
| | PBk32 | — | — | — | — | — | — | — | — | — |
| | Derivative 1 | — | — | — | — | — | — | — | — | — |
| | Derivative 2 | 2.3 | 3.0 | 2.7 | 2.7 | 2.7 | 2.5 | 2.3 | 2.6 | 2.3 |
| | Derivative 3 | — | — | — | — | — | — | — | — | — |
| Resin | A-20 | — | — | 3.0 | 3.0 | — | 8.2 | — | — | — |
| | A-22 | 5.7 | — | — | — | — | — | 7.8 | — | — |
| | A-26 | — | — | — | — | — | — | — | 6.6 | — |
| | A-29 | — | 5.8 | 2.3 | — | — | — | — | — | — |
| | A-40 | — | — | — | — | — | — | — | — | 7.4 |
| | A-48 | — | — | — | — | — | — | — | — | — |
| | CA-4 | — | — | — | — | — | — | — | — | — |
| | CA-5 | — | — | — | 2.3 | 5.5 | — | — | — | — |
| Solvent | S-1 | — | — | — | — | — | 77.0 | 78.0 | 78.7 | 77.2 |
| | S-2 | — | 79.9 | 79.4 | 79.4 | 79.3 | — | — | — | — |
| | S-3 | — | — | — | — | — | — | — | — | — |
| | S-4 | 79.7 | — | — | — | — | — | — | — | — |

TABLE 16

| | | Dispersion liquid | | | | | | | | | |
|---|---|---|---|---|---|---|---|---|---|---|---|
| | | G5 | Y1 | Y2 | Y3 | I1 | I2 | I3 | I4 | I5 | I6 |
| Colorant or | PR264 | — | — | — | — | — | — | — | — | — | — |
| near-infrared | PR254 | — | — | — | — | — | — | — | — | — | — |
| absorber | PR179 | — | — | — | — | — | — | — | — | — | — |
| | PB15:6 | — | — | — | — | — | — | — | — | — | — |
| | PB16 | — | — | — | — | — | — | — | — | — | — |
| | PG7 | — | — | — | — | — | — | — | — | — | — |
| | PG36 | 10.2 | — | — | — | — | — | — | — | — | — |
| | PY138 | — | 12.9 | — | — | — | — | — | — | — | — |
| | PY150 | 2.2 | — | — | 14.0 | — | — | — | — | — | — |
| | PY215 | — | — | 13.1 | — | — | — | — | — | — | — |
| | PV23 | — | — | — | — | — | — | — | — | — | — |
| | IR coloring agent | — | — | — | — | 12.5 | 12.5 | 12.5 | 13.5 | 13.5 | 13.5 |
| | Irgaphor Bk | — | — | — | — | — | — | — | — | — | — |
| | PBk32 | — | — | — | — | — | — | — | — | — | — |
| | Derivative 1 | — | — | — | — | — | — | — | — | — | — |
| | Derivative 2 | 2.4 | 2.3 | 2.3 | 2.3 | — | — | — | — | — | — |
| | Derivative 3 | — | — | — | — | 3.6 | 3.6 | 3.6 | 4.0 | 4.0 | 4.0 |
| Resin | A-20 | — | 7.0 | 7.4 | — | 5.0 | — | — | — | — | — |
| | A-22 | — | — | — | — | — | 5.0 | — | — | — | — |
| | A-26 | — | — | — | — | — | — | 5.0 | — | — | — |
| | A-29 | — | — | — | 9.4 | — | — | — | 5.6 | 2.9 | — |
| | A-40 | — | — | — | — | — | — | — | — | — | — |
| | A-48 | 7.4 | — | — | — | — | — | — | — | — | — |
| | CA-4 | — | — | — | — | — | — | — | — | 2.7 | — |
| | CA-5 | — | — | — | — | — | — | — | — | — | 5.6 |
| Solvent | S-1 | 77.8 | 77.8 | 77.2 | 74.3 | — | — | — | 76.9 | 76.9 | 76.9 |
| | S-2 | — | — | — | — | — | — | 78.9 | — | — | — |
| | S-3 | — | — | — | — | — | 78.9 | — | — | — | — |
| | S-4 | — | — | — | — | 78.9 | — | — | — | — | — |

| | | Dispersion liquid | | | | | | | |
|---|---|---|---|---|---|---|---|---|---|
| | | Bk1 | Bk2 | Bk3 | Bk4 | Bk5 | Bk6 | Bk7 | Bk8 |
| Colorant or | PR264 | — | — | 5.7 | — | — | — | — | — |
| near-infrared | PR254 | 6.4 | — | — | 4.7 | — | — | — | — |
| absorber | PR179 | — | 4.1 | — | — | — | — | — | — |
| | PB15:6 | — | — | — | 2.7 | — | 2.6 | 3.5 | 3.5 |
| | PB16 | 4.2 | 1.6 | 3.7 | — | 5.3 | — | — | — |
| | PG7 | — | 4.3 | — | — | — | — | — | — |
| | PG36 | — | — | — | — | — | — | — | — |
| | PY138 | — | — | — | 1.8 | — | 2.6 | 3.5 | 3.5 |
| | PY150 | — | — | — | — | — | — | — | — |
| | PY215 | — | — | 0.8 | — | — | — | — | — |
| | PV23 | — | — | — | — | — | — | 3.5 | 3.5 |
| | IR coloring agent | — | — | — | 3.0 | — | — | — | — |
| | Irgaphor Bk | — | — | — | — | 5.3 | 2.6 | — | — |
| | PBk32 | — | — | — | — | — | 2.6 | — | — |
| | Derivative 1 | 1.9 | — | 1.9 | 1.9 | — | — | 0.8 | 0.8 |
| | Derivative 2 | — | 2.0 | — | — | 1.8 | 1.8 | 0.8 | 0.8 |
| | Derivative 3 | — | — | — | — | — | — | 0.8 | 0.8 |
| Resin | A-20 | 5.0 | — | — | — | — | — | — | — |
| | A-22 | — | 4.8 | — | — | — | — | — | — |
| | A-26 | — | — | — | — | — | — | — | — |
| | A-29 | — | — | — | — | — | 4.2 | 4.2 | — |
| | A-40 | — | — | — | 4.6 | — | — | — | — |
| | A-48 | — | — | 4.4 | — | 4.2 | — | — | — |
| | CA-4 | — | — | — | — | — | — | — | 4.4 |
| | CA-5 | — | — | — | — | — | — | — | — |
| Solvent | S-1 | 82.5 | 83.2 | 83.5 | 81.4 | 83.5 | 83.7 | 82.8 | 82.6 |
| | S-2 | — | — | — | — | — | — | — | — |
| | S-3 | — | — | — | — | — | — | — | — |
| | S-4 | — | — | — | — | — | — | — | — |

The unit of numerical values shown in the above table is part by mass. Among the raw materials shown in the above table, details of the raw materials shown by abbreviations are as follows.

[Colorant or near-infrared absorber]

PR264: C. I. Pigment Red 264 (red pigment, diketopyrrolopyrrole pigment)

PR254: C. I. Pigment Red 254 (red pigment, diketopyrrolopyrrole pigment)

PR179: C. I. Pigment Red 179

PB15:6: C. I. Pigment Blue 15:6 (blue pigment, phthalocyanine pigment)

PB16: C. I. Pigment Blue 16 (blue pigment, phthalocyanine pigment)

PG7: C. I. Pigment Green 7

PG36: C. I. Pigment Green 36

PY138: C. I. Pigment Yellow 138

PY215: C. I. Pigment Yellow 215

PV23: C. I. Pigment Violet 23

IR coloring agent: compound having the following structure (near-infrared absorber, in the following structural formula, Me represents a methyl group and Ph represents a phenyl group)

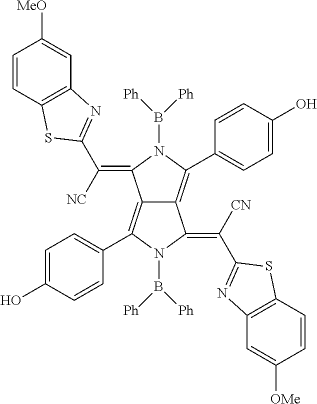 [SMILES: COc1ccc2sc(/C(C#N)=c3/c4c(-c5ccc(O)cc5)n(B(c5ccccc5)c5ccccc5)/c(=C(/C#N)c5nc6cc(OC)ccc6s5)c4c(-c4ccc(O)cc4)n3B(c3ccccc3)c3ccccc3)nc2c1]

Irgaphor Bk: Irgaphor Black S 0100 CF (manufactured by BASF, compound having the following structure, lactam-based pigment)

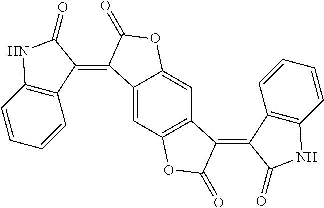 [SMILES: O=C1Nc2ccccc2/C1=C1/C(=O)Oc2cc3c(cc21)OC(=O)/C3=C1\C(=O)Nc2ccccc21]

PBk32: C. I. Pigment Black 32 (compound having the following structure, perylene-based pigment)

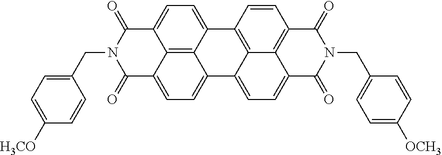 [SMILES: COc1ccc(CN2C(=O)c3ccc4c5ccc6c7c(ccc(c8ccc(c3c48)C2=O)c75)C(=O)N(Cc2ccc(OC)cc2)C6=O)cc1]

Derivative 1: colorant, compound having the following structure

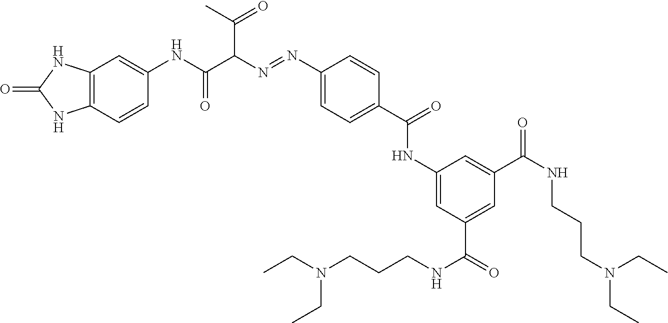 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Derivative 2: colorant, compound having the following structure

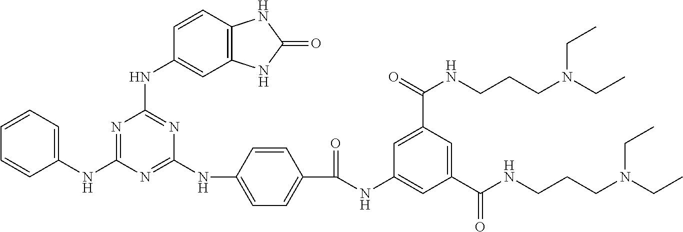 [SMILES: CCN(CC)CCCNC(=O)c1cc(NC(=O)c2ccc(Nc3nc(Nc4ccccc4)nc(Nc4ccc5[nH]c(=O)[nH]c5c4)n3)cc2)cc(C(=O)NCCCN(CC)CC)c1]

Derivative 3: near-infrared absorber, compound having the following structure

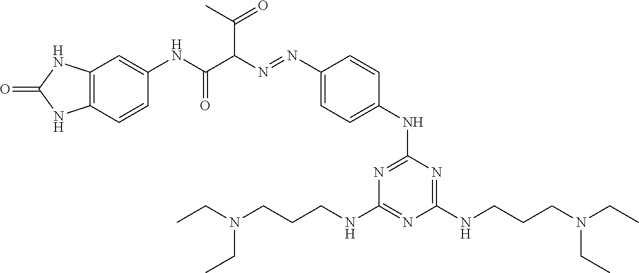 [SMILES: CCN(CC)CCCNc1nc(NCCCN(CC)CC)nc(Nc2ccc(/N=N/C(C(C)=O)C(=O)Nc3ccc4[nH]c(=O)[nH]c4c3)cc2)n1]

[Resin]

A-20, A-22, A-26, A-29, A-40, A-48: resins synthesized as in Synthesis Examples described above

CA-4: resin having the following structure ((meth)acrylic resin, a numerical value added to a main chain represents a molar ratio of each repeating unit, and a numerical value added to a polyester unit in a side chain is a repetition number of each unit; in addition, CA-4 was a resin not containing any of the repeating units represented by any one of Formula (1-1), . . . , or Formula (1-5))

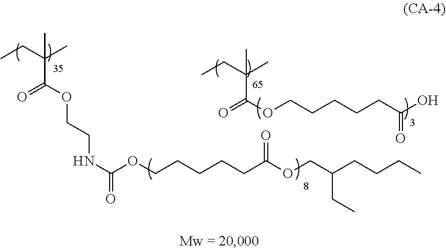

CA-5: resin having the following structure ((meth)acrylic resin, a numerical value added to a main chain represents a molar ratio of each repeating unit, and a numerical value added to a polyester unit in a side chain is a repetition number of each unit; in addition, CA-5 was a resin not containing any of the repeating units represented by any one of Formula (1-1), . . . , or Formula (1-5))

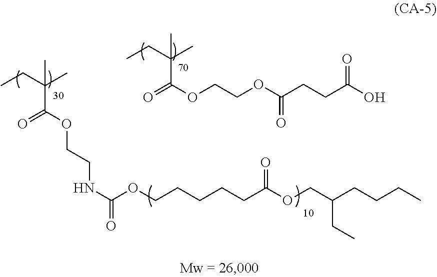

[Solvent (Organic Solvent)]

S-1: propylene glycol monomethyl ether acetate

S-2: propylene glycol monomethyl ether

S-3: cyclohexanone

S-4: cyclopentanone

<Production of Composition>

In each of Examples and Comparative Examples, raw materials shown in the tables below were mixed to prepare a composition or a comparative composition. The unit of the numerical value in the column of the amount added described in the tables below is parts by mass.

The description in the column of “Total content (%)” indicates a total content (mass %) of the colorant and the near-infrared absorber with respect to the total solid content of the composition.

The description in the column of “Proportion of total amount of specific repeating unit (mol %)” indicates a proportion (mol %) of the total amount of repeating units represented by any one of Formula (1-1), . . . , or Formula (1-5) with respect to the total molar amount of all repeating units included in all resin components included in the composition.

The description in the column of “Wavelength T %=50% (nm)” indicates a wavelength indicating a light transmittance of 50% in the thickness direction of a film which is formed from each composition and has a film thickness of 1 μm.

The description in the column of “Minimum T % (%)” indicates a minimum value of a light transmittance in a wavelength range of 950 to 1,300 nm.

The description in the column of “Amin/B” indicates a value of Amin/B which is a ratio of a minimum value Amin of an absorbance of the composition in a wavelength range of 400 to 640 nm to an absorbance B of the composition at a wavelength of 1,500 nm.

TABLE 17

| | | | | | | | | | | | | Polymerizable | | Photopolymerization | |
|---|---|---|---|---|---|---|---|---|---|---|---|---|---|---|---|
| | | Pigment dispersion liquid | | | | | | Dye | | Resin | | compound | | initiator | |
| | | | Part by | | Part by | | Part by | | Part by | | Part by | | Part by | | Part by |
| | | Type | mass | Type | mass | Type | mass | Type | mass | Type | mass | Type | mass | Type | mass |
| Example | 1 | R1 | 25.5 | B1 | 19.5 | — | — | — | — | A-38 | 6.9 | D-1 | 1.7 | E-2 | 0.5 |
| | 2 | R1 | 27.2 | B1 | 18.7 | — | — | — | — | A-2 | 6.8 | D-1 | 2.3 | E-1 | 0.9 |
| | 3 | R1 | 51.8 | B1 | 24.9 | — | — | — | — | A-3 | 2.0 | D-1 | 1.5 | E-2 | 0.4 |
| | 4 | R1 | 61.8 | B1 | 24.9 | — | — | — | — | A-3 | 0.5 | D-1 | 0.8 | E-2 | 0.3 |
| | 5 | R2 | 25.9 | B2 | 18.4 | — | — | — | — | A-4 | 6.6 | D-1 | 3.1 | E-1 | 1.0 |
| | 6 | R3 | 26.2 | B3 | 18.4 | — | — | — | — | A-5 | 6.2 | D-2 | 2.5 | E-2 | 0.9 |
| | 7 | R1 | 27.0 | B3 | 18.6 | — | — | — | — | A-6 | 6.6 | D-1 | 2.1 | E-3 | 0.7 |
| | 8 | R4 | 25.2 | B4 | 18.3 | — | — | — | — | A-7 | 5.9 | D-1 | 2.5 | E-1 | 0.8 |
| | 9 | R4 | 25.2 | B4 | 18.3 | — | — | — | — | A-45 | 5.9 | D-1 | 1.3 | E-1 | 0.5 |
| | 10 | R4 | 25.2 | B4 | 18.3 | — | — | — | — | A-46 | 5.9 | D-1 | 2.2 | E-1 | 0.8 |
| | 11 | R5 | 30.6 | B5 | 19.6 | — | — | — | — | A-8 | 7.8 | D-2 | 2.9 | E-2 | 1.1 |
| | 12 | R4 | 25.2 | B6 | 18.3 | — | — | — | — | A-39 | 5.8 | D-1 | 2.0 | E-1 | 0.6 |
| | 13 | R6 | 36.0 | G1 | 22.5 | — | — | — | — | A-9 | 2.3 | D-3 | 1.6 | E-3 | 0.5 |
| | 14 | R7 | 38.3 | G2 | 23.3 | — | — | — | — | A-10 | 2.2 | D-1 | 1.2 | E-3 | 0.4 |
| | 15 | R8 | 37.4 | G1 | 22.9 | — | — | — | — | A-11 | 2.3 | D-1 | 2.2 | E-1 | 0.8 |
| | 16 | R9 | 35.3 | G2 | 22.4 | — | — | — | — | A-12 | 2.4 | D-2 | 1.6 | E-1 | 0.6 |
| | 17 | R1 | 30.8 | G3 | 21.3 | — | — | — | — | A-13 | 5.1 | D-3 | 1.7 | E-1 | 0.7 |
| | 18 | R1 | 30.8 | G3 | 21.3 | — | — | — | — | A-41 | 5.1 | D-3 | 2.1 | E-1 | 0.7 |
| | 19 | R1 | 30.8 | G3 | 21.3 | — | — | — | — | A-42 | 5.1 | D-3 | 2.5 | E-1 | 0.7 |
| | 20 | R1 | 30.8 | G3 | 21.3 | — | — | — | — | A-43 | 5.1 | D-3 | 2.2 | E-1 | 0.6 |
| | 21 | R1 | 30.8 | G3 | 21.3 | — | — | — | — | A-47 | 5.1 | D-3 | 2.5 | E-1 | 1.0 |
| | 22 | R2 | 28.9 | G4 | 20.7 | — | — | — | — | A-8 | 4.7 | D-1 | 2.6 | E-2 | 0.9 |
| | 23 | R3 | 29.6 | G5 | 21.0 | — | — | — | — | A-9 | 4.2 | D-2 | 1.7 | E-2 | 0.6 |
| | 24 | R1 | 25.9 | B1 | 17.8 | Y1 | 9.1 | — | — | A-38 | 5.2 | D-3 | 2.5 | E-2 | 0.7 |
| | 25 | R3 | 25.7 | B4 | 18.1 | Y2 | 4.6 | — | — | A-39 | 5.6 | D-1 | 2.6 | E-3 | 0.9 |
| | 26 | R3 | 25.7 | B4 | 18.1 | Y2 | 4.6 | — | — | A-39 | 5.6 | D-1 | 2.6 | E-3 | 0.8 |
| | 27 | R3 | 25.7 | B4 | 18.1 | Y2 | 4.6 | — | — | A-39 | 5.6 | D-1 | 2.9 | E-3 | 0.9 |
| | 28 | R3 | 25.7 | B4 | 18.1 | Y2 | 4.6 | — | — | A-39 | 5.6 | D-1 | 1.3 | E-3 | 0.4 |
| | 29 | R3 | 25.7 | B4 | 18.1 | Y2 | 4.6 | — | — | A-39 | 5.6 | D-1 | 2.6 | — | — |

| | | Silane | | | | | | Polymerization | | | |
|---|---|---|---|---|---|---|---|---|---|---|---|
| | | coupling agent | | Curing agent | | Surfactant | | inhibitor | | Solvent | |
| | | | Part by | | Part by | | Part by | | Part by | | Part by |
| | | Type | mass | Type | mass | Type | mass | Type | mass | Type | mass |
| Example | 1 | — | — | — | — | H-1 | 0.04 | I-1 | 0.001 | S-1 | 45.9 |
| | 2 | — | — | — | — | H-1 | 0.04 | I-1 | 0.001 | S-1 | 44.1 |
| | 3 | — | — | — | — | H-1 | 0.04 | I-1 | 0.001 | S-1 | 19.4 |
| | 4 | — | — | — | — | H-1 | 0.04 | I-1 | 0.001 | S-1 | 11.8 |
| | 5 | — | — | — | — | H-1 | 0.04 | I-1 | 0.001 | S-1 | 44.9 |
| | 6 | — | — | — | — | H-1 | 0.04 | I-1 | 0.001 | S-1 | 45.9 |
| | 7 | — | — | — | — | H-1 | 0.04 | I-1 | 0.001 | S-1 | 45.1 |
| | 8 | — | — | — | — | H-1 | 0.04 | I-1 | 0.001 | S-3 | 47.3 |
| | 9 | — | — | — | — | H-1 | 0.04 | I-1 | 0.001 | S-3 | 48.8 |
| | 10 | — | — | — | — | H-1 | 0.04 | I-1 | 0.001 | S-3 | 47.6 |
| | 11 | — | — | — | — | H-1 | 0.04 | I-1 | 0.001 | S-3 | 38.0 |
| | 12 | — | — | — | — | H-1 | 0.04 | I-1 | 0.001 | S-3 | 48.1 |
| | 13 | — | — | — | — | H-1 | 0.04 | I-1 | 0.001 | S-1 | 37.1 |
| | 14 | — | — | — | — | H-1 | 0.04 | I-1 | 0.001 | S-1 | 34.6 |
| | 15 | — | — | — | — | H-1 | 0.04 | I-1 | 0.001 | S-1 | 34.4 |
| | 16 | — | — | — | — | H-1 | 0.04 | I-1 | 0.001 | S-1 | 37.6 |
| | 17 | — | — | — | — | H-1 | 0.04 | I-1 | 0.001 | S-1 | 40.5 |
| | 18 | — | — | — | — | H-1 | 0.04 | I-1 | 0.001 | S-1 | 40.1 |
| | 19 | — | — | — | — | H-1 | 0.04 | I-1 | 0.001 | S-1 | 39.7 |
| | 20 | — | — | — | — | H-1 | 0.04 | I-1 | 0.001 | S-1 | 40.1 |
| | 21 | — | — | — | — | H-1 | 0.04 | I-1 | 0.001 | S-1 | 39.4 |
| | 22 | — | — | — | — | H-1 | 0.04 | I-1 | 0.001 | S-3 | 42.2 |
| | 23 | — | — | — | — | H-1 | 0.04 | I-1 | 0.001 | S-3 | 42.9 |
| | 24 | — | — | — | — | H-1 | 0.04 | I-1 | 0.001 | S-1 | 38.7 |
| | 25 | — | — | — | — | H-1 | 0.04 | I-1 | 0.001. | S-1 | 42.5 |
| | 26 | F-1 | 0.3 | — | — | H-1 | 0.04 | I-1 | 0.001 | S-1 | 42.6 |
| | 27 | F-2 | 0.3 | — | — | H-1 | 0.04 | I-1 | 0.001 | S-1 | 42.3 |
| | 28 | — | — | G-1 | 1.0 | H-1 | 0.04 | I-1 | 0.001 | S-1 | 44.3 |
| | 29 | — | — | G-2 | 1.0 | H-1 | 0.04 | I-1 | 0.001 | S-1 | 43.4 |

TABLE 18

| | | | | | | | | | | | | Polymerizable | | Photopolymerization | |
|---|---|---|---|---|---|---|---|---|---|---|---|---|---|---|---|
| | | Pigment dispersion liquid | | | | | | Dye | | Resin | | compound | | initiator | |
| | | | Part by | | Part by | | Part by | | Part by | | Part by | | Part by | | Part by |
| | | Type | mass | Type | mass | Type | mass | Type | mass | Type | mass | Type | mass | Type | mass |
| Example | 30 | R3 | 25.7 | B4 | 18.1 | Y2 | 4.6 | — | — | A-39 | 5.6 | D-1 | 1.7 | E-3 | 0.6 |
| | 31 | R7 | 31.5 | B5 | 19.3 | Y3 | 6.9 | — | — | A-44 | 3.8 | D-1 | 2.1 | E-3 | 0.7 |
| | 32 | R7 | 31.5 | B5 | 19.3 | Y3 | 6.9 | — | — | A-45 | 3.8 | D-1 | 2.0 | — | — |
| | 33 | R7 | 31.5 | B5 | 19.3 | Y3 | 6.9 | — | — | A-46 | 3.8 | D-1 | 1.9 | E-3 | 0.6 |
| | 34 | R5 | 28.6 | B2 | 18.2 | I1 | 6.5 | — | — | A-9 | 7.0 | D-2 | 3.2 | E-3 | 1.2 |
| | 35 | R5 | 28.6 | B2 | 18.2 | I2 | 6.5 | — | — | A-10 | 7.0 | D-1 | 2.7 | E-1 | 0.8 |
| | 36 | R5 | 28.6 | B2 | 18.2 | I3 | 6.5 | — | — | A-11 | 7.0 | — | — | — | — |
| | 37 | R5 | 28.4 | B2 | 18.1 | I4 | 6.5 | — | — | A-9 | 7.0 | D-2 | 3.2 | E-3 | 1.1 |
| | 38 | R5 | 28.4 | B2 | 18.1 | I5 | 6.5 | — | — | A-9 | 7.0 | D-1 | 3.2 | E-1 | 1.2 |
| | 39 | R5 | 28.4 | B2 | 18.1 | I6 | 6.5 | — | — | A-9 | 7.0 | D-1 | 1.5 | E-2 | 0.6 |
| | 40 | R5 | 28.4 | B2 | 18.1 | — | — | Cyanine | 0.8 | A-9 | 8.0 | D-1 | 2.1 | E-2 | 0.7 |
| | 41 | R5 | 28.4 | B2 | 18.1 | — | — | SQ | 0.8 | A-9 | 8.0 | D-1 | 1.7 | E-2 | 0.6 |
| | 42 | R5 | 28.4 | B2 | 18.1 | — | — | PPB | 0.8 | A-9 | 8.0 | D-1 | 2.3 | E-2 | 0.8 |
| | 43 | R5 | 28.6 | B2 | 18.2 | I1 | 6.5 | — | — | A-38 | 7.0 | D-1 | 2.4 | E-3 | 0.8 |
| | 44 | Bk1 | 57.3 | — | — | — | — | — | — | A-39 | 5.4 | D-1 | 1.5 | E-1 | 0.5 |
| | 45 | Bk2 | 60.3 | — | — | — | — | — | — | A-40 | 5.4 | D-1 | 2.3 | E-2 | 0.8 |
| | 46 | Bk3 | 60.9 | — | — | — | — | — | — | A-17 | 5.9 | D-1 | 1.6 | E-3 | 0.5 |
| | 47 | Bk4 | 56.3 | — | — | — | — | — | — | A-18 | 6.3 | D-2 | 2.0 | E-1 | 0.8 |
| | 48 | Bk5 | 58.0 | — | — | — | — | — | — | A-19 | 6.6 | D-1 | 1.8 | E-2 | 0.7 |
| | 49 | Bk6 | 57.9 | — | — | — | — | — | — | A-28 | 6.7 | D-2 | 2.1 | E-3 | 0.8 |
| | 50 | Bk7 | 55.6 | — | — | — | — | — | — | A-25 | 7.0 | D-1 | 2.5 | E-1 | 0.9 |
| | 51 | Bk8 | 55.6 | — | — | — | — | — | — | A-38 | 6.6 | D-1 | 3.0 | E-1 | 1.2 |
| | 52 | Bk1 | 53.3 | I3 | 8.0 | — | — | — | — | A-25 | 4.8 | D-1 | 2.0 | E-2 | 0.8 |
| | 53 | Bk2 | 56.9 | I4 | 7.9 | — | — | — | — | A-27 | 4.5 | D-1 | 1.2 | E-3 | 0.4 |
| Comparative | 1 | R4 | 45.2 | B6 | 20.8 | — | — | — | — | CA-1 | 1.3 | D-1 | 1.7 | E-3 | 0.6 |
| example | 2 | R4 | 45.2 | B6 | 20.8 | — | — | — | — | CA-2 | 1.3 | D-1 | 0.9 | E-3 | 0.4 |
| | 3 | R4 | 45.2 | B6 | 20.8 | — | — | — | — | CA-3 | 1.3 | D-1 | 1.3 | E-3 | 0.5 |
| | 4 | Bk8 | 62.0 | — | — | — | — | — | — | CA-1 | 5.7 | D-1 | 2.2 | E-3 | 0.8 |

| | | Silane | | | | | | Polymerization | | | |
|---|---|---|---|---|---|---|---|---|---|---|---|
| | | coupling agent | | Curing agent | | Surfactant | | inhibitor | | Solvent | |
| | | | Part by | | Part by | | Part by | | Part by | | Part by |
| | | Type | mass | Type | mass | Type | mass | Type | mass | Type | mass |
| Example | 30 | F-2 | 0.3 | G-2 | 1.0 | H-1 | 0.04 | I-1 | 0.001 | S-1 | 43.7 |
| | 31 | — | — | — | — | H-1 | 0.04 | I-1 | 0.001 | S-1 | 35.9 |
| | 32 | — | — | — | — | H-1 | 0.04 | I-1 | 0.001 | S-1 | 36.6 |
| | 33 | — | — | — | — | H-1 | 0.04 | I-1 | 0.001 | S-1 | 36.1 |
| | 34 | — | — | — | — | H-1 | 0.04 | I-1 | 0.001 | S-1 | 35.3 |
| | 35 | — | — | — | — | H-1 | 0.04 | I-1 | 0.001 | S-1 | 36.1 |
| | 36 | — | — | G-1 | 3.0 | H-1 | 0.04 | I-1 | 0.001 | S-1 | 39.6 |
| | 37 | — | — | — | — | H-1 | 0.04 | I-1 | 0.001 | S-3 | 35.7 |
| | 38 | — | — | — | — | H-1 | 0.04 | I-1 | 0.001 | S-3 | 35.6 |
| | 39 | — | — | — | — | H-1 | 0.04 | I-1 | 0.001 | S-3 | 37.9 |
| | 40 | — | — | — | — | H-1 | 0.04 | I-1 | 0.001 | S-3 | 41.8 |
| | 41 | — | — | — | — | H-1 | 0.04 | I-1 | 0.001 | S-3 | 42.3 |
| | 42 | — | — | — | — | H-1 | 0.04 | I-1 | 0.001 | S-3 | 41.5 |
| | 43 | — | — | — | — | H-1 | 0.04 | I-1 | 0.001 | S-1 | 36.4 |
| | 44 | — | — | — | — | H-1 | 0.04 | I-1 | 0.001 | S-1 | 35.3 |
| | 45 | — | — | — | — | H-1 | 0.04 | I-1 | 0.001 | S-1 | 31.2 |
| | 46 | — | — | — | — | H-1 | 0.04 | I-1 | 0.001 | S-1 | 31.1 |
| | 47 | — | — | — | — | H-1 | 0.04 | I-1 | 0.001 | S-1 | 34.6 |
| | 48 | — | — | — | — | H-1 | 0.04 | I-1 | 0.001 | S-1 | 32.8 |
| | 49 | — | — | — | — | H-1 | 0.04 | I-1 | 0.001 | S-1 | 32.5 |
| | 50 | — | — | — | — | H-1 | 0.04 | I-1 | 0.001 | S-3 | 34.0 |
| | 51 | — | — | — | — | H-1 | 0.04 | I-1 | 0.001 | S-3 | 33.6 |
| | 52 | — | — | — | — | H-1 | 0.04 | I-1 | 0.001 | S-3 | 31.1 |
| | 53 | — | — | — | — | H-1 | 0.04 | I-1 | 0.001 | S-3 | 29.1 |
| Comparative | 1 | — | — | — | — | H-1 | 0.04 | I-1 | 0.001 | S-1 | 30.5 |
| example | 2 | — | — | — | — | H-1 | 0.04 | I-1 | 0.001 | S-1 | 31.5 |
| | 3 | — | — | — | — | H-1 | 0.04 | I-1 | 0.001 | S-1 | 31.0 |
| | 4 | — | — | — | — | H-1 | 0.04 | I-1 | 0.001 | S-1 | 29.2 |

TABLE 19

| | | | Proportion | | | |
|---|---|---|---|---|---|---|
| | | | of content | Wave- | Min- | |
| | | Total | of specific | length | imum | |
| | | content | repeating unit | T % = | T % | Amin/ |
| | | (%) | (mol %) | 50%(nm) | (%) | B |
| Example | 1 | 35.3 | 92.4 | 790 | 93 | 13.5 |
| | 2 | 34.0 | 96.1 | 790 | 90 | 11.0 |
| | 3 | 57.2 | 83.3 | 795 | 96 | 57.4 |
| | 4 | 66.4 | 84.5 | 795 | 89 | 75.8 |
| | 5 | 32.6 | 71.0 | 790 | 98 | 5.1 |
| | 6 | 34.3 | 97.3 | 750 | 96 | 9.6 |
| | 7 | 34.8 | 95.9 | 750 | 95 | 11.6 |
| | 8 | 35.0 | 54.3 | 770 | 89 | 15.0 |
| | 9 | 38.1 | 30.2 | 770 | 89 | 20.3 |
| | 10 | 35.5 | 16.5 | 770 | 94 | 13.0 |
| | 11 | 32.0 | 92.9 | 770 | 92 | 6.0 |
| | 12 | 36.5 | 68.1 | 770 | 90 | 13.0 |
| | 13 | 55.1 | 83.8 | 785 | 89 | 51.1 |
| | 14 | 54.1 | 87.2 | 785 | 98 | 49.3 |
| | 15 | 51.2 | 86.9 | 785 | 94 | 46.4 |
| | 16 | 54.3 | 81.0 | 785 | 91 | 53.6 |
| | 17 | 41.3 | 96.2 | 780 | 99 | 24.6 |
| | 18 | 40.4 | 64.7 | 780 | 94 | 21.9 |
| | 19 | 39.4 | 58.4 | 780 | 99 | 23.8 |
| | 20 | 40.3 | 77.3 | 780 | 91 | 23.6 |
| | 21 | 38.8 | 64.7 | 780 | 98 | 20.7 |
| | 22 | 39.4 | 94.4 | 780 | 97 | 21.7 |
| | 23 | 42.8 | 85.6 | 780 | 89 | 26.6 |
| | 24 | 39.4 | 91.4 | 790 | 98 | 22.9 |
| | 25 | 37.4 | 96.8 | 770 | 92 | 15.9 |
| | 26 | 37.1 | 96.8 | 770 | 92 | 16.2 |
| | 27 | 36.5 | 96.8 | 770 | 98 | 15.0 |
| | 28 | 39.2 | 96.8 | 770 | 99 | 18.4 |
| | 29 | 37.3 | 96.8 | 770 | 98 | 19.6 |
| Example | 30 | 37.3 | 96.8 | 770 | 94 | 16.7 |
| | 31 | 47.4 | 63.7 | 770 | 99 | 37.7 |
| | 32 | 49.2 | 53.2 | 770 | 93 | 41.5 |
| | 33 | 48.0 | 42.6 | 770 | 89 | 36.0 |
| | 34 | 33.8 | 81.5 | 790 | 94 | 7.6 |
| | 35 | 35.2 | 81.5 | 790 | 94 | 14.4 |
| | 36 | 36.2 | 89.3 | 790 | 98 | 17.3 |
| | 37 | 34.2 | 81.5 | 790 | 97 | 13.5 |
| | 38 | 34.1 | 79.9 | 790 | 98 | 13.2 |
| | 39 | 38.2 | 78.2 | 790 | 91 | 20.5 |
| | 40 | 34.4 | 81.2 | 820 | 90 | 8.7 |
| | 41 | 35.3 | 81.2 | 750 | 93 | 12.6 |
| | 42 | 33.9 | 81.2 | 870 | 98 | 8.7 |
| | 43 | 35.7 | 92.7 | 790 | 95 | 12.4 |
| | 44 | 41.0 | 94.8 | 740 | 89 | 22.1 |
| | 45 | 38.9 | 85.7 | 740 | 92 | 17.8 |
| | 46 | 40.6 | 96.8 | 740 | 89 | 22.1 |
| | 47 | 40.4 | 95.7 | 890 | 98 | 25.8 |
| | 48 | 37.9 | 97.3 | 740 | 95 | 16.8 |
| | 49 | 36.8 | 96.0 | 790 | 94 | 15.6 |
| | 50 | 36.3 | 88.7 | 790 | 93 | 14.5 |
| | 51 | 35.3 | 69.1 | 790 | 93 | 14.5 |
| | 52 | 42.7 | 88.6 | 890 | 93 | 25.4 |
| | 53 | 46.9 | 94.5 | 890 | 92 | 35.9 |
| Comparative | 1 | 55.4 | 0.0 | 770 | 98 | 55.9 |
| example | 2 | 58.7 | 0.0 | 770 | 99 | 61.4 |
| | 3 | 57.0 | 1.2 | 770 | 95 | 59.1 |
| | 4 | 41.1 | 0.0 | 790 | 94 | 27.2 |

Among the raw materials listed in the above tables, details of the raw materials shown by abbreviations are as follows.

[Pigment Dispersion Liquid]

R1 to R9, B1 to B6, G1 to G5, Y1 to Y3, I1 to I6, Bk1 to Bk8: pigment dispersion liquids described above

[Dye]

SQ, PPB, cyanine: compounds having the following structures

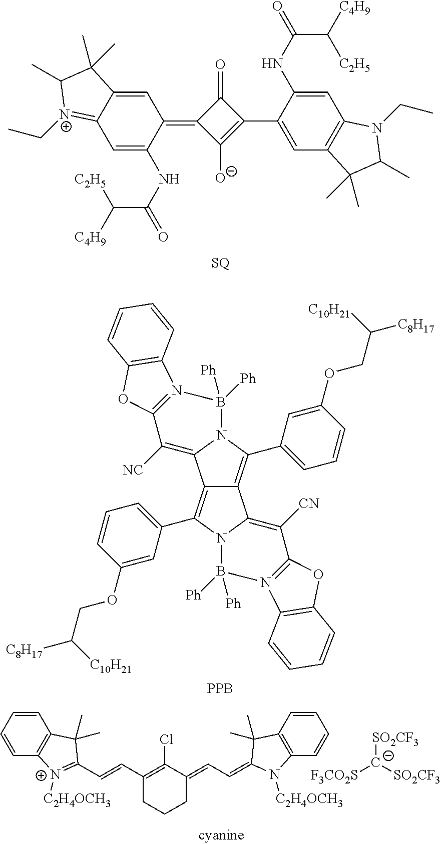

[Resin]

A-1 to A-48: resins synthesized as in Synthesis Examples described above

CA-1: resin represented by the following formula; a numerical value added to a main chain represents a molar ratio of each repeating unit; in addition, CA-1 was a resin not containing the repeating units represented by any one of Formula (1-1), . . . , or Formula (1-5) described above

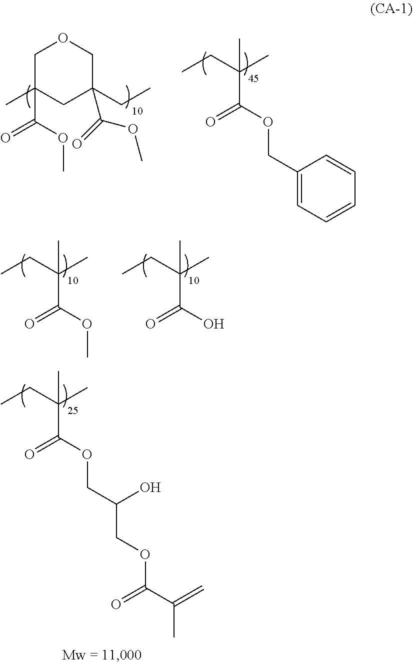

CA-2: resin represented by the following formula; a numerical value added to a main chain represents a molar ratio of each repeating unit; in addition, CA-2 was a resin not containing the repeating units represented by any one of Formula (1-1), . . . , or Formula (1-5) described above

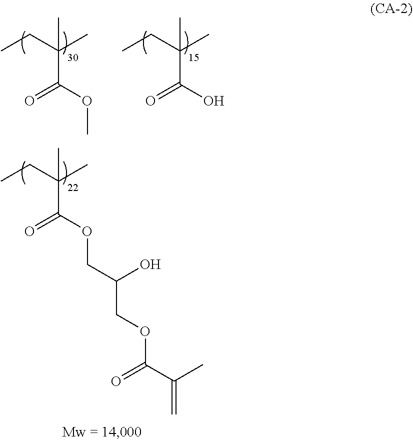

CA-3: resin represented by the following formula; in the following formula, a numerical value added to a main chain represents a molar ratio; in addition, CA-3 was a resin in which the proportion of the total amount of repeating units represented by any one of Formula (1-1), . . . , or Formula (1-5) described above with respect to the total molar amount of all repeating units included in the resin was 5 mol %

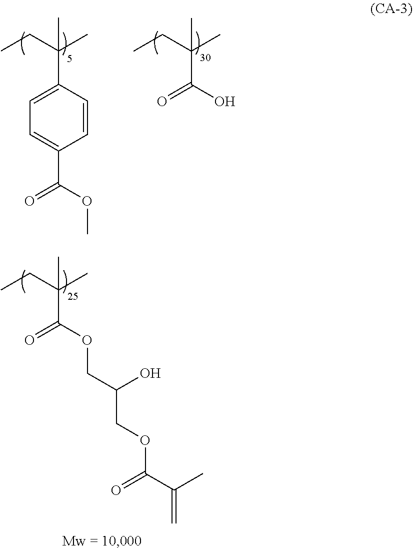

[Polymerizable Compound]

D-1: KAYARAD DPHA (manufactured by Nippon Kayaku Co., Ltd., mixture of dipentaerythritol hexaacrylate and dipentaerythritol pentaacrylate)

D-2: NK ESTER A-DPH-12E (manufactured by Shin-Nakamura Chemical Co., Ltd.)

D-3: ARONIX M-510 (manufactured by TOAGOSEI CO., LTD., carboxy group-containing polybasic acid-modified acrylic oligomer)

[Photopolymerization Initiator]

E-1: Omnirad 379EG (aminoacetophenone-based photo-radical initiator (manufactured by IGM Resins B.V.))

E-2: IRGACURE OXE01 (oxime ester-based photo-radical initiator (manufactured by BASF))

E-3: IRGACURE OXE03 (oxime ester-based photo-radical initiator (manufactured by BASF))

[Silane Coupling Agent]

F-1: compound represented by Formula (F-1); in Formula (F-1), Me represents a methyl group

F-2: compound represented by Formula (F-2); in Formula (F-2), Me represents a methyl group, and Et represents an ethyl group

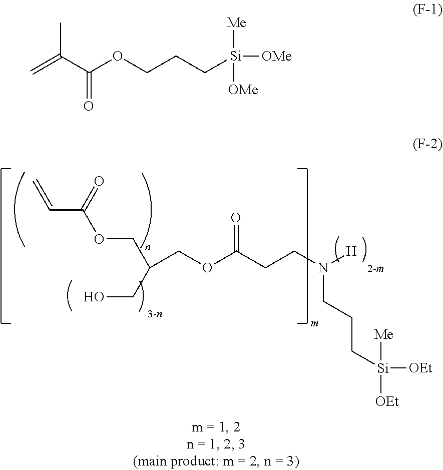

[Curing Agent (Compound Having Cyclic Ether Group)]

G-1: EPICLON N-695 (manufactured by DIC Corporation)

G-2: EHPE 3150 (manufactured by Daicel Corporation)

[Surfactant]

H-1: compound represented by the following structure; % showing a proportion of a constitutional unit is a molar ratio

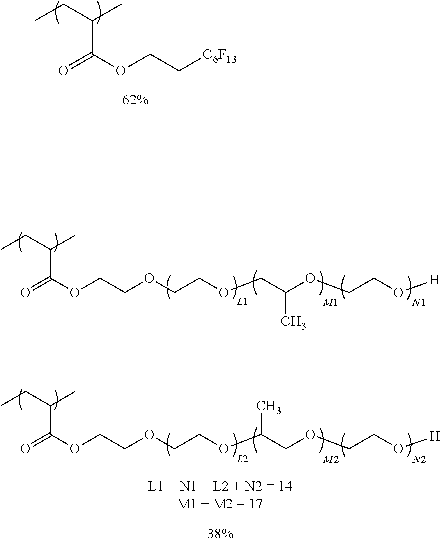

[Polymerization Inhibitor]

I-1: p-methoxyphenol

[Solvent (Organic Solvent)]

S-1: propylene glycol monomethyl ether acetate

S-3: cyclohexanone

<Evaluation>

[Evaluation of Exposure Sensitivity]

In each of Examples and Comparative Examples, the composition or the comparative composition was applied to a silicon wafer by spin coating, and dried (pre-baked) at 100° C. for 120 seconds using a hot plate to form a composition layer having a thickness of 0.70 μm.

Next, using an i-ray stepper exposure device FPA-3000 i5+ (manufactured by Canon Inc.), the composition layer was irradiated with light having a wavelength of 365 nm through a mask pattern in which square non-masked pixels with a side length of 1.0 μm were arranged in an area of 4 mm×3 mm to perform exposure thereon with a specific exposure amount.

Next, the silicon wafer on which the composition layer after the exposure had been formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pattern (pixel).

While changing the above-described specific exposure amount, the obtained pattern was observed, the minimum exposure amount for resolving the square pattern with a side length of 1.0 μm was determined, and evaluation was performed according to the following evaluation standard. The evaluation results are shown in Table 20. It can be said that, as the minimum exposure amount is smaller, the composition has more excellent exposure sensitivity. In addition, in the example described as “Not evaluated” in the column of “Exposure sensitivity” in Table 20, the exposure sensitivity was not evaluated.

—Evaluation Standard—

A: minimum exposure amount was less than 100 mJ/cm².

B: minimum exposure amount was 100 or more and less than 200 mJ/cm².

C: minimum exposure amount was 200 or more and less than 500 mJ/cm².

D: minimum exposure amount was 500 or more and less than 1,000 mJ/cm².

E: minimum exposure amount was 1,000 mJ/cm² or more.

[Evaluation of Dispersion Storage Stability]

In each of Examples and Comparative Examples, the viscosity (mPa·s) of the composition or the comparative composition was measured by “RE-85L” manufactured by TOKI SANGYO CO., LTD. After the above-described measurement, the composition was allowed to stand at 45° C. under the conditions of light shielding for 3 days, and the viscosity (mPa·s) was measured again. Storage stability was evaluated according to the following evaluation standard from a viscosity difference (ΔVis) before and after leaving to stand. The evaluation results are described in the column of “Dispersion storage stability” in Table 20. It can be said that, as the numerical value of the viscosity difference (ΔVis) is smaller, the storage stability of the composition is better. In each of the above-described viscosity measurements, the temperature and humidity were controlled to 22+5° C. and 60+20% in a laboratory, and the temperature of the composition was adjusted to 25° C.

—Evaluation Standard—

A: ΔVis was 0.5 mPa·s or less.

B: ΔVis was more than 0.5 mPa·s and 1.0 mPa·s or less.

C: ΔVis was more than 1.0 mPa·s and 2.0 mPa·s or less.

D: ΔVis was more than 2.0 mPa·s and 2.5 mPa·s or less.

E: ΔVis was more than 2.5 mPa·s.

[Evaluation of Spectral Change]

In each of Examples and Comparative Examples, on a glass substrate, the composition or the comparative composition was applied to a glass substrate by spin coating, and dried (pre-baked) at 100° C. for 120 seconds using a hot plate. Thereafter, the composition or the comparative composition was heated (post-baked) at 200° C. for 30 minutes using an oven to produce a film having a thickness of 0.60 μm. Using Cary 5000 UV-Vis-NIR spectrophotometer (manufactured by Agilent Technologies, Inc.), a transmittance Tr1 of the obtained film at a wavelength of 450 nm was measured. Next, the obtained film was heat-treated at 320° C. for 3 hours in a nitrogen atmosphere. A transmittance Tr2 of the film after the heating treatment at a wavelength of 450 nm was measured.

An absolute value ΔT of the difference between Tr1 and Tr2 was calculated, and the spectral change was evaluated according to the following evaluation standard. The evaluation results are described in the column of “Spectral change” in Table 20. It can be said that, as ΔT is smaller, the spectral change is less likely to occur, which is preferable. Both Tr1 and Tr2 were measured in a state in which the temperature and humidity were controlled to 22±5° C. and 60±20% in a laboratory, and the temperature of the substrate was adjusted to 25° C.

—Evaluation Standard—

A: ΔT was 0.1% or less.

B: ΔT was more than 0.1% and 0.5% or less.

C: ΔT was more than 0.5% and 1% or less.

D: ΔT was more than 1% and 5% or less.

E: ΔT was more than 5%.

[Evaluation of Film Contraction Ratio]

In each of Examples and Comparative Examples, on a glass substrate, the composition or the comparative composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm. The film thickness was measured by scraping a part of the film to expose a surface of the glass substrate, and measuring a level difference (film thickness of the coating film) between the surface of the glass substrate and the coating film using a stylus profilometer (DektakXT, manufactured by BRUKER). Next, the obtained film was heat-treated at 320° C. for 3 hours in a nitrogen atmosphere. The film thickness of the film after the heating treatment was measured in the same manner as described above, a film contraction ratio was calculated from the following expression, and the film contraction ratio was evaluated according to the following evaluation standard. The evaluation results are described in the column of “Film contraction ratio” in Table 20. Both T0 and T1 below were measured in a state in which the temperature and humidity were controlled to 22+5° C. and 60 f 20% in a laboratory, and the temperature of the substrate was adjusted to 25° C. It can be said that, as the film contraction ratio is smaller, the film contraction is more suppressed, and the heat resistance of the obtained film is excellent.

Film contraction ratio (%)=(1−(T1/T0))×100

T0: thickness of film immediately after production (=0.60 μm)

T1: thickness of film after the heating treatment at 320° C. for 3 hours in a nitrogen atmosphere

—Evaluation Standard—

A: film contraction ratio was 1% or less.

B: film contraction ratio was more than 1% and 5% or less.

C: film contraction ratio was more than 5% and 10% or less.

D: film contraction ratio was more than 10% and 30% or less.

E: film contraction ratio was more than 30%.

[Evaluation of Cracks]

In each of Examples and Comparative Examples, on a glass substrate, the composition or the comparative composition was applied to a glass substrate by spin coating, and dried (pre-baked) at 100° C. for 120 seconds using a hot plate. Thereafter, the composition was heated (post-baked) at 200° C. for 30 minutes using an oven to produce a film having a thickness of 0.60 μm.

Next, SiO₂ was laminated at 200 nm on the surface of the obtained film by a sputtering method to form an inorganic film. The obtained film in which the inorganic film was formed on the surface was heat-treated at 320° C. for 3 hours in a nitrogen atmosphere. The surface of the inorganic film after the heating treatment was observed with an optical microscope, the number of cracks per 1 cm² was counted, and the presence or absence of cracks was evaluated according to the following evaluation standard. The evaluation results are described in the column of “Crack” in Table 20.

—Evaluation Standard—

A: number of cracks per 1 cm² was 0.

B: number of cracks per 1 cm² was 1 to 10.

C: number of cracks per 1 cm² was 11 to 50.

D: number of cracks per 1 cm² was 51 to 100.

E: number of cracks per 1 cm² was 101 or more.

TABLE 20

| | | Evaluation result | | | | |
|---|---|---|---|---|---|---|
| | | Exposure | Dispersion | | Film | |
| | | sensi- | storage | Spectral | contraction | |
| | | tivity | stability | change | ratio | Crack |
| Example | 1 | C | A | B | A | A |
| | 2 | C | A | B | A | A |
| | 3 | C | A | A | A | A |
| | 4 | C | A | A | A | A |
| | 5 | B | A | B | B | A |
| | 6 | B | A | B | A | A |
| | 7 | C | A | B | A | A |
| | 8 | C | A | B | B | A |
| | 9 | A | A | B | C | A |
| | 10 | A | A | B | C | A |
| | 11 | C | A | B | A | A |
| | 12 | A | A | A | B | A |
| | 13 | B | A | A | A | A |
| | 14 | C | A | A | A | A |
| | 15 | C | A | A | A | A |
| | 16 | C | A | A | A | A |
| | 17 | C | A | A | A | A |
| | 18 | B | A | B | B | A |
| | 19 | A | A | B | B | A |
| | 20 | A | A | B | B | A |
| | 21 | A | A | B | B | A |
| | 22 | A | A | B | A | A |
| | 23 | A | A | A | A | A |
| | 24 | A | A | A | A | A |
| | 25 | A | A | A | A | A |
| | 26 | B | A | A | A | A |
| | 27 | A | A | A | A | A |
| | 28 | A | A | A | A | A |
| | 29 | Not | A | A | A | A |
| | | evaluated | | | | |
| Example | 30 | A | A | A | A | A |
| | 31 | A | A | A | B | A |
| | 32 | Not | A | A | B | A |
| | | evaluated | | | | |
| | 33 | A | A | A | B | A |
| | 34 | B | A | B | A | A |
| | 35 | B | A | B | A | A |
| | 36 | Not | A | B | A | A |
| | | evaluated | | | | |
| | 37 | A | A | B | A | A |
| | 38 | A | A | B | B | A |
| | 39 | A | A | B | B | A |
| | 40 | A | A | C | B | A |
| | 41 | A | A | C | B | A |
| | 42 | A | A | B | A | A |
| | 43 | A | A | A | A | A |
| | 44 | A | A | A | A | A |
| | 45 | A | A | B | A | A |
| | 46 | A | A | A | A | A |
| | 47 | A | A | A | A | A |
| | 48 | A | A | A | A | A |
| | 49 | A | A | A | A | A |
| | 50 | A | A | A | A | A |
| | 51 | A | A | B | B | A |
| | 52 | A | A | A | A | A |
| | 53 | A | A | A | A | A |
| Comparative | 1 | D | A | C | E | D |
| example | 2 | D | A | C | E | D |
| | 3 | D | A | C | E | D |
| | 4 | D | A | D | E | E |

As described above, in a case where the compositions of Examples were used, compared to a case of using the comparative compositions of Comparative Examples 1 to 3, the film contraction ratio was excellent. Therefore, it could be said that, compared to the comparative compositions of Comparative Examples 1 to 3, the compositions described in Examples had excellent heat resistance of the obtained film. In a case where, in Example 1, the evaluation was performed in the same manner as above without adding the surfactant during preparing the composition, the same result as in Example 1 was obtained. In a case where, in Example 1, the evaluation was performed in the same manner as above without adding the polymerization inhibitor during preparing the composition, the same result as in Example 1 was obtained. In addition, the same result could be obtained in a case where the cured film of the composition of Example 2 was laminated on the cured film of the composition of Example 1 and evaluated in the same manner. In addition, even in a case where a near-infrared cut filter formed of the pigment dispersion liquid 11 was laminated on the cured film of the composition of Example 1, the heat resistance was excellent as in Example 1.

### Example 100: Pattern Formation by Photolithography Method

The composition of Example 13 was applied to a silicon wafer by spin coating, and dried (pre-baked) at 100° C. for 120 seconds using a hot plate. Thereafter, the composition was heated (post-baked) at 200° C. for 30 minutes using an oven to form a composition layer having a thickness of 0.60 μm.

Next, using an i-ray stepper exposure device FPA-3000 i5+ (manufactured by Canon Inc.), the composition layer was irradiated with light having a wavelength of 365 nm through a mask pattern in which square non-masked pixels with a side length of 1.1 μm were arranged in an area of 4 mm×3 mm to perform exposure thereon with an exposure amount of 500 mJ/cm².

Next, the silicon wafer on which the composition layer after the exposure had been formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pattern (pixel).

The produced silicon wafer with a pattern was divided into two, and one of these was heat-treated at 320° C. for 3 hours in a nitrogen atmosphere (hereinafter, one is referred to as a substrate before heating treatment at 320° C. and the other is referred to as a substrate after heating treatment at 320° C.). In a case where cross sections of resist patterns formed on the substrate before heating treatment at 320° C. and the substrate after heating treatment at 320° C. were evaluated by a scanning electron microscope (SEM), the height of the resist pattern formed on the substrate after heating treatment at 320° C. was 79% of the height of the resist pattern formed on the substrate before heating treatment at 320° C.

### EXPLANATION OF REFERENCES

110: solid-state imaging element
111: near-infrared cut filter
112: color filter
114: near-infrared transmitting filter
115: microlens
116: planarizing layer

What is claimed is:

1. A composition comprising:
a colorant;
a resin; and
a solvent,
wherein the resin includes at least one repeating unit selected from the group consisting of repeating units each represented by any one of Formula (1-1), . . . , or Formula (1-5),
a proportion of a total amount of the repeating units each represented by any one of Formula (1-1), . . . , or Formula (1-5) is 10 mol % or more with respect to a total molar amount of all repeating units included in the resin,
a total content of the colorant and a near-infrared absorber is 30 mass % or more with respect to a total solid content of the composition, and
Amin/B, which is a ratio of a minimum value Amin of an absorbance of the composition in a wavelength range of 400 to 640 nm to an absorbance B of the composition at a wavelength of 1,500 nm, is 5 or more, 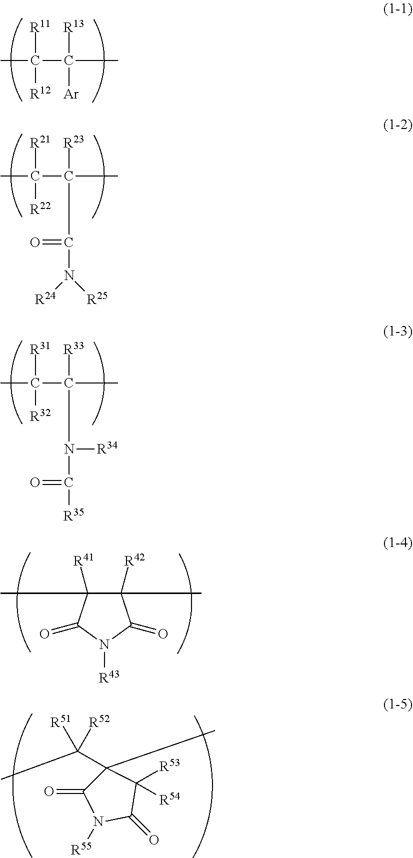
in Formula (1-1), R¹¹, R¹², and R¹³ each independently represent a hydrogen atom, a fluorine atom, an alkyl group which may be substituted with a fluorine atom, or an aromatic hydrocarbon group which may be substituted with a fluorine atom, and Ar represents an aromatic group having 5 to 30 ring members,
in Formula (1-2), R²¹, R²², and R²³ each independently represent a hydrogen atom, a fluorine atom, an alkyl group which may be substituted with a fluorine atom, or an aromatic hydrocarbon group which may be substituted with a fluorine atom, R²⁴ and R²⁷ each independently represent a hydrogen atom, an alkyl group having 1 to 30 carbon atoms, or an aromatic hydrocarbon group having 6 to 30 carbon atoms, and R²⁴ and R²⁵ may be bonded to each other to form a ring structure,
in Formula (1-3), R³¹, R³², and R³³ each independently represent a hydrogen atom, a fluorine atom, an alkyl group which may be substituted with a fluorine atom, or an aromatic hydrocarbon group which may be substituted with a fluorine atom, R³⁴ and R³⁵ each independently represent a hydrogen atom, an alkyl group having 1 to 30 carbon atoms, or an aromatic hydrocarbon group having 6 to 30 carbon atoms, and R³⁴ and R³⁵ may be bonded to each other to form a ring structure,
in Formula (1-4), R⁴¹ and R⁴² each independently represent a hydrogen atom, a fluorine atom, an alkyl group which may be substituted with a fluorine atom, or an aromatic hydrocarbon group which may be substituted with a fluorine atom, and R⁴³ represents a hydrogen atom, an alkyl group having 1 to 30 carbon atoms, or an aromatic hydrocarbon group having 6 to 30 carbon atoms,
in Formula (1-5), R⁵¹ to R⁵⁴ each independently represent a hydrogen atom, a fluorine atom, an alkyl group which may be substituted with a fluorine atom, or an aromatic hydrocarbon group which may be substituted with a fluorine atom, and R⁵⁵ represents a hydrogen atom, an alkyl group having 1 to 30 carbon atoms, or an aromatic hydrocarbon group having 6 to 30 carbon atoms.

2. The composition according to claim 1,
wherein a proportion of a total amount of the repeating unit represented by Formula (1-1) is 10 mol % or more with respect to the total molar amount of all repeating units included in the resin.

3. The composition according to claim 1,
wherein the proportion of the total amount of the repeating units each represented by any one of Formula (1-1), . . . , or Formula (1-5) is more than 60 mol % with respect to the total molar amount of all repeating units included in the resin.

4. The composition according to claim 1,
wherein, in Formula (1-1), Ar has, as a substituent, a substituent including a heteroatom.

5. The composition according to claim 1,
wherein a wavelength of a film, which is formed from the composition and has a film thickness of 1 μm, indicating a light transmittance of 50% in a thickness direction of the film is 700 to 950 nm, and a minimum value of a light transmittance of the film in a wavelength range of 950 to 1,300 nm is 90% or more.

6. The composition according to claim 1,
wherein a wavelength of a film, which is formed from the composition and has a film thickness of 1 μm, indicating a light transmittance of 50% in a thickness direction of the film is 70) to 800 nm, and a minimum value of a light transmittance of the film in a wavelength range of 800 to 1,300 nm is 90% or more.

7. The composition according to claim 1,
wherein the colorant is an organic pigment.

8. The composition according to claim 1, further comprising:
the near-infrared absorber.

9. The composition according to claim 1,
wherein the colorant includes a black coloring material.

10. The composition according to claim 1,
wherein the colorant includes at least one coloring material selected from the group consisting of a red coloring material, a green coloring material, a blue coloring material, a yellow coloring material, and a violet coloring material.

11. The composition according to claim 1,
wherein the resin has at least one group selected from the group consisting of a hydroxy group, a carboxy group, a sulfo group, a phosphoric acid group, and an amino group.

12. The composition according to claim 1,
wherein an acid value of the resin is 0 to 150 mgKOH/g.

13. The composition according to claim 1,
wherein the resin has an ethylenically unsaturated bond.

14. The composition according to claim 1,
wherein, as the resin, the following resin 1 and resin 2 are included,
resin 1: a resin which is the resin and includes a group having an acid group and an ethylenically unsaturated bond,
resin 2: a resin which is the resin, has at least one group selected from the group consisting of a hydroxy group, a carboxy group, a sulfo group, a phosphoric acid group, and an amino group, and has a molecular chain having a molecular weight of 500 to 10,000 and having no acid group and basic group.

15. The composition according to claim 1, further comprising:
a polymerizable compound.

16. The composition according to claim 1, further comprising:
a polymerization initiator.

17. The composition according to claim 16,
wherein the polymerization initiator is a photopolymerization initiator.

18. The composition according to claim 1,
wherein the composition is used for forming a pattern in a photolithography method.

19. The composition according to claim 1,
wherein the composition is used for a solid-state imaging element.

20. A film obtained from the composition according to claim 1.

21. A cured film obtained by curing the composition according to claim 1.

22. A near-infrared transmitting filter comprising:
the film according to claim 20.

23. A solid-state imaging element comprising:
the film according to claim 20.

24. An infrared sensor comprising:
the film according to claim 20.

25. A method for manufacturing a cured film, comprising:
a step of curing a film formed from the composition according to claim 1 by at least one of exposure or heating.

26. The method for manufacturing a cured film, comprising:
a step of curing a film formed from the composition according to claim 1 by exposure.

27. A method for manufacturing a cured film, comprising:
an exposing step of exposing a part of a film formed from the composition according to claim 1; and
a developing step of developing the film after exposure.
